(19) United States
(12) Patent Application Publication
(10) Pub. No.: US 2026/0244802 A1
(43) Pub. Date: Aug. 20, 2026

(54) AUTOMATED DETERMINATION OF CLEARANCE REQUIREMENTS IN CONSTRUCTION OF A BUILDING

(71) Applicant: Togal.AI Inc., Miami, FL (US)

(72) Inventors: Patrick E Murphy, Miami, FL (US); Johnny Maghzal, Miami, FL (US)

(73) Assignee: Togal.AI Inc., Miami, FL (US)

(21) Appl. No.: 19/161,229

(22) PCT Filed: Aug. 30, 2024
(86) PCT No.: PCT/US24/44846

§ 371 Date: Aug. 30, 2025

Related U.S. Application Data
(60) Provisional application No. 63/535,971, filed on Aug. 31, 2023.

(51) Int. Cl. G06F 30/13; G06F 30/12

(52) U.S. Cl. CPC G06F 30/13; G06F 30/12

(57) ABSTRACT

Apparatus and methods for performing clearance analysis of a building design plan includes a display and a controller with a processor and memory storing executable software. The controller is configured to receive a design plan, convert it into dynamic components, and generate an interactive user interface on the display. Users can define and reprioritize multiple clearance objectives in real time. An explainable AI engine analyzes the design for alignment with these objectives, providing human-readable explanations and visual traces for each clearance determination. The apparatus maintains a versioned history of user and AI modifications, enabling comparison, reversion, and branching of design states. The system supports collaborative, multi-user interaction, real-time feedback, and integration of updated building codes. Visual indicators highlight non-alignment areas, and suggested modifications are provided with corresponding explanations, enabling transparent, traceable, and adaptive clearance analysis for complex building projects.

### CROSS REFERENCE TO RELATED APPLICATIONS

This application is a U.S. National Phase of International Application Number PCT/US24/44846, filed Aug. 30, 2024, which claims the benefit of and priority to U.S. Provisional Application No. 63/535,971, filed Aug. 31, 2023, the entire disclosures of each of which are incorporated herein by reference.

### FIELD OF THE INVENTION

The present invention provides improved methods and apparatus for automated determination of clearance requirements for aspects of an architectural design plan with a deployment objective. More specifically, the present invention provides for automated conversion of design plans into dynamic components that can be interactively manipulated and analyzed within a user interface to determine clearance objectives associated with the deployment objective. Interactive user interfaces allow a clearance objective to involve one or more of: structural elements, fixtures, environmental considerations, and occupancy requirements. The apparatus and methods described herein enable precise and efficient evaluation of design plans, facilitate the identification of areas that do not meet user input objectives. In some embodiments, a controller suggests modifications to bring designs into conformity with user input objectives. The invention is applicable to a wide range of building types, including residential, commercial, industrial, and mixed-use structures, and can be utilized in various environmental and regulatory contexts.

### BACKGROUND OF THE INVENTION

Design plans are integral to the construction and architectural industry, serving as the blueprints that guide the construction of buildings and infrastructure. These design plans encompass detailed specifications of structural elements, electrical systems, plumbing, and many other aspects of the building process. However, beyond the aesthetic and functional considerations, design plans must also building deployment objective reflect placement of building aspects that allow for deployment of the building for a user defined purpose.

Building deployment objectives may vary based on several factors, including geographic location, the type of building, its intended use, and the specific hazards associated with its environment.

Geographic location plays a useful role in determining the specific building deployment objectives that a design plan must comply with. For example, buildings in areas prone to seismic activity, such as California in the United States or Japan, may include a user objective to adhere to strict seismic design requirements.

In contrast, buildings in coastal regions, such as Florida or the Gulf Coast, may include user objectives that address wind load requirements due to the risk of hurricanes and other severe wind events.

Manual alignment checking requires a deep understanding of building deployment objective and/or user objectives for different types of buildings and geographic locations. Reviewers must be familiar with the relevant sections of the codes, understand how to interpret them in the context of a specific design, and be able to identify potential areas of non-alignment. This process is often time-consuming and labor-intensive, as it requires careful attention to detail and a thorough understanding of the technical aspects of the codes.

### SUMMARY OF THE DISCLOSURE

Accordingly, the present disclosure provides methods and apparatus for the detailed analysis of two-dimensional (2D) references, or three-dimensional references (3D), such as floorplans, design plans, blueprints, and similar architectural documents. These methods utilize artificial intelligence (AI) to conduct comprehensive assessments of clearance requirements, evaluating the spatial relationships between various elements, such as structural components, fixtures, and open spaces. The AI-driven approach facilitates precise measurements and analysis, enabling the identification of potential clearance issues and determining if the design plan adheres to relevant spatial standards and regulations. This system enhances traditional methods by providing automated, accurate, and efficient clearance analysis, reducing the likelihood of errors and streamlining the design review process.

The present invention provides a system designed to analyze clearance requirements in building design plans. The system receives a design plan, which may represent a portion or the entirety of a building, into a controller that operates an artificial intelligence (AI) engine. The AI engine is tasked with converting the static design plan into a set of dynamic components. These dynamic components are useful elements within the design plan and can represent both structural elements and fixtures. The invention further includes an interactive user interface that displays these dynamic components, allowing users to modify and interact with them in real-time.

The first step in this system is the intake of a design plan, which is typically a static representation of the building's layout (such as for example via a portable document format “PDF” document), including walls, doors, fixtures, and other architectural features. Upon receiving the design plan, the controller, powered by the AI engine, processes this information to convert it into multiple dynamic components. This conversion transforms a non-interactive, fixed plan into a series of components that can be analyzed, adjusted, and tested for alignment with clearance requirements.

Dynamic components in this context may refer to elements of a design plan that can be independently manipulated by a user in an interactive interface and/or within an automated controller. These elements may include structural aspects such as walls, doors, windows, and load-bearing columns, as well as fixtures like furniture, plumbing installations, or HVAC systems. For example, a wall in the design plan is converted into a dynamic component that can be moved, resized, or reoriented within the user interface. Similarly, a fixture like a sink or toilet is treated as a dynamic component that can be repositioned within the design space. A dynamic component may include one or more of: polygons, lines, points, symbols, images, meme, non-fungible tokens (NFTs), or other manipulatable items.

Structural elements within the design plan may further be classified into specific categories to facilitate detailed analysis. The structural elements may define boundaries, paths, and spaces:
Boundaries: These refer to the physical limits within the design plan, such as walls, partitions, and exterior facades. Boundaries may define the overall structure and layout of the building. In the dynamic component model, boundaries can be adjusted to examine how changes in wall placement or thickness may affect the available clearance for movement or the positioning of fixtures.
Paths: Paths are designated routes within the building, including hallways, corridors, staircases, and passageways. Paths are analyzed to determine if they provide adequate clearance for movement, including the ability to move materials and equipment, service architectural aspects (e.g. maintenance of the building or service of equipment within the building), and general ease of navigation. For example, the AI engine may analyze the width and clearance around a HVAC unit, escalator, elevator, plumbing, electrical panel, filter, or other serviceable item, or the ability for multiple persons to walk abreast on a pathway and/or to walk in different directions on a pathway or a general access area or space.
Spaces: Spaces refer to defined areas within the building, such as rooms, lobbies, and open areas. The system assesses these spaces for their adequacy in providing sufficient clearance around fixtures and for meeting spatial requirements. For example, a conference room's space is analyzed to determine whether it can accommodate the required number of occupants while maintaining proper clearance around seating and tables.

Fixtures, on the other hand, are elements within the design plan that interact with the structural components but are not part of the building's primary structure. These may include furniture, appliances, lighting fixtures, and plumbing installations. The AI engine treats these as dynamic components, allowing users to reposition and resize them within the design to test different configurations and their impact on clearance and overall functionality.

The present invention includes an interactive user interface that helps in how users engage with the dynamic components. The user interface allows users to view, modify, and interact with the various dynamic components of the design plan. Each dynamic component may be associated with a set of parameters that can be adjusted directly within the interface. These parameters may include dimensions, positioning, orientation, and other relevant attributes that influence how the component fits within the overall design.

For example, if a user needs to adjust the clearance between a door and a nearby wall, they can simply select the door component within the user interface and modify its position or the width of the adjacent wall. The user interface may also allow users to simulate different scenarios, such as the opening and closing of doors or the movement of furniture, to assess the impact on clearance and alignment with codes.

The user interface is designed to be intuitive and user-friendly, providing real-time feedback as changes are made. This feature may particularly be beneficial for architects, engineers, and alignment officers who need to make quick adjustments and immediately see the impact on the design's alignment with clearance requirements. Additionally, the user interface may include tools for measuring distances, checking angles, and comparing different design configurations, further aiding in the analysis process.

In some embodiments, a design plan represents a residential building where the system may be used to analyze the clearance around doorways and corridors to determine alignment with accessibility standards. The AI engine may convert each doorway and corridor into dynamic components, and the user may adjust the width of the doors or the placement of walls to verify that there is sufficient clearance for wheelchair access.

Another example may involve a commercial kitchen design where the system may be used to check the clearance around appliances and workstations. The dynamic components in this case may include counters, ovens, sinks, and refrigerators. The user can interact with these components to adjust their placement to achieve adequate clearance for workers to move freely, complying with occupational safety standards.

In some embodiments, a database of regional building deployment objectives and standards may be integrated with the system. The AI engine may reference this database to automatically check the design plan against the specific clearance requirements relevant to the building's location. The system may also incorporate features for collaborative design, where multiple users can work on the same design plan simultaneously, making real-time adjustments and sharing insights.

Additionally, the system may be equipped with simulation capabilities, allowing users to visualize how the building's spaces will function once constructed. For example, it may simulate the flow of people through a hallway during an emergency travel, providing valuable insights into whether the clearance is sufficient to prevent bottlenecks.

Building plans are often regarded as the foundational framework of a construction project, providing a comprehensive blueprint that guides the creation of structures that serve various purposes within our communities. Many elements of a building to be constructed are included in details of the design plans. The elements may include architectural aspects, equipment, fixtures, or other physical items. Inherent with the placement and size of such elements is an amount of space that separates them. The present invention identifies and analyzes clear and unobstructed spaces within these design plans. The clear and unobstructed spaces may then be considered in relation to functionality, convenience and service requirements of equipment placed in the building.

Specifically, the present invention uses AI to auto-detect, measure, and classify components of building plans, including spaces specified for equipment or area access, and ascertain whether requirements relating to a building design assess clearances and open space.

In some embodiments, the AI engine may be designed to conduct a comprehensive load-bearing analysis of a building's structural elements to determine alignment with relevant codes for structural stability. This analysis may include evaluating key components such as beams, columns, the base structure, load-bearing walls, and floor slabs. The AI engine is capable of calculating and assessing various factors that contribute to the overall stability and safety of the building.

The AI engine begins by analyzing the number and placement of columns (e.g., a vertical load-bearing member) within the building design. Columns are primary load-bearing elements that transfer the weight of the structure from the floors and roof down to the foundation. The AI engine assesses whether the number of columns specified in the design plan is sufficient to support the expected loads, taking into account factors such as the building's height, floor area, and the type of materials used in construction.

Beyond the number of columns, the AI engine may also evaluate the internal reinforcement of each column. It calculates the required number of steel bars (rebar) within each column based on the load they need to bear. The AI engine may also determine the appropriate diameter and spacing of these steel bars to optimize the column's strength and stability. For example, in a high-rise residential building, the AI engine may recommend additional reinforcement for columns on lower floors that bear more weight from the upper stories.

Beams are horizontal structural elements that distribute loads from the floors and walls to the columns. The AI engine may analyze the beams in the design plan to determine if they are properly sized and positioned to carry the expected loads. It assesses the length, cross-sectional area, and material properties of each beam, as well as the connection points between beams and columns. The AI engine also evaluates the beam span, which is the distance between two support points, such as columns or load-bearing walls. It determines whether the beams are capable of spanning the required distances without excessive deflection or failure. In the design of a commercial building with large open spaces, for example, the AI engine may suggest the use of deeper or stronger beams to accommodate the wider spans needed for open-floor layouts.

The foundation of a building useful may be functional to distribute a load of the entire structure to the ground. The AI engine examines the base structure and foundation, analyzing factors such as the type of foundation (e.g., slab, pier, or pile foundation), the depth of the foundation, and the soil characteristics of the construction site. It evaluates whether the foundation design is adequate to support the building's load and prevent issues like settling, shifting, or structural failure. The AI engine may also analyze the load distribution on the foundation, checking for even load transfer from the columns and beams to the ground. For example, in a building located on soft or unstable soil, the AI engine may recommend deeper foundations or additional piers to provide greater stability.

Load-bearing walls support the weight of floors and roofs and transfer loads down to the foundation. The AI engine analyzes the placement, thickness, and material composition of load-bearing walls within the design. It assesses whether these walls are appropriately positioned to carry the loads imposed by the structure above them.

Floor slabs, which are horizontal platforms that form the floors of a building, are also analyzed by the AI engine. It calculates the load-bearing capacity of the slabs based on their thickness, reinforcement, and material properties. The AI engine determines if the slabs can support the expected live loads (such as people, furniture, and equipment) and dead loads (such as the weight of the slab itself and any permanent fixtures).

For example, in the design of a multi-story office building, the AI engine may analyze the columns and beams on each floor, checking that they are sufficiently reinforced and appropriately spaced to support the combined weight of the floors above. It may identify areas where additional columns are necessary or where the use of stronger materials is advisable. In another example, the AI engine may analyze the foundation design for a warehouse being constructed on uneven terrain. By assessing the load distribution and soil characteristics, the AI engine may suggest modifications to the foundation design, such as deeper piers or the use of a different foundation type, to provide better load support and stability.

In some specific examples, the present invention utilizes machine learning and/or artificial intelligence to identify and analyze architectural aspects such as doorways, walls, equipment, stairwells, elevator shafts, open upper stories, atriums, and shafts. The AI engine determines the clearance and open space between these elements to determine if they meet necessary requirements for safety, accessibility, and functionality. For example, the AI may assess whether the clearance around doorways is sufficient for wheelchair accessibility or if the distance between walls and equipment allows for safe operation and maintenance of machinery.

The present invention significantly reduces inconsistencies in design alignment analysis and minimizes the potential for mistakes. It also provides consistent feedback on the reasons why a building design has adequate clearances and open spaces. If an original plan does not meet these requirements, the AI engine may suggest modifications to the design plan to achieve alignment with the necessary clearances and open spaces. For example, sufficient open space for one or more of: install and remove large items, such as equipment items, furniture, art; area to service aspects of the building; accommodate multiple people travelling abreast or travelling in different directions, service and/or maintain an equipment item in the building, allow for persons and/or vehicles to traverse the building, allow for automation such as unmanned ground vehicles (UGVs) and unmanned aerial vehicles (UAVs) to traverse the building, the AI engine may recommend widening the corridor or reconfiguring adjacent spaces to create the required width. Similarly, if the open space in a commercial building fails to meet air circulation preferences, the AI engine may suggest relocating vents, doors or adjusting the layout to provide sufficient circulation.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, airflow paths, windows, or other discrete aspects of a building. In addition, the AI engine may identify and categorize components such as load-bearing walls, non-load-bearing partitions, and structural beams, all of which are used for assessing the building's structural integrity and alignment with preferences and defined open areas sufficient to accommodate a preferred use of deployment of the building. For example, deployment of a building as a warehouse may have different clearance objectives than deployment as a residential area or a manufacturing or retail or dinning deployment.

A scaling process is applied to the floorplan and size descriptors are assigned to the discernable components. The scaling process allows the AI engine to accurately represent the physical dimensions of the components within the building design. In addition, distances, such as, for example, a distance to an exit from the furthest point in a residential unit are calculated.

Variables are specified that will be used to assess alignment and an alignment determination is made based upon values for the specified variables. For example, variables may include the minimum width of corridors for accessibility, the maximum allowable distance to an emergency exit, or the minimum ceiling height in habitable rooms. The AI engine uses these variables to assess whether the design complies with applicable building deployment objectives and regulations. If the design does not comply, the AI engine can identify the specific variables that were not met and provide targeted suggestions for how to bring the design into alignment.

In some embodiments, a controller will also set forth one or both of: components and conditions required to be in alignment with a set of rules or codes and where in the floorplan the components/conditions were included. Some embodiments may also include, in the case where the conditions/components were not met by a floorplan, the portions referenced in determining non-alignment. For example, if the AI engine determines that a particular room does not meet the minimum area requirement for its intended use, it may highlight that room in the floorplan and suggest either increasing its size or reclassifying its use to a function that requires less space. Still further, some embodiments may include suggested changes and/or options for sets of changes to the floor plan that may be implemented in order to achieve alignment.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (sometimes referred to herein as artificial intelligence or “AI”). This approach allows for a more efficient and thorough analysis of complex building designs, particularly in identifying potential issues that may not be immediately apparent through manual review.

Based upon AI analysis of pixel patterns derived from the two-dimensional references and knowledge accumulated from increasing volumes of analyzed two-dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. For example, the AI engine may analyze polygons representing rooms and hallways to determine if they conform to minimum area and accessibility standards. Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings.

In still another aspect, in some embodiments, enhanced interactive user interfaces may include one or more of: user-definable and/or editable lines; user-definable and/or editable vectors; and user-definable and/or editable polygons. The interactive user interface may also be referenced to generate diagrams based upon the lines, vectors and polygons defined in the interactive user interface. For example, a user may define a line representing a travel path or an area boundary, and the AI engine may then analyze this input to determine whether it meets the necessary safety and accessibility standards. Still further, various embodiments include values for variables that are definable via the interactive user interface with AI processing and human input. This allows for a highly customizable analysis process, where users can input specific requirements based on the unique needs of their project and receive tailored alignment feedback from the AI engine.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. For example, the AI engine may use deep learning techniques to improve its ability to recognize complex patterns in building designs, such as the optimal placement of structural elements for both safety and aesthetic appeal, or the best configuration of ventilation systems to provide adequate airflow while minimizing energy use. Over time, as the AI engine processes more design plans, it becomes increasingly adept at identifying potential alignment issues and suggesting effective solutions.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates a portion of a design plan that includes multiple dwelling units assessed by the AI engine for alignment analyses.

FIG. 1D illustrates an exemplary AI-powered system in accordance with the present invention.

FIGS. 1E-1F illustrate exemplary design plans assessed by the AI engine for structural strength analyses in accordance with the present invention.

FIGS. 1G-1H illustrate exemplary design plans of multi-story buildings assessed by the AI engine for alignment analyses in accordance with the present invention.

FIG. 1I illustrates an exemplary scenario considered by the AI engine for alignment analyses of a building construction considering the surroundings of the building in accordance with the present invention.

FIGS. 2A, 2B, 2C and 2D illustrate a two-dimensional representation of a floor plan and an AI analysis of same to assess boundaries, spaces, structural components, and fixtures.

FIGS. 3A-3D show various views of the AI-analyzed boundaries overlaid on the original floorplan including a table illustrated to contain hierarchical dominance relationships between area types.

FIGS. 4A-4B illustrate various aspects of dominance-based area allocation in accordance with the present invention.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate method steps that may be executed in some embodiments of the present invention.

FIG. 11 illustrates additional method steps that may be executed in some embodiments of the present invention.

FIGS. 12A-12B illustrate diagrams of travel paths analyzed by the AI engine for alignment analyses of design plans in some embodiments of the present invention.

FIG. 13 illustrates exemplary airflow paths of an HVAC system within a design plan analyzed by the AI engine for alignment analyses.

FIG. 14 illustrates a block diagram of exemplary aspects that may be used in building or refining design models.

FIGS. 15A-15B illustrate exemplary interactive user interfaces including selection of a space in a design plan for alignment analysis.

FIGS. 16A-16B illustrate exemplary method steps that may be included in some embodiments of the present invention.

### DETAILED DESCRIPTION

The present invention provides methods and apparatus for utilizing artificial intelligence (AI) to convert a two-dimensional reference, such as a design plan, into an interactive user interface. This interface allows users to assess whether the design plan includes adequate clearance between items and sufficient open space. The invention also incorporates methods for analyzing a building (or other structure) design based on automated AI analysis of a two-dimensional reference, applying machine learning to determine if the design meets clearance preferences and requirements. For example, the AI engine may analyze whether hallways in a commercial building meet the necessary width for emergency egress or if mechanical rooms provide enough space around HVAC units for maintenance access.

Following the design analysis, AI and machine learning may recognize and recommend aspects of a building to provide a consistent aesthetic and functional allocation of open space. For example, the AI engine may suggest modifications to the layout of rooms and corridors in an office building to improve both the flow of movement and the aesthetic appeal, so that spaces are neither too cramped nor overly spacious, which could waste valuable real estate. In some embodiments, these techniques may be combined with automated processes for analyzing building plans and providing a comprehensive blueprint that guides the creation of structures that serve various purposes within communities. Many elements of a building to be constructed are detailed in the design plans, including architectural aspects, equipment, fixtures, and other physical items. The invention identifies and analyzes clear and unobstructed spaces to evaluate their adequacy. For example, the AI engine may assess whether the space between kitchen counters and appliances in a residential design plan is sufficient to allow for easy movement and accessibility.

In some embodiments, the present invention identifies and analyzes clearance specifications, such as minimum distances or spaces necessary between objects, structures, equipment, or elements within a building. These clearances are determined via the AI processes described herein. For example, the AI engine may determine that a certain distance is required between electrical panels and other equipment to provide safety and alignment with electrical codes. The AI engine may also generate suggested changes to a design to allow for convenient service and maintenance of equipment included in the plan, prevent potential hazards, enable efficient operation, and comply with building deployment objectives and industry standards. Clearance specifications set forth adequate clearances around elements like equipment, architectural aspects, stairs, ramps, doors, and hallways to prevent overcrowding, reduce the risk of collisions, and allow for the swift travel of occupants in case of emergencies. For example, in a high-traffic commercial building, the AI engine may suggest widening corridors or repositioning doors to enhance the flow of foot traffic and meet unmanned vehicle safety preferences.

Building deployment objectives and regulations establish specific requirements for clearance specifications based on the type of building, its occupancy, and intended use. These codes are designed to prioritize the safety, health, and overall well-being of occupants. By adhering to clearance specifications, builders and designers can avoid delays, fines, or modifications due to non-alignment, so that their projects proceed smoothly. According to the present invention, clearance specifications are analyzed so that the AI engine may provide insights on whether the designed clearance is sufficient to support the intended use of various building components. Adequate space around mechanical equipment, such as HVAC systems, electrical panels, and plumbing fixtures, allows for proper installation, maintenance, and repair. For example, the AI engine may evaluate whether there is enough space around an HVAC unit in a mechanical room to allow for routine inspections and repairs, thus reducing the risk of accidents and extending the equipment's lifespan.

In another aspect, clearance specifications may be considered to ascertain the aesthetic aspects of a design. Incorporating appropriate clearances into the initial design phase allows architects and designers to create visually pleasing and harmonious spaces while adhering to regulatory requirements. For example, the AI engine may suggest increasing the distance between furniture and walls in a living room to enhance the sense of openness and improve the overall aesthetic of the space. The invention provides a framework for analyzing various types of clearance specifications, including horizontal clearances (distances between walls, partitions, furniture, and other elements within a room), vertical clearances (distances between the floor and ceiling or between different floor levels), egress clearances (minimum widths of corridors, stairwells, and doorways), and equipment clearances (adequate space around mechanical, electrical, and plumbing equipment).

For example, the AI engine may evaluate whether the spacing between desks in an open-plan office is sufficient to allow for comfortable movement and accessibility. It may also assess whether the vertical clearance above work surfaces in a commercial kitchen design is adequate for safe operation and proper lighting installation. In addition, the AI engine may verify that the space around a boiler in a utility room is sufficient to allow for easy access and proper ventilation, reducing the risk of overheating and providing alignment with safety standards. Equipment clearance refers to the specific spatial allowances required around mechanical, electrical, plumbing, and other utility equipment within a building. The AI engine may analyze design plans to determine if space is provided for equipment to be properly installed, efficiently maintained, and operated without obstruction. For example, the AI engine may analyze whether there is enough clearance around a water heater in a residential design to allow for easy access during repairs or replacement.

Preventing overheating and ventilation issues is another aspect of equipment clearance that the AI engine may address. The AI engine may assess whether there is sufficient space around equipment like generators or air conditioning units to allow for proper ventilation, preventing overheating and prolonging the equipment's lifespan. Alignment with codes and regulations is not only about functionality but also about providing safety and legal adherence. The AI engine may verify that all equipment in a design plan meets the minimum clearance distances required by relevant codes, reducing the risk of safety hazards and legal consequences. Furthermore, the AI engine may suggest increasing the clearance around an electrical panel to accommodate future upgrades or the installation of additional equipment, providing flexibility for future modifications or technological advancements without necessitating major structural changes.

In some embodiments of the present invention, a method for performing alignment analysis of a design plan with relevant building deployment objectives using an artificial intelligence (AI) engine is implemented. The process begins with the controller, which operates the AI engine, receiving a design plan that represents at least a portion of the building under consideration. The design plan, which may be a blueprint or other architectural documentation, is then converted by the controller into multiple dynamic components. These components may include rooms, hallways, structural elements, fixtures, and other significant elements that make up the physical layout of the building.

Once these dynamic components are established, the controller generates a first interactive user interface. This interface visually represents the portion of the building through the dynamic components, each of which has parameters that can be adjusted or modified by the user directly through the interface. For example, a user may change the dimensions of a room or alter the positioning of a doorway. This feature allows for real-time adjustments and immediate feedback on how these changes affect the overall design.

After the dynamic components are arranged within the interactive user interface, the controller forms a first set of boundaries that define the spatial limits of the components. These boundaries are quantified by their respective lengths and areas, which collectively outline the dimensions of at least a portion of a first unit within the building, such as an individual room or section of a floor. The formation of these boundaries useful may act as a precursor for further analysis of the design's alignment with relevant building deployment objectives.

Following the establishment of these boundaries, the controller proceeds to determine various design factors for the first unit. These factors include the proposed use of the building (e.g., residential, commercial, or industrial), the type of unit (e.g., bedroom, office, or lobby), the specific area covered by the unit, the number of floors within the building, the type of flooring used in the unit, the intended occupancy (how many people the space is designed to accommodate), and the geographical location of the building (which may influence local building deployment objectives and regulations).

Simultaneously, the controller ascertains design parameters specific to the first unit. These parameters involve identifying and analyzing structural elements such as columns, beams, and load-bearing walls, as well as fixtures like plumbing, HVAC systems, and electrical outlets. The combination of these structural and fixture elements provides a detailed understanding of the physical composition and functional aspects of the unit.

With both the design factors and parameters determined, the controller then evaluates these against the set of conditions required by the relevant building deployment objectives. These conditions are predefined by user objectives. The controller uses the design factors and parameters to assess whether the design plan adheres to these conditions. For example, if the design factor indicates that the unit is intended to be a commercial kitchen, the controller may reference user objectives related to ventilation, equipment operation, and flow of food preparation. A similar scenario may be applied to manufacture and/or supply chain facility requirements for flow of materials and operation of equipment.

The controller provides feedback within the first interactive user interface. This feedback indicates whether the design of the building, as represented by the dynamic components and their associated parameters, is in alignment with the relevant building deployment objectives. If the design meets all the required conditions, the interface may display a confirmation of alignment. If there are any discrepancies or areas where the design falls short of the required standards, the interface may highlight these issues, potentially suggesting modifications that may bring the design into alignment.

In some embodiments, the AI engine is utilized to perform a comprehensive alignment analysis of a design plan, determining if the building meets all relevant building deployment objectives and regulations. Initially, the method begins with the controller, powered by the AI engine, receiving the design plan for at least a portion of the building. This design plan is then converted into multiple dynamic components by the controller. These components include structural elements such as beams, columns, load-bearing walls, slabs, and foundations, which are integral to the building's integrity and stability.

To assess the alignment of these structural elements, the AI engine determines a set of conditions based on the specific characteristics of each element. For example, if the structural element is a column, the AI engine calculates the number of rebars within the column, a useful factor useful in determining the column's load-bearing capacity. The AI engine also determines the length and diameter of these rebars, as these dimensions directly affect the structural strength of the column.

Furthermore, the AI engine assesses the distances between various structural elements, such as the spacing between columns. This spacing is required for maintaining the structural integrity of the building, especially in multi-story constructions. The AI engine then calculates the overall load-bearing strength of these elements, considering the number of floors the building comprises, and the location of the unit within the building (whether it is on the ground floor, top floor, or any floor in between).

The AI engine also evaluates the design factors related to the building, including the proposed use of the building, the type of the first unit, its area, and the floor type. For example, if the building is intended for residential use, the AI engine analyzes the unit's layout to determine if it complies with residential building deployment objectives, including egress requirements, equipment safety preferences, and occupancy limits. The AI engine can predict the intended occupancy of the unit based on its type, including, by way of non-limiting example determine that an area includes: a kitchen, bathroom, bedroom, or office space, and determine if it includes desired aspects for such spaces.

Moreover, the AI engine considers the environmental conditions of the building's location, such as whether the building is in a seismic zone, floodplain, or coastal area. It incorporates this information into the alignment analysis, checking for requirements like wind load resistance, seismic activity considerations, and snow load capacities.

In addition to structural elements, the AI engine also analyzes fixtures within the building, such as plumbing installations, electrical fixtures, HVAC systems, and furniture. For example, the AI engine may verify that the placement of plumbing fixtures complies with local plumbing codes, providing proper spacing and access for maintenance. The AI engine may also automatically suggest modifications to the design plan if it detects any potential non-alignment with the relevant codes, providing specific recommendations to bring the plan into alignment.

The AI engine also facilitates a collaborative approach by allowing multiple users to interact with the design plan via the first interactive user interface. Users can view, modify, and discuss the design parameters in real-time, so that all stakeholders are involved in the decision-making process.

Furthermore, the AI engine has access to a continuously updated database of building deployment objectives, so that the alignment analysis is always based on the latest regulations. The engine can also simulate the structural behavior of the building under various load conditions, providing a 3D visualization of the building's performance in the first interactive user interface.

For complex design plans involving multiple units or floors, the AI engine prioritizes the analysis based on a dominance rank of the units, so that prioritized areas are assessed first. The engine can also perform a cost analysis, estimating the expenses involved in modifying the design to meet alignment requirements.

The AI engine provides visual indicators within the interactive user interface, highlighting areas of the design that do not comply with the relevant codes. This allows users to quickly identify and address any issues, so that the building meets all necessary regulations before construction begins. Additionally, the AI engine is capable of performing alignment analysis for multiple units within the same building, providing a comprehensive review of the entire design plan.

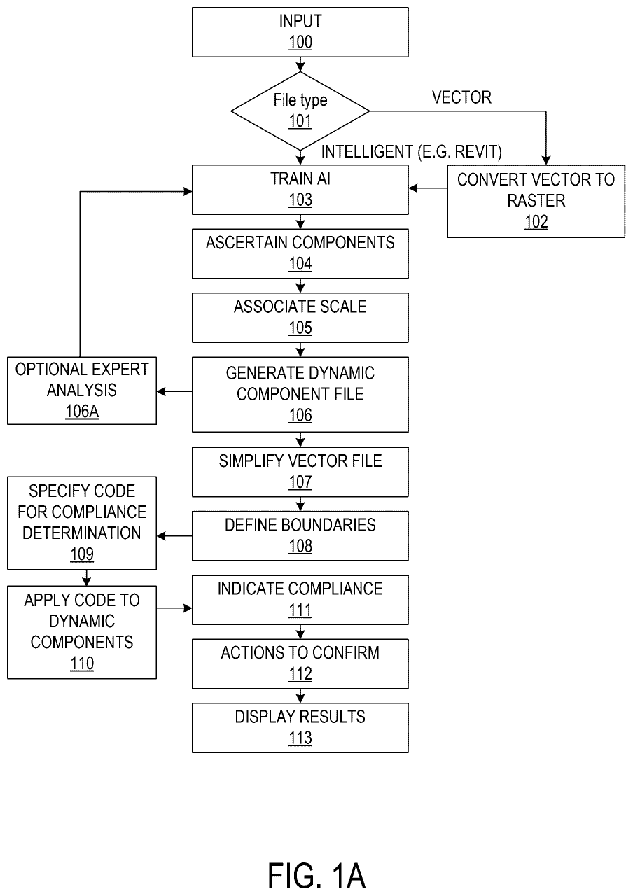

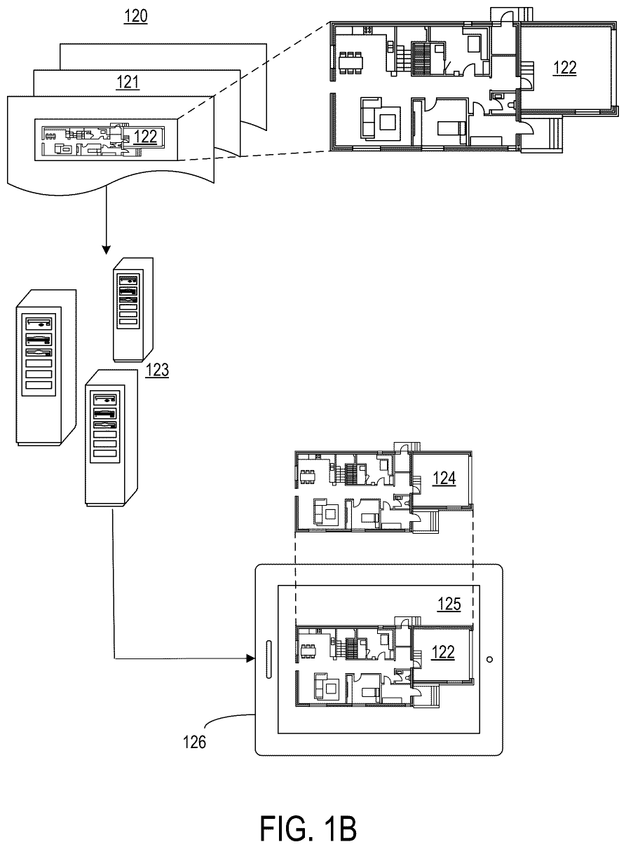

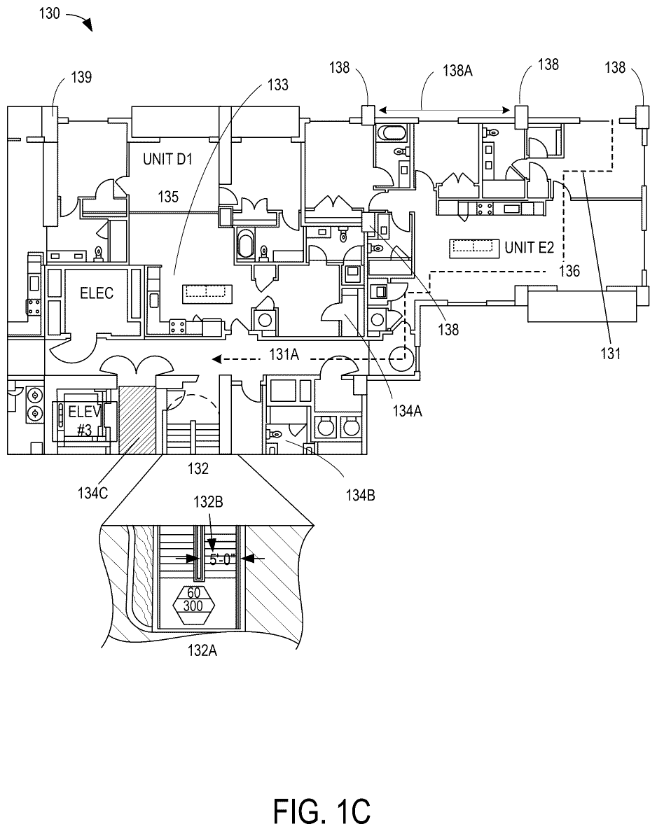

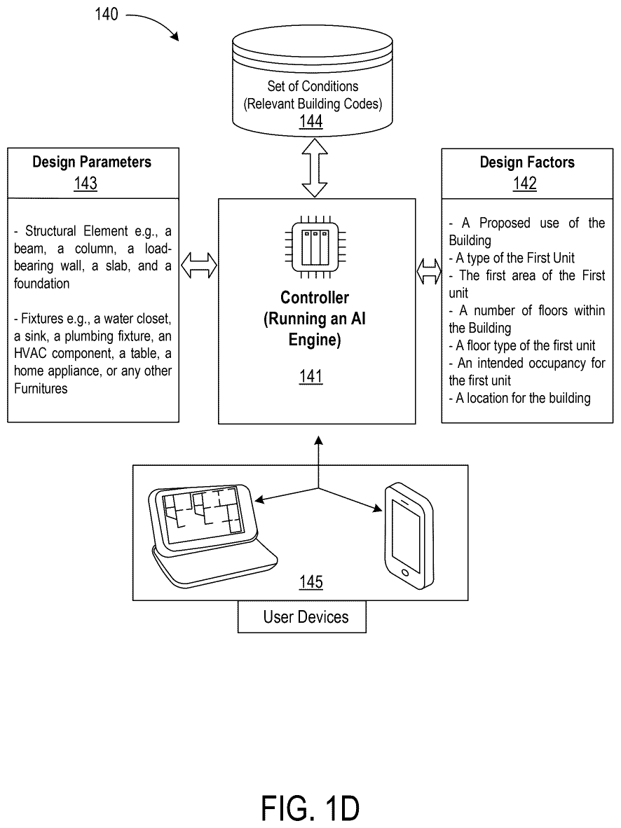

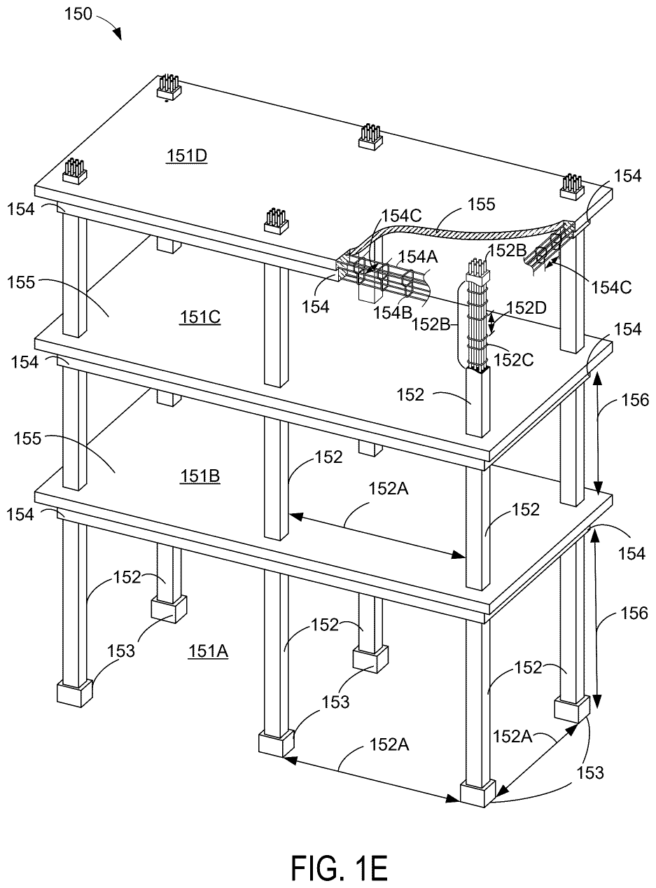

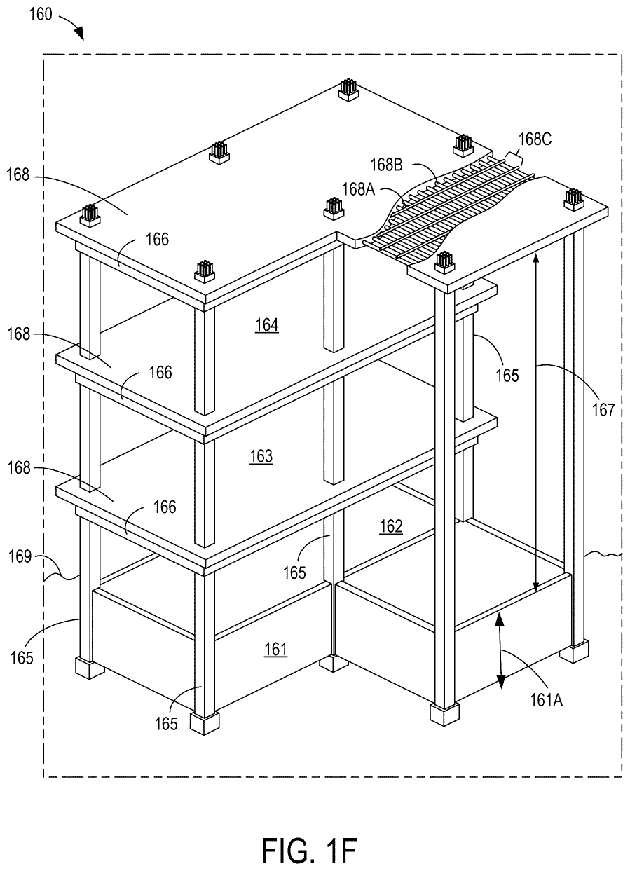

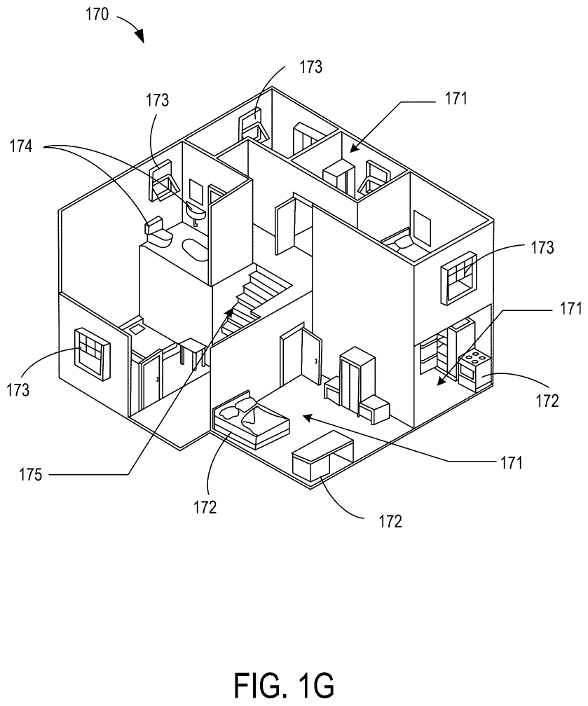

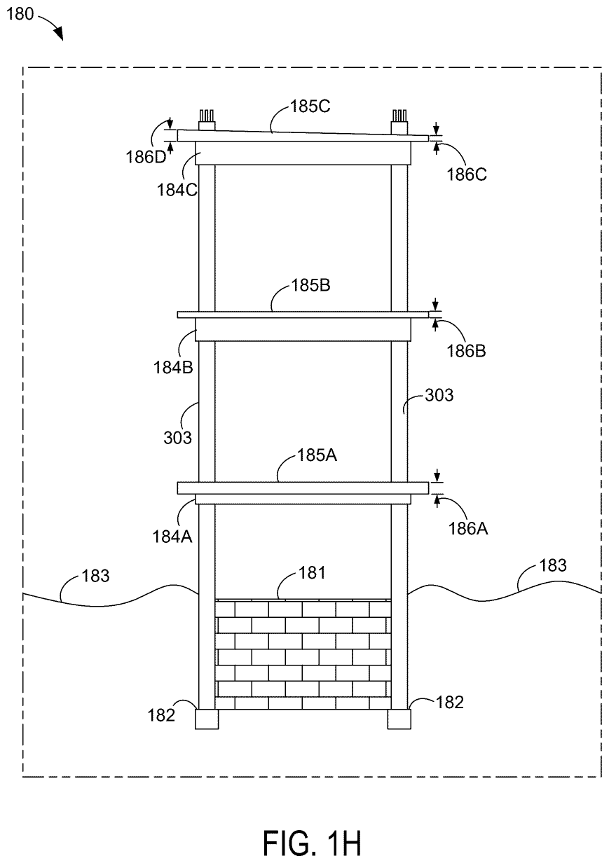

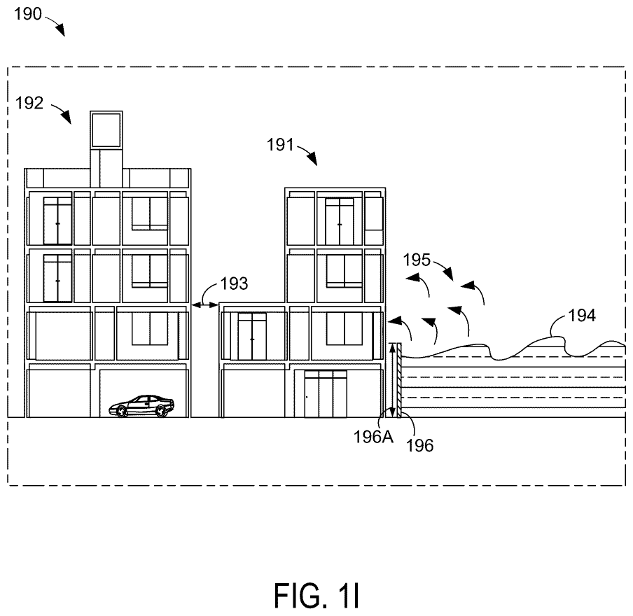

Referring to FIG. 1A, a general flow diagram showing some preferred embodiments of the present invention is illustrated. At step 100, a design plan (which may be a design plan or dynamic architectural design file (e.g., a Revit® compatible file) indicating aspects of a building; is input into a controller or other data processing system using a computing device. The design plan may include an item of a known size, such as, by way of a non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide). For example, in an embodiment where the design plan is a CAD file, the AI engine may directly interpret the scale and dimensions without needing additional user input, enhancing the efficiency of the alignment analysis.

Input of the two-dimensional reference into the controller may occur, for example, via known ways of rendering an image as a vector diagram, such as via a scan of paper-based initial drawings; upload of a vector image file (e.g., encapsulated postscript file (eps file); adobe illustrator file (ai file); or portable document file (pdf file). In other examples, a starting point for estimation may be a drawing file in an electronic file containing a model output for an architectural floor plan. In still further examples, other types of images stored in electronic files such as those generated by cameras may be used as inputs for automated processes that determine alignment with requirements of a code.

In some embodiments, the design plan may be file extensions that include but are not limited to: DWG, DXF, PDF, TIFF, PNG, JPEG, GIF, or other type of files based upon a set of engineering drawings. Some design plans may already be in a pixel format, such as, by way of a non-limiting example, a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charged couple device (CCD) to create the file containing the image on the smart device. For example, a construction site manager may use a smart device to capture and upload an image of an in-progress building, enabling real-time alignment checks by the AI engine.

In some embodiments, a degree of the processing as described herein may be performed on a controller, which may include a cloud server, a standalone computing device or a smart device. In many examples, the input file may be communicated by the smart device to a controller embodied in a remote server. In some embodiments, the remote server, which is preferably a cloud server, may have significant computing resources that may be applied to AI algorithmic calculations analyzing the image.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly. For example, a dedicated AI chip may expedite the processing of large-scale architectural plans, enabling quicker turnaround times for alignment reports.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software-only embodiments of the AI engine may be run on one or more of: local computers, cloud servers, or on smart device processing environments.

At step 101, a controller may determine if a design received into the controller includes a vector diagram. If a file type of the received design plan, such as an input architectural floor plan technical drawing, includes at least a portion that is not already in raster graphics image format (for example, that it is in vector format), then the input architectural floor plan technical drawing may be transformed to a pixel or raster graphics image format in step 102. Vector-to-image transforming software may be executed by the controller, or via a specialized processor and associated software. For example, a construction company using legacy design files may require conversion of those files into a raster format before the AI engine can assess them for modern alignment standards.

In some embodiments, the controller may determine a pixel count of a resulting rasterized file. The rasterized file will be rendered suitable for a controller hosting an artificial intelligence engine (“AI engine”) to process, and the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric.

At step 103, training (and/or retraining) of the AI engine is performed. Training may include, for example, manual identification of patterns in a rasterized version of an image included in a design plan that correspond with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan. For example, during training, the AI engine may be fed a series of design plans with known clearance issues to improve its ability to detect similar issues in future analyses.

In some embodiments, and in a non-limiting example, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, stairs, and the like.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. Using deep artificial neural networks, original architectural floor plans (along with any labeled boundaries) may be used to train AI models to make predictions about what is inside a boundary. In exemplary embodiments, the AI model may be given over about 50,000 similar architectural floor plans to improve boundary-prediction capabilities.

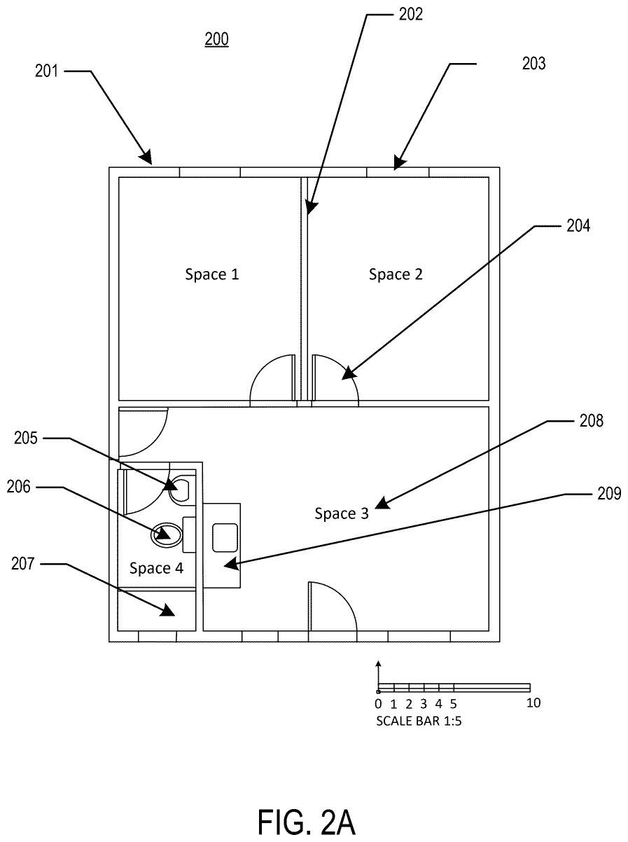

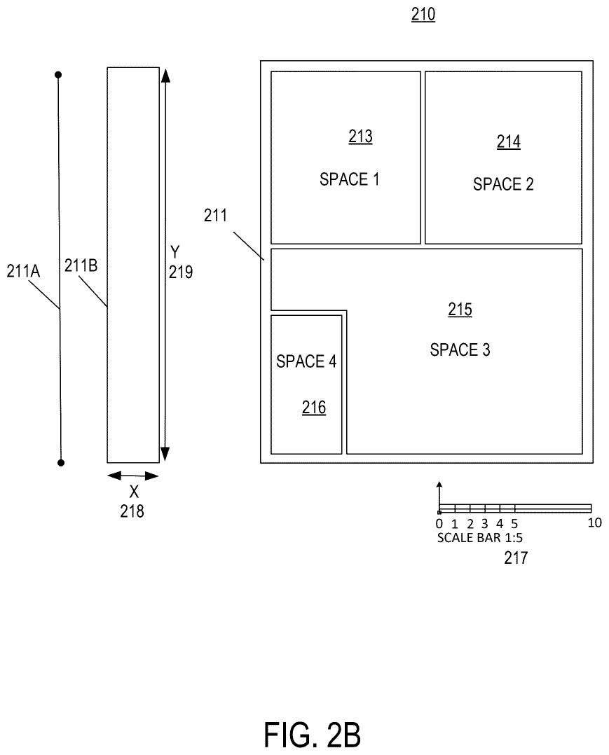

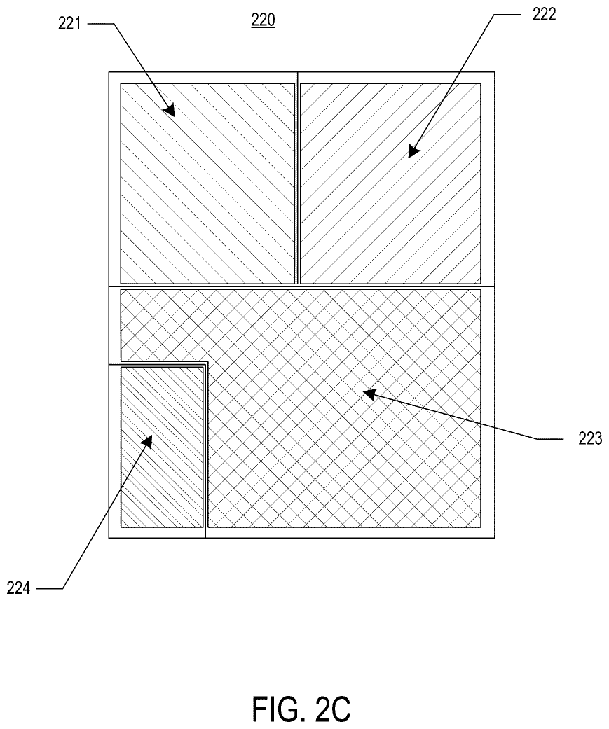

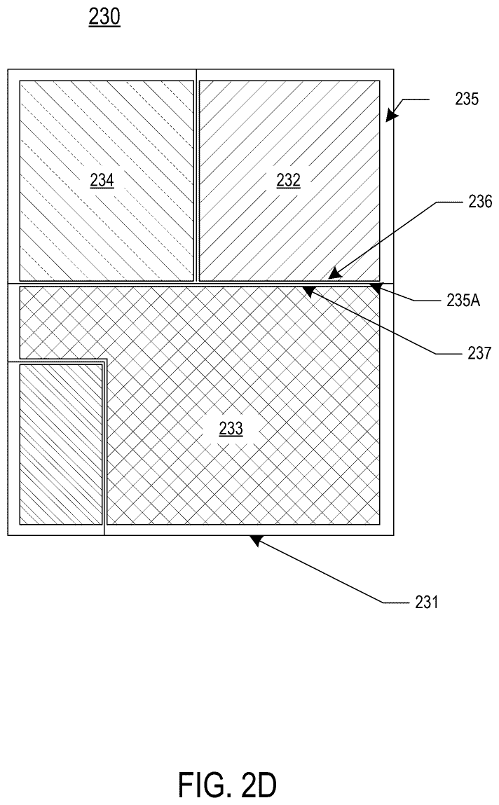

In some embodiments, a training database may utilize a collection of design data that may include one or more of: a combination of a vector graphic two-dimensional references such as floor plans and associated raster graphic versions of the two-dimensional references; raster graphic patterns associated with features; and a determination of boundaries may be automatically or manually derived. (An exemplary AI-processed two-dimensional reference that includes a design pan and/or a floorplan 210, with boundaries 211 predicted, is shown in FIG. 2B, based on the floorplan of FIG. 2A.)

In still another aspect, in some embodiments, a controller may access data from various types of Building Information Modeling (BIM) and Computer Aided Drafting (CAD) design programs and import dimensional and shape aspects of select spaces or portions of the designs as they relate to a design plan. For example, a BIM model may provide detailed information about the materials used in different parts of a building, which the AI engine can analyze to assess alignment with preferences.

At step 104, an AI engine may ascertain features included in the design plan, the AI engine may additionally ascertain that a feature is located within a particular set of boundaries or external to the set of boundaries. Features may include, by way of a non-limiting example, one or more of: architectural aspects, fixtures, duct work, wiring, piping, or other items included in a two-dimensional reference submitted to be analyzed. For example, the AI engine may recognize that certain areas need more clearance due to equipment safety preferences, suggesting adjustments to wall placements. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as a line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shapes.

At step 105, a scale (e.g.; FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale for a particular image, drawing or other two-dimensional reference. The drawing scale may, for example, be in inches: feet, centimeters: meters, or any other appropriate scale. For example, in an embodiment where the design plan is a scanned image of a historical building, the AI engine may require manual input of the scale by the user to accurately assess dimensions, as the original scale may be inconsistent or missing.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. In another embodiment, if the exact dimensions of a common element like a standard door are known, the AI engine may use that as a reference to automatically adjust the scale across the entire plan.

At step 106, a controller is operative to generate a user interface with dynamic components that may be manipulated by one or both of user interaction and automated processes. Any or all of the components in a user interface may be converted to a version that allows a user to modify an attribute of the component, such as the length, size, beginning point, end point, thickness, or other attribute. In some embodiments, a boundary may be treated as a component and manipulated in like manner. For example, a user may adjust the boundary of a room to account for planned renovations, and the AI engine may then automatically recalculate occupancy limits and travel paths based on the new dimensions.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. For example, in a renovation project, the AI engine may suggest the addition of sound resistant walls in certain areas, which the user can accept or modify via the interface. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes. For example, the AI engine may allow a user to define a vertex at the corner of a room and then drag it to reshape the room's dimensions, automatically adjusting all related parameters such as area and perimeter.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of a non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step transform features such as windows, doorways, vias and the like to other features and may remove them and/or replace them as elements—such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and Non-Uniform Rational Basis Spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons. In some embodiments, when an L-shaped corner is detected, the AI engine may recognize it as a standard 90-degree angle and automatically adjust nearby elements to conform to this, so that all connected walls and components align perfectly.

In another aspect, in some embodiments, one or both of a user and a controller may indicate a component type for a boundary. Component types by include, for example, one or more of line segments, polygons, multiple line segments, multiple polygons, and combinations of line segments and polygons. For example, a user may specify that a particular boundary represents a load-bearing wall, prompting the AI engine to apply additional alignment checks related to structural integrity.

At step 106A, In some embodiments, components presented in an interactive user interface may be analyzed by a user and refinements may be made to one or more components (e.g., size, shape and/or position of the component). In some embodiments, user modifications may also be input back to the AI engine train the AI engine. User modifications provided back to the AI Engine may be referenced to make subsequent AI processes more accurate and/or enable additional types of AI processes. For example, if a user repeatedly modifies door placements, the AI engine may learn to preemptively suggest similar adjustments in future design analyses, improving its predictive capabilities.

At step 108, a controller (such as, by way of a non-limiting example, a cloud server) operative as an AI engine may create AI-predicted dynamic boundaries that are arranged to form a representation of a submitted design plan that does not include the boundaries that bound it.

In various embodiments, a boundary may be used to define a unit, such as a residential unit, a commercial office unit, a common area unit, a manufacturing area, a recreational area, a dining area, or other area delineated according to a permitted use. For example, in a mixed-use building, the AI engine may automatically differentiate between commercial and residential spaces, applying distinct alignment rules to each.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may, in turn, be used as a basis for modifying an occupant load, defining a travel path, classifying a space, or other purposes. For example, in a healthcare facility, adjusting the size of a patient room may prompt the AI to reanalyze the design for alignment with healthcare regulations regarding patient egress and equipment spacing.

For example, a change in a boundary may make an area larger. The larger area may be a basis for an increase in storage capacity, a larger item of equipment, more retail space, more dining space, or more occupancy load. The larger area may also result in a longer travel path from the furthest point in the defined area to a point of egress (e.g.; if a user chooses to use a worst case in determining an egress route). In a school building, increasing the area of a classroom may trigger the AI engine to recommend additional exit doors or adjustments to the hallway width to accommodate a larger number of students during travel.

At step 109, one or both of the user and an automated process on a controller may specify a desired clearance parameter and/or a required clearance such as for equipment installation and operation determination based upon the AI generated boundaries. In some embodiments, a user may specify a set of preferences, such as, for example, a drop-down menu may indicate available clearance parameters, and a user may select one or more sets of clearance parameters to apply to the floor plan. Accordingly, by way of a non-limiting example, a user may select that a set of floorplans be analyzed with the AI engine to assess actual clearance values and available clearance parameters. For example, in an industrial setting, a user may specify minimum clearance around heavy machinery, and the AI engine may automatically assess and flag any areas that do not meet the required space for safe operation.

At step 110, a set of parameters for a selected clearance is applied to some or all of the dynamic components generated via the AI engine. For example, if the clearance parameters specify that all hallways in a hospital must be wide enough for two gurneys to pass each other, the AI engine will analyze all relevant components and flag any non-compliant areas.

At step 111, the user interface or other output may be caused to display an indication of whether a design plan adheres to requirements of the selected clearance and/or open space parameters. In some preferred embodiments, a list of conditions required in order for a building to adhere to the clearance parameters, and an indication of why one or more of the conditions is met may be illustrated within a user interface or other output. For example, in a warehouse environment, the AI engine may generate a report indicating that certain areas meet the required clearance for vehicle and/or forklift maneuverability, while others need adjustments.

In generating a value for such as variable, the AI engine and/or the user may need to that one or more boundaries define a specific type of area, such as a bedroom, a hallway, or a stairwell. Each specific type of area may have specified variables associated with it. By way of a non-limiting example, the user interface may employ a simple yes/no indicator for alignment with a requirement of a selected code. In other embodiments, the user interface may visually indicate a portion of the design plan that was referenced in determining whether a desired clearance is present or not. For example, if a code requires that all bedrooms have at least one egress window, the AI engine may highlight compliant rooms in green and non-compliant ones in red.

Some specific embodiments may include a first portion of a user interface with delineated conditions for code alignment, such as, for example, a listing of sections of a code, an ability for a user to select a specific section of the code, and a link that brings up an interface with visual indicators illustrating a state of alignment (or non-alignment as the case may be) with the user selected section of code. For example, in a commercial kitchen design, the user may select a section of the health code related to ventilation, and the interface may then display areas of the kitchen that meet or fail to meet the required airflow standards.

At step 112, in another aspect, the present invention may use the AI engine to generate suggested modifications to a design plan in order to transition the design plan from a state of not meeting clearance requirements to a state that does meet clearance requirements. For example, if a corridor is too narrow to meet accessibility standards, the AI engine may suggest relocating a wall or changing the layout of adjacent rooms to widen the corridor.

At step 113, a conclusion of whether a design plan meets clearance requirements may be displayed in an interactive user interface in an integrated fashion in with a replication of the two-dimensional reference (such as the design plan, architectural floor plan or technical drawing). The user interface may also be shown in a form that includes user modifiable elements, such as, but not limited to: polylines, polygons, arcs, circles, ellipses, splines, line segments, icons, points and other drawing features or combinations of lines and other elements. For example, if a building's egress routes are flagged as non-compliant, the user can interactively modify the routes directly within the interface, and the AI engine may immediately reanalyze the new layout for alignment.

Referring now to FIG. 1B, a high-level diagram illustrates components included in a system 120 that uses AI to generate an interactive user interface 125 and programmable apparatus (controller) 123 operative to execute method steps useful in determining alignment with a design plan or other architectural description. For example, in a commercial building project, the AI engine may analyze the placement of load-bearing walls and suggest adjustments to meet seismic alignment codes.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of a non-limiting example, one or more of: walls, doors, doorways, hallways, rooms, residential units, office units, bathrooms, stairs, stairwells, windows, fixtures, real estate accouterments, and the like. For example, the AI engine may analyze a scanned image of a historical building's blueprint so that modern accessibility standards are met, such as sufficient doorway widths for wheelchair access.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. Presentation of the two-dimensional reference may include, for example, scanning a hardcopy version of the two-dimensional document into electronic format and transmitting the electronic format to the controller 123 running the AI engine.

The controller is operative to generate a user interface 125 on a user computing device 126. The user computing device may include a smart device, workstation, tablet, laptop, or other user equipment with a processor, storage, and display. In some embodiments where multiple stakeholders are involved, such as architects and engineers, each can access the user interface on their respective devices, enabling collaborative real-time adjustments to the design.

The user interface 125 includes a reproduction of the pictorial representation 122 and an overlay 124 with one or more user manipulatable components, such as, by way of non-limiting examples: boundaries, line segments, polygons, images, icons, points, and the like. The line segments may have calculated lengths that may be mathematically manipulated and/or summarized. Aspects such as polygons, line segments, shapes, icons, and points may be counted, added, subtracted, extrapolated, and other functions performed on them. For example, in a hospital design, the AI engine may automatically calculate the lengths of travel routes, and the user can adjust these routes within the interface if they do not comply with local preferences.

In addition, renditions of the user interface 125 may be created and saved, and/or communicated to other users, or controllers, compared to subsequent interface renditions, archived and/or submitted to additional AI analysis. For example, a user may save an initial alignment report and then generate a new report after making suggested changes, allowing for a comparison of before-and-after alignment status.

In some embodiments, a first user interface 125 rendition, may be modified by a user to create a second user interface 125, and submitted to AI analysis to ascertain alignment with a selected code. For example, after initial analysis, a user may modify the layout of a retail store to enhance customer flow and then resubmit the design to the AI engine to determine if it still meets equipment operation preferences. Some embodiments may also calculate costs, expenses, man hours or other variables associated with changes to a design plan in order to bring the design plan into alignment. For example, if the AI engine identifies that a wall needs to be moved to comply with accessibility regulations, it may also estimate the cost of this modification, including labor and materials. Change order renditions provided as options to bring a design plan into alignment with a selected code may also be provided with a unique identifier, time and/or date stamped to create a continuum of work, as related to original projects and alignment-initiated changes. In large-scale projects, this feature allows project managers to track alignment changes over time, so that all modifications are documented and easily retrievable for future reference or audits. Each of the items in the continuum of work may be stored and subsequently used for ascertaining the eventual alignment of a building with each selected code.

Referring now to FIG. 1C, a schematic diagram illustrates an exemplary design plan floor layout 130, which represents a portion of a building and comprises a plurality of units 135, 136, and 137. These units are spatial divisions within the building and may correspond to various functional areas such as rooms, offices, corridors, hallways, kitchen areas, water closet areas, conference rooms, common areas, drawing rooms, and bedrooms. Each unit is designed to fulfill specific requirements based on the intended use of the building, and the layout of these units is integral to the overall design of the structure.

The controller 123, operating an AI engine, is configured to analyze each unit 135, 136, and 137 by identifying and assessing various design parameters. These parameters include, but are not limited to, structural elements 138 and 139, and fixtures 134A, 134B, and 134C. Structural elements 138-139, which are useful for maintaining the building's integrity, may include vertical load-bearing columns (138) that support the weight of the building and transfer it to the foundation. Horizontal beams (139) span between columns and walls, distributing loads across the structure. Slabs, which form the floors and ceilings of each unit, are also analyzed for their ability to support the intended loads.

In addition to columns, beams, and slabs, the structural analysis conducted by the AI engine extends to other useful elements such as load-bearing walls, which serve the dual purpose of dividing spaces and supporting the structure above them. Shear walls, which are designed to resist lateral forces such as those caused by wind or seismic activity, are also included in the analysis. These walls are strategically placed within the building's design to provide additional stability against horizontal forces. Furthermore, core structures that house elevators, stairwells, and mechanical shafts may also be analyzed for their role in providing vertical circulation and housing building services.

The AI engine also evaluates various fixtures within each unit, represented by labels 134A, 134B, and 134C. Fixtures may include plumbing installations such as sinks, toilets, showers, and bathtubs, which are connected to the building's water supply and drainage systems. Electrical fixtures, including outlets, switches, and lighting components, are analyzed for their placement and functionality within each unit. HVAC components, such as vents, ducts, and air conditioning units, are evaluated for their ability to maintain the desired indoor climate.

Other fixtures analyzed by the AI engine may include security systems, including cameras and access control panels, which are also included in the analysis to provide monitoring and protection against unauthorized access. Communication devices, such as intercoms and network outlets, are evaluated for their role in facilitating communication within the building.

Windows and skylights, which provide natural light and ventilation, are assessed for their placement and size to maximize energy efficiency and occupant comfort. Doors, including both manual and automatic types, are analyzed for their ability to control access between different spaces within the building. Additional fixtures, such as elevators, escalators, and ramps, may also be evaluated for their role in facilitating movement between floors, particularly in multi-story buildings. Handrails and guardrails, which provide safety on stairs and ramps, are also considered in the analysis.

The AI engine's comprehensive analysis of both structural elements and fixtures within each unit allows for a detailed evaluation of the building's design. By converting the static design plan into dynamic components, the AI engine can assess the alignment of each unit with relevant building deployment objectives and standards. This process may include analyzing the interaction between structural elements and fixtures to identify potential conflicts and areas where modifications may be necessary to meet regulatory requirements.

In some embodiments of the present invention, the AI engine is configured to analyze structural elements such as columns 138 to determine their dimensions, including height, width, and length. These dimensions are useful for assessing the structural integrity of the building. The height of a column 138 is directly related to the overall height of the structure and the loads it must support, including the weight of floors, ceilings, and any additional loads imposed by occupants or equipment. The width and length of a column 138 are equally important as they determine the cross-sectional area, which influences the column's ability to withstand axial loads without buckling. The AI engine measures these dimensions by referencing the design plan, using a scaling process, and cross-references them with standard building deployment objectives and engineering principles to assess whether the columns are appropriately sized for their intended purpose.

The AI engine may also determine the number and type of reinforcement bars (rebars) within each column 138. These rebars, which can include materials such as steel bars or iron rods, are embedded within the concrete of the column 138 to enhance its load-bearing capacity. The presence and arrangement of rebars may be helpful for column 138 to resist tensile stresses and shear forces that may occur due to various loads, including seismic activity or wind pressure. By determining the quantity, diameter, and spacing of these rebars, the AI engine can assess whether the reinforcement is adequate for the expected loads. For example, a column designed to support significant weight over multiple stories may incorporate a higher number of thicker rebars spaced closer together to prevent failure under load.

The AI engine's analysis extends to measuring the distance 138A between adjacent columns 138. This distance is a vital factor in determining the overall structural integrity of the building, as it affects how loads are distributed across the structure. Columns 138 that are spaced too far apart may lead to excessive bending moments in the beams 139 that span between them, potentially causing structural failure. Conversely, columns 138 that are too close together may result in an inefficient use of materials and space. The AI engine calculates the distance 138A between columns 138 by considering the load-bearing specifications, the type of materials used, and the intended use of the building. For example, in a high-rise office building, the AI engine may determine that the distance 138A between columns 138 should be minimized to support the additional weight of multiple floors, while in a large open-plan warehouse, the distance 138A between columns 138 may be maximized to allow for unobstructed space.

Similarly, the AI engine may analyze beams 139, which transfer loads from the floors above to the columns 138 and ultimately to the foundation of the building. The AI engine assesses the dimensions of beams 139, including their length, depth, and width, to determine their load-bearing capacity. The depth of a beam, for example, is directly related to its ability to resist bending under load; deeper beams can generally support more weight. The AI engine also evaluates the material composition of beams, whether they are constructed from steel, concrete, or wood, and compares these factors against the expected loads to determine if the beams are adequate for the design. Additionally, the AI engine may analyze the connections between beams 139 and columns 138 to assess their ability to transfer loads effectively. Proper connections are useful for maintaining the structural integrity of the building, particularly in areas subject to high loads or lateral forces.

In addition to columns and beams, the AI engine may analyze other structural elements, such as slabs and load-bearing walls. Slabs, which form the floors and ceilings of the building, are evaluated for their thickness, reinforcement, and material composition. The AI engine assesses whether the slabs can support the expected live loads (e.g., people, furniture, equipment) and dead loads (e.g., the weight of the slab itself and any permanent fixtures) without excessive deflection or cracking. The analysis of load-bearing walls focuses on their placement, thickness, and the materials used to determine their ability to support the weight of the structure above them.

In some embodiments of the present invention, the AI engine is configured to predict the load within a building or a specific unit (e.g., units 135-137) by analyzing various factors such as the area of the units, the proposed use of the building, predicted occupancy load, and the types of fixtures installed within each unit. This predictive analysis is used in determining the overall structural specifications of the building and in assessing alignment with relevant building deployment objectives.

The area of each unit is a primary factor in predicting the load that the building or individual units will need to support. The AI engine calculates the area of each unit by analyzing the dimensions provided in the design plan (or using a scale, as discussed in FIG. 2B). Larger areas generally indicate a greater load, as they typically accommodate more occupants, furniture, and equipment. For example, a large conference room or open office space (such as units 135 or 136) may be expected to bear a higher load compared to smaller, private offices or bedrooms. The AI engine takes into account the floor area to determine the distribution of live loads, such as those generated by people and movable objects, and dead loads, such as the weight of permanent structures and fixtures within the space. The calculated area directly informs the AI engine's load predictions, allowing it to assess the adequacy of the structural elements designed to support these loads.

The proposed use of the building is another useful design factor that influences load predictions. Different uses of a building generate different types of loads due to variations in occupancy density, the nature of activities conducted within the building, and the types of equipment or furniture preferred. For example, a residential building will have a different load profile compared to a commercial office space or an industrial warehouse. In a residential building, the load is primarily driven by the occupancy and household furniture, while in an office space, the load is influenced by the density of workstations, office equipment, and common areas like conference rooms. An industrial warehouse, on the other hand, may experience higher loads due to heavy machinery, storage racks, and goods. The AI engine analyzes the intended use of each unit (or of the building itself), using predefined standards and load factors associated with different building types, to predict the load preferences accurately.

Occupancy load is a key determinant of the live load that the building or unit will experience. The AI engine predicts the occupancy load by referencing the design specifications and relevant building deployment objectives that define occupancy limits based on the type of space and its intended use. For example, a large conference room (e.g., unit 136) in an office building may be designed to accommodate a high number of occupants during meetings, while a bedroom in a residential unit (e.g., unit 137) may have a much lower occupancy limit. The AI engine uses these occupancy limits, combined with data on standard occupant weight and movement, to calculate the live load generated by occupants. This calculation may also include factors such as peak occupancy times, which may significantly increase the load on the structural elements during certain periods, and the distribution of occupants across different areas of the building.

The types of fixtures installed within each unit also play a significant role in determining the overall load. Fixtures 134A-134C such as plumbing installations, HVAC systems, electrical fixtures, and furniture contribute to the dead load that the building must support. The AI engine accesses a database containing the weight and specifications of various fixtures, which may include items such as sinks, toilets, bathtubs, lighting fixtures, and built-in furniture. By referring to this database, the AI engine can calculate the cumulative weight of the fixtures in each unit. For example, a bathroom (part of unit 137) with heavy plumbing fixtures will have a higher dead load compared to a standard bedroom with minimal fixtures. The AI engine incorporates these fixture weights into its load predictions, providing a comprehensive assessment of the total load that each unit will impose on the building's structural elements.

Once the AI engine has predicted the load within the building or individual units 135-137, it references different sets of building deployment objectives to analyze alignment. Building deployment objectives are regulatory standards that vary based on factors such as the intended use of the building, the type of unit, and the specific structural elements involved.

In some cases, more than one type of building deployment objective may be applied to determine alignment for a single unit (e.g., unit 135 or 137). This is because different aspects of a unit may fall under the jurisdiction of various codes. For example, a unit designed as a kitchen area 133 (part of unit 135) will need to comply with general structural codes, plumbing codes, equipment operation preferences, maintenance preferences, and aesthetic preferences. The AI engine cross-references these multiple codes to determine if all aspects of the unit 135 are aligned with the user preferences. This multi-code analysis is particularly important in complex units that serve multiple functions, such as a commercial space that includes both office areas and storage facilities. The AI engine must consider the different load preferences and best practices for each functional area within each unit, leading to a comprehensive alignment analysis.

In some embodiments of the present invention, the AI engine may be configured to analyze the design plan 130 to assess various travel paths 131 that connect different units within the building. Paths 131, as depicted in the design plan 130, represent the hallways, corridors, and other passageways that facilitate movement between units such as 135, 136, and 137, and to an exit point of the building. These paths are useful for the functionality and ease of use of the building, as they not only enable the day-to-day movement of occupants but also serve as routes for equipment or material transport travel, or for automation, such as UGVs and/or UAVs.

The AI engine systematically evaluates each travel path 131 to determine its effectiveness in connecting the different units 135-137 within the building. This analysis may include calculating the distance 131A from a furthest point in the building to an entrance/egress point 132. The egress point is a designated exit from the building, which in this case, may be a stairwell 132A as shown in the blown-up view. The distance 131A may be used in alignment analysis, particularly in the context of emergency travel. The AI engine calculates this distance 131A by mapping the layout of the building and identifying the longest possible route that an occupant may need to travel to reach a desired destination, such as, for example an entrance/egress point 132.

In addition to distance analysis, the AI engine evaluates the width of the paths 131, which is another important factor in providing efficient travel. The width of a path directly affects the number of people who may pass through the corridor abreast,. The AI engine measures the width of each travel path 131 and compares it to the minimum width requirements specified in building deployment objectives. For example, the IBC mandates specific width requirements based on the occupant load of the building and the function of the path. In a high-occupancy office building (e.g., unit 136), wider paths may be required to accommodate the flow of people during peak times or emergencies.

The AI engine's analysis extends to the stairwells 132A, which serve as the primary egress points during travel. The stairwell 132A, as illustrated in the blown-up view, is a useful component of the building's egress system. The AI engine calculates the width 132B of the stairwell 132A to determine whether it meets the regulatory standards for emergency travel. The width 132B of the stairwell 132A is used for accommodating the flow of occupants descending from upper floors. The AI engine assesses and compares this width against the preferences associated with best practices and user input, which dictate widths based on a deployment use and building aspects (e.g., number of floors).

The analysis of stairwell width 132B is particularly important in buildings with multiple floors or high occupancy levels. In such cases, the stairwell 132A must be wide enough to allow for a rapid and orderly travel, preventing bottlenecks and reducing the risk of injury. The AI engine considers various factors, such as the occupant load per floor and the expected travel time, to determine the adequacy of the stairwell width. If the stairwell 132A is found to be too narrow, the AI engine may suggest design modifications, such as widening the stairwell 132A or adding additional stairwells to distribute the occupant load more effectively.

The AI engine's comprehensive analysis of paths 131 and entrance/egress points 132, including the distance 131A and stairwell width 132B, is integral to the overall alignment assessment of the building's design. By evaluating these factors, the AI engine may verify that the design facilitates safe and efficient travel. This analysis also helps architects and engineers to identify potential issues early in the design process, allowing them to make necessary adjustments to meet regulatory standards and enhance the safety of the building's occupants.

Furthermore, the AI engine may analyze the configuration and accessibility of entrance/egress points 132 in relation to the units 135-137 within the building. This includes evaluating the proximity of entrance/egress points 132 to high-occupancy areas, such as conference rooms or common areas, and determining whether additional egress points are needed to improve travel efficiency. The AI engine may also assess the visibility and signage associated with entrance/egress points 132, as clear and accessible for transport of items, persons, and/or machines (e.g.; UAVs and UGVs).

In some embodiments of the present invention, the AI engine may be configured to determine a set of conditions specified by a building deployment objective established by an user objective. This determination may be based on various design factors, each of which contributes to the overall analysis of the building's alignment with relevant user objectives. These design factors may include the proposed use of the building, the types of the units 135-137, the areas of the units 135-137, the number of floors within the building, the floor type of each unit (135-137), the intended or predicted occupancy for the units 135-137, and the location of the building.

The proposed use of the building is one of the primary design factors that influence the set of conditions determined by the AI engine. Different types of buildings, such as residential, commercial, industrial, or educational facilities, are subject to different building deployment objectives due to the varying nature of activities conducted within them. For example, a residential building may include specific conditions related to occupant access, building rules (and/or Home Owner Association “HOA” guidelines or rules) and access, whereas a commercial office building may have additional preferences related to structural load capacity, equipment and device access, and energy efficiency. The AI engine uses the proposed use of the building and best practices for the intended use. These conditions may include minimum room sizes, and preferences for ventilation and natural lighting.

The type of the units 135-137 within the building is another useful factor that affects the set of conditions determined by the AI engine. The type of a unit may vary widely, encompassing spaces such as bedrooms, offices, conference rooms, kitchens, bathrooms, equipment areas, and storage areas.

Each type of unit may have standard or unique specifications based on the unit's function. For example, a kitchen unit may adhere to objectives related to ventilation, psychological impact, aesthetics, sanitation, plumbing and waterproofing standards. The AI engine identifies the type of each unit and cross-references it with the applicable objectives to determine the preferred set of conditions. For a conference room, this may include conditions for acoustic insulation, multi-person ingress and egress, and comfortable populations. For a bedroom in a residential building, the conditions may focus on natural light, ventilation, spaciousness. and privacy preferences.

Larger units may be subject to different conditions compared to smaller ones, particularly in terms of structural support, and preferred deployment use. The AI engine may calculate an area of a unit based upon a design plan and compare it against a minimum and maximum area preferred use specified in the relevant building deployment objectives. For example, a large open-plan office space may entail additional structural supports and larger travel paths to accommodate the higher occupancy, while a small storage room may need specific conditions related to supply chain use and access control. The AI engine may also use the unit's area to determine conditions such as preferred ceiling height, the minimum size of windows for natural lighting, and the maximum permissible distance to an egress point.

A number of floors within the building is another important factor that an AI engine may consider when determining a set of preferred conditions. The AI engine assesses a total number of floors and references objectives that indicate a necessary structural load capacities, multi traveler access stairwells, and elevator preferences. For example, a high-rise building may need reinforced foundations and load-bearing walls to support the additional weight of multiple floor. The AI engine also considers vertical transportation systems such as elevators, escalators, and ramps, for determining if they meet the preferences for speed, capacity, and accessibility.

The floor type of a unit is another factor that the AI engine analyzes. The floor type refers to whether the unit is located on the ground floor, a typical floor, or a top floor, each of which has specific preferences. Ground floor units, for example, may prefer additional floodproofing if the building is located in a flood-prone area. Ground floor units may also need a strong load-bearing structure (e.g., columns, beams, and slabs) to support upper floors. Units on higher floors may have associated preferences, such as higher water pressure plumbing, doors and windows, to provide access to views. The AI engine evaluates the floor type and determines the necessary conditions, such as enhanced structural support for top-floor units exposed to wind loads or seismic activity, or additional insulation for ground-floor units to prevent moisture ingress.

The intended or predicted occupancy for the first unit may be another factor in determining the preferred conditions. Occupancy levels are one variable to consider in determining preferred space available for a desired building deployment use. The AI engine predicts an expected occupancy based on the unit's type, area, and proposed use, then cross-references building deployment objectives that specify requirements based on occupant density. For example, a high-occupancy space like a theater or conference room may prefer wider travel paths and larger exits to accommodate quick travel. The AI engine calculates these preferences and determines conditions such as the number of preferred entrances/exits, the width of doors and corridors, and the capacity of HVAC systems to maintain air quality in densely populated spaces.

The location of the building is another vital factor that influences the set of conditions required by building deployment objective. Different geographical locations are subject to varying environmental conditions, such as seismic activity, wind loads, snow loads, and flood risks, all of which impact the building's design and alignment requirements. The AI engine analyzes the location by referencing building deployment objectives that address these environmental factors. For example, a building located in a seismic zone must adhere to stricter structural objectives designed to resist earthquake forces, such as the installation of shear walls and flexible joints. Similarly, a building in a coastal area may need to meet wind resistance standards and incorporate corrosion-resistant materials. The AI engine determines the specific conditions required for the building's location, such as the need for elevated foundations in flood zones or reinforced roofs in areas with heavy snowfall.

In determining the set of conditions preferred by building deployment objectives, the AI engine often references more than one type of building deployment objective to determine comprehensive alignment. For example, a single unit such as a kitchen may need to meet structural objectives, plumbing objectives, and deployment objectives. The AI engine cross-references these objectives to identify overlapping preferences and potential conflicts, so that the design meets all applicable standards. This multi-objective analysis is particularly important in mixed-use buildings or complex units that serve multiple functions. For example, a mixed-use building with residential, commercial, and industrial units may prefer different sets of objectives for each type of unit, and the AI engine must integrate these objectives to produce a cohesive set of conditions that cover all aspects of the building's design.

Referring now to FIG. 1D, an exemplary AI-powered system 140 in accordance with some embodiments of the present invention is illustrated. The AI-powered system 140 is designed to perform alignment analysis of design plans for buildings by leveraging advanced computational methods. The AI-powered system 140 may comprise a controller 141, which serves as the processing unit responsible for executing various tasks involved in the alignment analysis. The controller 141 may be integrated into a user device 145, which can take on various forms depending on the specific application and user preferences.

The user device 145 may comprise various types of devices such as a laptop, tablet, smartphone, or a specialized handheld device designed specifically for architectural and engineering applications. These devices are equipped with the necessary hardware and software to facilitate the alignment analysis process. The user device 145 may include a processor, which is the core computational unit that executes instructions, and a memory or storage area that stores executable software codes or programs. These programs, when executed by the processor within the controller 141, enable the user device 145 to carry out complex analyses on the design plans of at least a portion of a building.

The memory or storage area within the user device 145 may store a variety of data and software tools that are used during the alignment analysis. This may include the design plans, building deployment objectives, and any previous analysis results. The software stored in the memory may specifically be designed to interact with the AI engine running within the controller 141. When the software is executed, it triggers the processor to perform a series of operations that analyze the design plans, identify alignment issues, and suggest modifications as needed.

The user device 145 also comprises a display screen which may be a touchscreen display. The display is responsible for generating a first interactive user interface that visually presents the design plans to the user. The user interface is designed to be interactive, allowing the user to engage directly with the design data. The user interface renders the design plans in a detailed and accessible format, showcasing dynamic components such as walls, beams, columns, and fixtures. These components are presented in a way that allows the user to see their relationships and interactions within the overall building layout.

The dynamic components displayed on the user interface are not static; they are interactive elements that the user can manipulate. The user interface enables the user to modify various parameters associated with these dynamic components. For example, a user may click on a column or beam and adjust its dimensions, position, or material properties directly through the interface. The boundaries of each unit within the design plan may also be displayed, showing the limits of each space and how they connect with other parts of the building. In addition to rendering the design plans and dynamic components, the user interface also displays the results of the alignment analysis.

The user interface may also provide tools for navigating the design plan, zooming in and out, and focusing on specific areas of interest. This allows the user to conduct a thorough review of the entire design plan or to focus on particular components that require closer inspection. The interface also supports the modification of changeable parameters associated with the dynamic components. For example, the user can adjust the height of a column, the width of a path, or the load-bearing capacity of a beam. As these parameters are modified, the AI engine automatically recalculates the alignment analysis to reflect the changes, providing real-time feedback on the impact of the adjustments.

The user device 145 may also be equipped with input devices such as a touchscreen, keyboard, or stylus, allowing the user to interact with the user interface in various ways. These input methods make it easier to perform detailed design work, especially when working with complex or intricate design plans. The user interface is designed to be user-friendly, with intuitive controls and clear visual feedback to guide the user through the alignment analysis process.

The display screen of the user device 145 may also be capable of rendering three-dimensional views of the design plan, providing a more immersive and comprehensive view of the building layout. The 3D visualization allows the user to better understand the spatial relationships between different components and to identify potential issues that may not be apparent in a 2D design plan. The 3D views can be rotated, panned, and zoomed, giving the user full control over the perspective from which they view the design. In some embodiments, the AI engine is capable of creating a 3D visualization for a 2D design plan.

The alignment analysis performed by the AI engine within the controller 141 is based on a set of conditions that are stored in a database or memory area. These conditions are derived from relevant building deployment objectives and standards, which are regularly updated to reflect the latest regulations. The AI engine cross-references the design plans with these conditions to identify any discrepancies or non-compliant elements. The results of alignment analysis are then displayed on the user interface, where the user can review them and make the necessary adjustments to the design plan to achieve alignment.

The user device 145 may also support the saving and exporting of alignment analysis results. Users can save their work at any point, preserving the current state of the design plan and the associated analysis results. The results can be exported in various formats, such as PDF or CAD files, for sharing with other stakeholders. In some embodiments, the AI-powered system 140 allows multiple users to work on a single design plan simultaneously, providing collaborative alignment analysis.

The controller 141 is configured to receive a design plan of at least a portion of a building. Upon receiving the design plan, the controller 141 processes and converts the static design plan into multiple dynamic components. The dynamic components represent various structural and functional elements within the building, which are integral to the analysis and evaluation of the building's alignment with relevant building deployment objectives.

The controller 141 generates a first interactive user interface that visually presents these dynamic components on the user device 145. The dynamic components included in the user interface are interactive, allowing the user to engage with the design in a detailed and meaningful way. Each dynamic component may be associated with one or more changeable parameters, such as dimensions, materials, or positions, which can be modified directly via the first interactive user interface.

In some embodiments, the controller 141 arranges the dynamic components to form a first set of boundaries. The set of boundaries may correspond to at least a portion of a first unit within the building's design. The boundaries are defined by specific measurements, including a respective first length and a first area, which collectively represent the physical limits of the first unit. The controller 141 is capable of performing similar operations for other units within the design plan, systematically arranging dynamic components to create defined spaces within the overall building structure.

The controller 141, through the AI engine, then determines various design factors 142 for the first unit. The design factors 142 are used for assessing the specific preferences and conditions that apply to the first unit within the building. The design factors 142 may include, but are not limited to, the proposed use of the building (e.g., residential, commercial, industrial), the type of the first unit (e.g., kitchen, office, bathroom), the area of the first unit (e.g., square footage), the number of floors within the building, the floor type of the first unit (e.g., ground floor, top floor, or a floor in between), the intended occupancy for the first unit (e.g., maximum number of people), and the location of the building (e.g., urban, rural, coastal). These design factors are useful in determining the specific building deployment objectives and standards that will apply to the first unit for alignment analysis. The AI engine may automatically determine the design factors 142 by analyzing the design plan, or the design factors 142 may be provided by the user as input through the user interface.

Simultaneously, the controller 141 may ascertain the design parameters 143 for the first unit. Design parameters 143 may encompass both structural elements and fixtures within the first unit. Structural elements may include components such as beams, columns, load-bearing walls, slabs, and foundations. These elements are fundamental to the building's structural integrity and are analyzed in detail by the AI engine. Fixtures, on the other hand, refer to installed components such as plumbing fixtures (e.g., sinks, toilets, showers), HVAC components (e.g., air conditioning units, vents), electrical fixtures (e.g., outlets, switches, lighting), and other furniture or appliances (e.g., cabinets, countertops, built-in shelving). The AI engine may automatically determine these design parameters 143 by analyzing the design plan and referencing pre-existing databases (not shown) of structural and fixture specifications.

In some embodiments, determining the design parameters 143 by the controller 141 may also involve calculating and analyzing various dimensional attributes related to the structural elements and fixtures. These attributes may include heights, lengths, distances, relative distances, widths, thicknesses, and angles. For example, the AI engine may determine the precise height of columns within a unit, which is useful for understanding how these columns support the load of the floors above. The length and width of beams are also determined to assess their load-bearing capacity and their ability to span between columns without excessive deflection. Additionally, the determination of design parameters 143 may include calculating the distance between key structural elements, such as the spacing between adjacent columns. Relative distances may also be considered; for example, the AI engine may determine the relative distance between a load-bearing wall and an adjacent column to analyze how these elements work together to support the building's weight.

The determination process further extends to evaluating the thickness of slabs, which impacts their ability to support live and dead loads, such as people, furniture, and permanent fixtures. The AI engine may also determine the depth of foundations to determine if they are adequately designed to bear the weight of the building and resist forces from the surrounding soil. Additionally, the angle at which beams or trusses are installed may be analyzed to confirm that they are properly oriented to manage the loads they carry.

In the context of fixtures, the design parameters 143 may include dimensions such as the height of plumbing fixtures from the floor, the spacing between electrical outlets, and the size of HVAC vents. For example, the AI engine may determine the height of a sink relative to the floor to comply with accessibility standards or the distance between lighting fixtures to provide adequate illumination throughout the first unit. The relative distances between multiple fixtures, such as the spacing between a stove and a refrigerator in a kitchen unit, may also be analyzed to enhance usability and safety.

Furthermore, determining design parameters 143 may involve assessing the rebar (steel bar) configuration within concrete columns and beams. The AI engine may determine the number, diameter, and placement of rebars, which are useful for the structural reinforcement of these elements. For example, the AI engine may analyze whether the rebar spacing within a column is sufficient to provide the necessary tensile strength, especially in regions prone to seismic activity.

Moreover, the AI engine may evaluate the alignment and orientation of structural elements, such as the vertical alignment of columns or the horizontal alignment of beams. These alignments are important so that the load paths within the building are direct and unobstructed, thereby minimizing the potential for structural failures. In some embodiments, the AI engine may also determine the clearances around fixtures and structural elements, such as the distance between a column and a nearby wall or the clearance between an HVAC vent and the ceiling. These clearances are important for maintenance access, air circulation, and alignment with building deployment objectives that dictate minimum spacing preferences for various components.

Once the design factors 142 and design parameters 143 have been determined, the controller 141 proceeds to analyze these inputs to determine a set of conditions 144 required by the relevant building deployment objectives. These codes may be established by user objectives and are stored within a database accessible by the controller 141. The set of conditions derived from these codes is directly dependent on both the design factors and design parameters. For example, a proposed use of the building may be associated with certain preferences, such as, for example, preferences for residential units versus, common areas, or storage areas, and commercial buildings may have entirely different preferences. Similarly, the type of unit and its structural elements may influence the specific conditions that must be met, such as equipment operation preferences, load-bearing preferences, and accessibility preferences.

The AI engine, leveraging its computational capabilities, cross-references the design factors 142 and parameters 143 with the relevant building deployment objectives to generate a tailored set of conditions 144 that apply to the first unit. This set of conditions 144 may include but are not limited to the preferences such as minimum ceiling height, structural load capacities, energy efficiency standards, and accessibility provisions. Multiple relevant building deployment objectives may be used to determine alignment for a single unit, particularly if the unit serves multiple functions or falls under different regulatory categories. For example, a commercial kitchen may need to comply with both structural codes related to load-bearing elements and health codes governing sanitation and food preparation areas.

Finally, the controller 141 may indicate within the first interactive user interface of the user device 145 whether the building, or the specific unit in question, complies with the determined set of conditions preferred by the building deployment objectives. The user interface provides clear visual feedback, highlighting areas of the design plan that meet the standards as well as those that do not. If the first unit or building is not in alignment, the user interface may also suggest modifications to bring the design into alignment with the preferred conditions. These suggestions may include altering the dimensions of a structural element, changing the placement of a fixture, or adjusting the layout of the first unit to better conform to user preferences.

In some embodiments of the present invention, the set of conditions 144 determined by the AI engine may comprise a comprehensive list of deployment and structural preferences that are desired to be adhered to in the design and construction of a building. These conditions are derived from relevant building deployment objectives, standards, and practices. The set of conditions 144 may include, but is not limited to, the following:

Preferred Occupancy Capacity: Conditions related to a number of occupants in a specific space or unit within the building during a preferred deployment use. This may include factors such as the total floor area of the unit, the type of use (e.g., office, residential, assembly), and how many people may comfortably occupy a space at any given time.

Structural Load Preferences: Conditions that specify a minimum load-bearing capacity of structural elements such as beams, columns, slabs, and foundations. These conditions specify that the structural elements should support both live loads (e.g., people, furniture) and dead loads (e.g., the weight of the building materials themselves).

Rebar Specifications: Conditions related to the reinforcement of concrete elements, including the required diameter, material grade, spacing, and placement of rebars within columns, beams, and slabs. These specifications are useful for providing the structural integrity of concrete components, particularly in areas prone to seismic activity or other extreme conditions.

Travel Path Standards: Conditions that govern the design of travel routes, including a preferred width of corridors and stairwells (which may be interactively input into the controller by a user via a user interactive interface), the preferred travel distance to an exit, placement of travel ramps and elevators for convenient accessibility, alignment to accommodate individuals, deliveries, equipment transfer, materials transfer, mobile transfer apparatus (e.g., forklift, robot, dolly, wheelchair, shopping cart, hand truck, or other mobility facilitating device.

Energy Efficiency Standards: Conditions related to the energy performance of the building, including preferences for insulation, glazing, HVAC systems, lighting, and renewable energy sources. These conditions may be based on standards such as LEED (Leadership in Energy and Environmental Design) or other local energy codes that aim to reduce the building's environmental impact and operational costs.

Ventilation and Air Quality Preferences: Conditions that dictate the design of ventilation systems, including the placement and size of air ducts, the preferred air exchange rates, and the inclusion of filtration systems to maintain indoor air quality. These conditions are important for providing a healthy living and working environment, particularly in spaces with high occupancy or specific environmental hazards.

Plumbing and Sanitation Codes: Conditions that specify preferred installation and maintenance of plumbing systems, including the preferred pipe sizes, water pressure, drainage slopes, and the placement of fixtures such as sinks, toilets, and showers. Preferred practices may also include preferences for wastewater treatment and the prevention of cross-contamination between potable and non-potable water systems.

Electrical Preferred Practices: Conditions related to the design and installation of electrical systems, including the preferred load capacity of circuits, the placement of outlets and switches, grounding and bonding preferences, and the installation of protective devices such as circuit breakers and GFCIs (Ground Fault Circuit Interrupters), remote controls, smart building apparatus and other devices.

Seismic Design Preferences: Conditions that specify preferred measures to protect the building against seismic activity, including the use of flexible joints, shear walls, base isolators, and other seismic-resistant technologies. These conditions may be particularly relevant in regions prone to earthquakes and are intended to minimize damage and preserve structural integrity during seismic events.

Wind Load and Weather Resistance: Conditions that address the building's ability to withstand wind loads and other weather-related forces, such as snow loads, rainwater management, and resistance to extreme temperatures. These conditions may dictate the use of specific materials, structural reinforcements, and design practices to protect the building from environmental stresses.

Other conditions may include a set of conditions 144 related to: Zoning and Land Use Regulations, Noise Control and Acoustic Performance, Lighting and Illumination Standards, Material and Construction Quality Standards, Environmental Impact and Sustainability, Occupant Health and Safety Standards, Structural Stability and Foundation Requirements, Flood and Water Management Requirements, Building Height and Massing Regulations, Accessibility and Universal Design Standards, Travel and Entrance/Exit Requirements, Airflow Control Systems, HVAC System Performance Requirements, Solar and Renewable Energy Integration, Parking and Transportation Access, Landscaping and Outdoor Space Requirements, Historic Preservation and Aesthetic Standards, Waste Management and Recycling Facilities, Telecommunications and Network Infrastructure, Security and Surveillance Systems, Noise Abatement and Soundproofing Measures, Floodproofing and Water Resilience, Exit Signage and Markings, Window Glazing and Shading Requirements, Biodiversity and Green Roof Standards, Accessibility to Public Transit and Walkability, Stormwater Management and Drainage Design, Elevator and Escalator Performance Standards, Exterior Lighting and Dark Sky Alignment, Building Automation and Smart Systems Integration, Hazardous Materials Management, Emergency Power and Backup Systems, Indoor Air Quality and Ventilation Standards, Resilience to Natural Disasters, Thermal Comfort and Occupant Well-being, and Occupant Safety and Security.

In some embodiments of the present invention, the controller 141, which operates an AI engine, may be integrated with one or more databases (not shown) containing useful information that enhances the AI engine's ability to assess the alignment of building plans. These databases may include, but are not limited to, databases containing the weight and specifications of various fixtures, historical data of a location's weather or flood history, seismic history, material properties, local building deployment objectives, and environmental impact assessments. By accessing and cross-referencing this vast array of data, the AI engine can provide a comprehensive analysis of the building plans, providing they meet all necessary regulatory, structural, and environmental preferences.

A database that may be integrated with the controller 141 may contain detailed specifications of various fixtures, including their weight, dimensions, and material properties. For example, the database may include information about different types of HVAC units, plumbing fixtures like sinks and toilets, electrical components, and structural elements such as beams and columns. The AI engine can use this information to calculate the load-bearing preferences for floors and walls within the building design. For example, if the building plan includes a large, heavy chandelier in a room, the AI engine may reference the database to determine its weight and assess whether the ceiling and supporting structure are adequate to bear this load without compromising structural integrity. Similarly, the AI engine may assess whether the placement of heavy machinery or equipment in industrial buildings requires additional reinforcement in the floor or foundation.

Another useful database that may be integrated with the controller 141 may contain historical weather data for the location where the building is planned to be constructed. This database may include records of past weather events, such as hurricanes, floods, snowstorms, earthquakes, and extreme temperatures. By analyzing this historical data, the AI engine can assess the resilience of the building design against likely environmental challenges. For example, if the building is in a region prone to flooding, the AI engine may reference flood history data to recommend elevating the building's foundation or incorporating flood barriers. Additionally, the AI engine may use historical wind data to determine if the building's design can withstand the strongest winds recorded in the area, considering factors such as roof design, window placement, and structural bracing.

The AI engine may also integrate with a database containing local building deployment objectives and preferences. This database may include parameters for preferred safety, travel paths, accessibility, energy efficiency, and more. By accessing this information, the AI engine determines if every aspect of the building plan complies with the relevant legal standards. For example, the AI engine may cross-reference the planned travel paths in the building preferred conditions to verify that the distance to exits is within acceptable limits, or it may assess whether the number of exits is sufficient for the planned occupancy load.

In addition to these databases, the AI engine may access databases containing environmental impact assessments. These assessments may include data on local ecosystems, protected areas, and potential environmental hazards. By integrating this data, the AI engine can evaluate the potential environmental impact of the building project and recommend design modifications to mitigate negative effects. For example, if the building is planned near a wetland, the AI engine may suggest adjustments to the building's footprint to avoid disrupting the natural habitat, or it may recommend using eco-friendly materials and construction practices to minimize environmental damage.

Furthermore, the AI engine may access a database of material properties, which includes information about the strength, durability, thermal resistance, and other characteristics of building materials. This information is used for assessing whether the selected materials are appropriate for the building's location and intended use. For example, in a coastal area, the AI engine may recommend using materials resistant to saltwater corrosion for external structures. Additionally, the AI engine may use this data to optimize the selection of materials based on factors like cost, availability, and environmental impact, so that the building is both sustainable and economical.

The integration of these databases with the controller 141 allows the AI engine to perform a multifaceted analysis of the building plans. By leveraging detailed data on fixtures, weather history, building deployment objectives, environmental impacts, and material properties, the AI engine can provide highly accurate and context-specific recommendations. For example, if the database indicates that the region is prone to earthquakes, the AI engine may assess the building's structural design to determine if it includes necessary seismic reinforcements, such as flexible joints or dampers. Similarly, if the database reveals that the area has a history of heavy snowfalls, the AI engine may recommend adjusting the roof design to prevent snow accumulation and provide proper drainage.

Referring now to FIG. 1E, an exemplary design plan of at least a portion of a building 150 that is assessed by the AI engine for structural strength analyses in accordance with the present invention, is illustrated. The AI engine may be tasked with evaluating the load-bearing capability of the building 150, which is a fundamental aspect of its structural integrity. Load-bearing capability refers to the building's capacity to support the various loads it encounters, including the weight of the building itself (dead load), the weight of its occupants and furnishings (live load), and environmental loads such as wind, snow, or seismic forces. The AI engine analyzes multiple factors that contribute to this capability, such as the number of floors, the height of each floor, the number of columns or pillars on each floor, and the configuration of the reinforcement within these structural elements.

The AI engine begins by determining the number of floors in the building 150. For the purposes of this illustration, the building 150 comprises a ground floor 151A, a first floor 151B, a second floor 151C, and a roof 151D. However, it should be noted that the building may contain fewer or more than three floors, depending on its design and purpose. The number of floors directly impacts the load-bearing analysis because each additional floor increases the weight that the lower structural elements must support. The AI engine calculates the cumulative load from all the floors, factoring in the weight of construction materials, fixtures, and potential live loads such as people, furniture, and equipment (as discussed in FIG. 1C).

The AI engine also determines the heights 156 of each floor, as well as the total height of the building 150. The height 156 of each floor is a useful factor in load-bearing analysis because it affects the load distribution and the potential for lateral forces, such as those caused by wind or seismic activity. Taller floors or buildings may require additional structural support to maintain stability and prevent excessive deflection or sway. The AI engine analyzes the relationship between floor height and load-bearing preferences, so that the columns, beams, and other structural elements are adequately designed to support the height of the building 150 without compromising safety.

In addition to analyzing floor heights, the AI engine determines the number of columns or pillars 152 present on each floor. Columns 152 are vertical structural elements that transfer loads from the floors and roof above down to the foundation 153. The number of columns 152 on each floor is a key factor in determining the building's load-bearing capacity. More columns can distribute the load more evenly, reducing the stress on individual columns 152 and the foundation 153. The AI engine calculates the optimal number of columns based on the building's design, intended use, and the loads it is expected to carry. The placement and number of columns are analyzed in relation to the overall stability and load distribution of the building.

The AI engine further assesses the distance 152A between adjacent columns 152. This distance is significant because it influences the load distribution across the floor and impacts the structural integrity of the beams 154 that span between the columns 152. If the distance 152A between columns 152 is too high, the beams 154 may be subjected to excessive bending moments, which can lead to structural failure. Conversely, if the columns 152 are placed too close together, it may result in an inefficient use of materials and space. The AI engine evaluates this distance 152A in the context of the building's design, determining if it falls within the preferred limits based on the number of floors and the loads they impose. The AI engine may also analyze the impact of these distances on the overall stiffness and deflection of the structure.

The analysis conducted by the AI engine extends to the reinforcement within the columns 152, specifically the number of rebars 152B. Rebars, or reinforcing bars, are typically made of steel and are embedded within concrete columns 152 to enhance their load-bearing capacity and resistance to tensile forces. The AI engine determines the quantity, diameter, and placement of rebars 152B within each column 152. This determination is useful because an insufficient number of rebars 152B or improper placement can weaken the column's ability to support the loads imposed on it, potentially leading to cracking or failure under stress. The AI engine uses industry standards and building deployment objectives to calculate the appropriate rebar configuration for each column 152, considering factors such as the height of the building, the expected loads, and the seismic zone (location of building) in which the building is located.

The AI engine also evaluates the type and number of joints 152C used to connect the rebars 152B within the columns 152. These joints, which may include welded, mechanical, or lap splices, may also be useful for maintaining the continuity and integrity of the reinforcement. The type of joint selected can impact the overall strength and flexibility of the column 152, especially in areas subject to dynamic loads such as earthquakes. The AI engine determines the most suitable joint type based on the specific preferences of the building, considering factors such as the rebar material, the expected loads, and the environmental conditions. The number of joints 152C within each column 152 is also analyzed, as excessive or improperly placed joints can create weak points in the structure.

Additionally, the AI engine calculates the distances 152D between these joints 152C. The spacing of joints is another factor that may affect the performance of the reinforced column 152. Proper spacing helps to distribute stress evenly along the length of the column 152 and prevents the concentration of forces that may lead to failure. The AI engine assesses whether the joints 152C are spaced according to the relevant building deployment objectives and standards, determining if they contribute effectively to the column's load-bearing capability. The analysis may include evaluating the joint spacing 152D in relation to the height of the column 152, the type of load it carries, and the overall design of the building 150.

The comprehensive analysis of these factors such as number of floors, floor heights, number and placement of columns, rebar configuration, type and number of joints, and joint spacing, allows the AI engine to provide a detailed assessment of the building's structural strength and load-bearing capacity. By evaluating each element and its relationship to the overall structure, the AI engine determines if the building is designed to withstand the various loads it will encounter throughout its lifespan.

Similarly, the AI engine is also configured to analyze beams 154 within the building 150 as part of its comprehensive structural assessment. The beams 154 are horizontal structural elements that bear loads from the floors, ceilings, and walls, transferring these loads to the columns 152 and, ultimately, the foundation 153. The AI engine evaluates several useful aspects of the beams 154, starting with the number of rebars 154A embedded within them. Rebars within beams 154 serve a similar purpose as those in columns 152 such as they provide tensile strength and reinforce the concrete against bending and shear forces. The AI engine calculates the appropriate number of rebars 154A for each beam 154 based on the expected loads, the span of the beam 154, and the specific preferences of the building's design. The placement and configuration of these rebars 154A are also analyzed to determine if they contribute effectively to the beam's structural integrity.

In addition to assessing the number of rebars 154A, the AI engine examines the number and type of joints 154B within the beams 154. Joints in beams, much like those in columns 152, are for maintaining the continuity and strength of the reinforcement. These joints may include welded splices, mechanical couplers, or lap splices, each chosen based on the material properties of the rebars 154A, the load conditions, and the design specifications. The AI engine determines the most suitable type of joint for each beam 154, taking into account factors such as the expected loads, the beam's length, and the environmental conditions the building 150 will face. The analysis includes evaluating how these joints 154B are spaced along the length of the beam 154, as improper joint placement can create weak points that compromise the beam's ability to bear loads.

The AI engine further analyzes the spacing 154C between the rebars 154A within each beam 154 (and column 152). The spacing 154C is a useful factor in the beam's ability to resist bending and shear forces. If the rebars 154A are too closely spaced, it may lead to congestion during concrete pouring, which can result in voids or poor compaction. Conversely, if the rebars 154A are spaced too far apart, the beam 154 may lack the necessary tensile strength to resist cracking and deflection under load. The AI engine evaluates the rebar spacing 154C based on the beam's dimensions, the type of load it is designed to carry, and the building's overall structural preferences.

The AI engine's capabilities extend beyond the analysis of beams 154 and columns 152 to include the foundation 153 of the building 150. The foundation is the base upon which the entire structure rests, and it must be designed to support the weight of the building 150 while resisting various forces such as soil pressure, seismic activity, and water intrusion. The AI engine determines the type of foundation 153 that is most appropriate for the building 150, considering factors such as soil conditions, load requirements, and environmental risks. For example, the AI engine may recommend a shallow foundation, such as a slab-on-grade or a strip footing, for buildings on stable, low-load sites. In contrast, for buildings on less stable ground or those requiring deeper support, the AI engine may suggest a deep foundation, such as pile foundations or drilled shafts.

In addition to determining the type of foundation 153, the AI engine may assess the size and strength of the foundation 153. The size of the foundation, including its depth, width, and overall footprint, is calculated based on the loads it must support and the soil's bearing capacity. The AI engine analyzes these dimensions to determine if the foundation 153 is large enough to distribute the building's weight evenly, preventing excessive settlement or shifting. The strength of the foundation 153 is determined by the materials used, such as the grade of concrete, and the inclusion of reinforcements like rebar or post-tensioning cables. The AI engine evaluates these materials and methods to confirm that the foundation will maintain its integrity under the building's load and environmental conditions.

Further, the AI engine is also capable of analyzing slabs 155, which serve as the floors and ceilings within the building 150. The detailed analysis of slabs is discussed further in FIG. 1F below, where the AI engine assesses factors such as slab thickness, reinforcement placement, and load distribution. The slabs 155 are an integral part of the building's structure, connecting the various floors and providing a solid surface for occupancy and use. The AI engine's analysis of the slabs 155 includes calculating the expected live and dead loads, assessing the distribution of forces across the slab, and determining the appropriate reinforcement to prevent cracking and excessive deflection.

Referring now to FIG. 1F, it illustrates an exemplary design plan of at least a portion of a building 160 that the AI engine may analyze for alignment according to relevant building deployment objectives. In this particular illustration, the design plan is tailored for a building 160 located in a flood-prone area or location. Buildings in such areas are subject to specific design preferences intended to mitigate the risks posed by floodwaters, and the AI engine is configured to analyze the design for alignment with these preferences.

One of the primary features analyzed by the AI engine in this context is the presence of a pier structure 161, which is a common design element used in flood-prone areas to elevate the building 160 above expected flood levels. The pier structure 161 serves to allow floodwaters 169 to flow beneath the building 160, thereby reducing the risk of water damage to the inhabited portions of the structure. The AI engine assesses the design to confirm that the pier structure 161 is correctly implemented according to the relevant building deployment objectives and flood management guidelines.

The AI engine may determine the type and dimensions of the pier structure 161, including its height 161A from the ground. The height of the pier structure 161 must be sufficient to raise the building 160 above the predicted flood level, accounting for factors such as historical flood data, local topography, and climate conditions. For example, in a region prone to significant flooding, the AI engine may determine that the pier structure 161 needs to be elevated several meters above ground level to prevent floodwaters 169 from reaching the main floors of the building 160. The AI engine calculates the appropriate height 161A by referencing relevant codes and guidelines, determining if the design provides adequate protection against potential flood events.

The AI engine also ascertains the number of floors, such as floors 162-164, that are situated above the pier structure 161. This analysis is important because the height 167 of the building 160 from the pier structure 161 must be designed to accommodate both the functional preferences of the building 160 and the structural demands imposed by its elevation. The AI engine evaluates how the height 167 impacts the overall stability of the building 160, particularly in terms of wind loads, seismic forces, and the structural integrity of the elevated portions. For example, a taller building may require additional bracing or reinforcement to maintain stability when subjected to lateral forces, especially in an area where both flooding and high winds are potential hazards.

In conjunction with analyzing the pier structure 161, the AI engine also assesses the columns 165 and beams 166 that support the elevated floors 162-164 of the building 160. As discussed in FIG. 1E, these structural elements are used for maintaining the building's load-bearing capacity. The AI engine analyzes the number, placement, and dimensions of the columns 165, as well as the beams 166, to determine if they are capable of supporting the building's weight, including the additional loads that may result from floodwater pressure on the pier structure. This analysis includes calculating the appropriate sizes for these elements based on the building's height, the expected loads, and the need for stability in a flood-prone area.

Further, the AI engine is configured to analyze the slabs 168, which form the floors and ceilings of each level above the pier structure 161. In this analysis, the AI engine determines various useful parameters such as the number of rebars 168A and 168B, the type of rebars used, their diameters, and the spacing 168C between them within the slabs 168. The rebars, both vertical 168A and horizontal 168B, are used for reinforcing the concrete slabs 168, providing the tensile strength needed to resist cracking and deflection under load.

The AI engine examines the number and type of rebars 168A-168B used in the slabs 168 to determine if they are adequate for the structural demands placed on the building 160. For example, in an area prone to flooding, the slabs 168 may need to withstand additional forces such as buoyancy and water pressure, which may lead to increased stresses on the concrete. The AI engine selects the appropriate rebar types such as high-strength steel or corrosion-resistant alloys, based on the environmental conditions and the expected loads. The diameter of the rebars is also determined by the AI engine, with thicker rebars typically preferred in slabs that must bear heavier loads or resist significant tensile forces.

The spacing 168C between the rebars 168A-168B is another useful parameter analyzed by the AI engine. Proper spacing is preferred to allow the load to be evenly distributed across the slab 168 and to prevent localized stresses that may lead to cracking or structural failure. The AI engine calculates the optimal spacing based on the slab's dimensions, the expected loads, and the specific requirements of the building deployment objectives. For example, in a slab that spans a large area, closer spacing of rebars may be necessary to maintain structural integrity, whereas in smaller slabs, wider spacing may be sufficient. The AI engine may also determine the overall thicknesses of slabs 168, beams 166, and columns 165.

Referring now to FIG. 1G, it illustrates an exemplary design plan of a multi-story building 170 that may be assessed by the AI engine for alignment analyses in accordance with the present invention. The building 170 features a complex layout with multiple units 171, each serving distinct functions within the overall design. The AI engine is configured to analyze the design plan in detail, beginning with the identification and classification of the various units 171 within the building 170. These units may include living spaces, water closet areas, corridors, hallways, kitchen areas, bedrooms, and other functional spaces. Each unit 171 is analyzed based on its intended use, size, and configuration to determine whether it meets the relevant building deployment objectives and standards applicable to its function.

The AI engine may also determine the presence and type of various fixtures 172 within the building 170. Fixtures are integral to the functionality of the units 171 and may include plumbing fixtures such as sinks, toilets, showers, and bathtubs; electrical fixtures such as outlets, switches, and lighting; HVAC components such as air conditioning units, vents, and thermostats; kitchen appliances such as stoves, ovens, and refrigerators; and furniture such as built-in cabinets and countertops. The AI engine analyzes these fixtures for alignment with building deployment objectives, assessing factors such as placement, accessibility, safety, and energy efficiency. For example, the AI engine may verify that electrical outlets are positioned at the correct height from the floor and that plumbing fixtures are installed according to the preferred distances from walls and other fixtures.

Further, the AI engine is capable of analyzing the building 170 for ventilation alignment. Ventilation is a useful aspect of building design, affecting indoor air quality, occupant comfort, and energy efficiency. The AI engine determines the presence and size of windows 173, which provide natural ventilation. The size of the windows 173 may particularly be important, as it influences the amount of natural light and fresh air that can enter the building. The AI engine may calculate the total window area for each unit 171 and compare it to the floor area to determine whether it meets the minimum preferences set by building deployment objectives. Additionally, the AI engine may check for the presence of exhaust fans in bathrooms and kitchens, which are necessary to remove moisture and odors, thus preventing mold growth and maintaining air quality.

The HVAC system within the building 170 may be analyzed by the AI engine for ventilation alignment. The AI engine evaluates the design and structure of the HVAC system, including the placement of air ducts, vents, and air handling units. It assesses whether the system is adequately designed to provide sufficient heating, cooling, and air exchange throughout the building. This may include verifying that air ducts are correctly sized and placed to provide even distribution of air, that the HVAC system is energy efficient, and that it complies with relevant standards such as ASHRAE (American Society of Heating, Refrigerating and Air-Conditioning Engineers) guidelines. The AI engine may also analyze the integration of the HVAC system with other building systems, such as air ventilation, determining if the system operates effectively in all conditions.

In addition to ventilation alignment, the AI engine may be tasked with analyzing plumbing alignment within the building 170. Plumbing fixtures 174, such as water closets, sinks, showers, and bathtubs, are assessed to determine if they meet the relevant codes related to water supply, drainage, and waste management. The AI engine evaluates the placement and installation of these fixtures, checking for proper alignment with plumbing lines, appropriate clearances, and alignment with water conservation standards. For example, the AI engine may verify that low-flow toilets and faucets are installed, that plumbing connections are secure to prevent leaks, and that drainage slopes are adequate to prevent water pooling and backflow.

The AI engine may also assess the building's plumbing system for accessibility, particularly in units designed for use by individuals with disabilities. This may include verifying that sinks and water closets (174) are installed at accessible heights, that there is adequate space around fixtures for wheelchair access, and that the plumbing system is designed to accommodate the needs of all occupants. The AI engine may check for alignment with standards such as the Americans with Disabilities Act (ADA), determining if the building 170 is accessible and functional for everyone.

Another aspect analyzed by the AI engine may be the accessibility of points of entrance/egress 175 within the building 170. Entrance/egress 175 points are openings through a wall or other barrier that persons use to access the building 170. The AI engine determines the location and accessibility of entrance/egress 175 points, determining if they are placed in strategic locations throughout the building 170 correspond with best practices and/or a desired purpose of a deployed use of the building. This may include analyzing the width of doors and corridors leading to the entrance/egress 175 points, the presence of unobstructed paths, and the alignment of stairwells and ramps with building deployment objectives.

The AI engine also evaluates whether the egress points are clearly marked and easily identifiable by occupants. This may involve checking the placement of exit signs, the installation of emergency lighting, and the use of tactile indicators for visually impaired individuals. The AI engine may also assess the building's overall egress strategy, determining if there are sufficient egress points to accommodate the building's occupancy load and that these points are distributed in a way that minimizes travel distance for all occupants.

Referring now to FIG. 1H, it illustrates an exemplary design plan of a multi-story building 180, which is assessed by the AI engine for alignment analyses in accordance with the present invention. The building 180, in this example, is designed to be constructed in a flood-prone area, where the primary concern is preventing the inflow of water 183 into the lower levels of the structure. To address this challenge, the building incorporates a pier structure 181, which is strategically elevated on a foundation 182. The pier structure 181, constructed of bricks, serves as the primary defense against floodwaters, allowing water to pass beneath the building without compromising the integrity of the living or working spaces above.

The AI engine begins its analysis by examining the design and construction of the pier structure 181. This structure is used for elevating the building above the anticipated flood level, reducing the risk of water damage to the main floors. The AI engine evaluates the materials used, such as the bricks forming the pier structure 181, to determine if they are suitable for withstanding both the load of the building and the environmental conditions, including prolonged exposure to moisture. The AI engine may also assess the height of the pier structure 181, determining if it provides sufficient clearance above the floodplain while maintaining structural stability. The bricks must be of high quality, with the proper density and water resistance to prevent degradation over time, and the AI engine may cross-reference these attributes with material standards specific to flood-prone construction.

The foundation 182 on which the pier structure 181 rests is also analyzed by the AI engine. The foundation 182 must be robust enough to support the weight of the building while also resisting the forces exerted by floodwaters, which may potentially erode the soil around it. The AI engine may evaluate the type of foundation 182 used, whether it is a deep foundation, such as piles driven into the ground, or a shallow foundation like a concrete slab, based on the soil conditions and expected load. The AI engine calculates the foundation's dimensions, and the materials preferred to prevent settlement or shifting, so that the building 180 remains level and stable even under adverse conditions.

The AI engine further analyzes the beams 184A-184C that span between the columns of the building 180. These beams are used for supporting the slabs 185A-185C and distributing loads across the structure. The AI engine examines the thicknesses of beams 184A-184C, as well as their material composition, to verify they meet the structural preferences. For example, the AI engine may determine that the beam 184A, which supports the lower slab 185A, needs to be thicker and stronger than the upper beams 184B and 184C, as it carries the cumulative load of the entire building. The AI engine may also assess the spacing between the beams 184A-184C, determining if they are adequately positioned to prevent excessive deflection or bending, which may compromise the building's integrity.

Moving on to the slabs 185A-185C, the AI engine conducts a detailed analysis of their thicknesses and slopes. The slab 185A, forming the first floor above the pier structure 181, is subject to the greatest load, as it must bear the weight of the upper floors in addition to any live loads (e.g., occupants, furniture, equipment). Therefore, the AI engine determines that a slab 185A should be the thickest, as indicated by the dimension 186A. The AI engine calculates the thickness based on the expected loads, material properties, and the slab's span between supporting beams.

The middle slab 185B, corresponding to the second floor, is analyzed next. The AI engine may determine that the thickness (186B) of this slab can be less than that of the lower slab 185A but still sufficient to support the floor above it. This slab is subjected to a lower load, as it only needs to support the weight of the occupants and furnishings of the second floor, along with the load of the top floor. The AI engine takes into account the slab's position within the structure, the expected live and dead loads, and the material characteristics to optimize its thickness. By reducing the slab thickness where possible, the AI engine contributes to material savings and overall cost efficiency in the building's construction.

The top slab 185C serves as the roof of the building and must withstand environmental factors such as rain, snow, and wind. The AI engine assesses the thickness 186C at the thinner end and the thickness 186D at the thicker end, noting that this slab is intentionally designed with a slope (from thicker to thinner end). The sloped design may be effective for water drainage, preventing the accumulation of water or snow on the roof, which may lead to structural damage or leaks. The AI engine calculates the optimal slope to facilitate proper drainage while providing that the slab remains structurally sound.

In addition to analyzing the individual elements, the AI engine considers how these components work together to create a cohesive and resilient structure. The interaction between the pier structure 181, the beams 184A-184C, and the slabs 185A-185C is analyzed for the overall stability of the building 180, particularly in a flood-prone area. The AI engine assesses how the loads are transferred from the slabs 185A-185C to the beams 184A-184C and then down to the pier structure 181 and foundation 182. This load path must be continuous and free from weak points to prevent structural failures during extreme weather events or over the lifespan of the building 180.

The AI engine also evaluates the materials used throughout the building 180, considering factors such as durability, resistance to moisture, and thermal properties. For example, the AI engine may recommend using reinforced concrete for the slabs 185A-185C and beams 184A-184C, given its strength and resistance to water infiltration. The AI engine may also analyze the thermal properties of the materials, determining if the building 180 is energy-efficient and comfortable for occupants, even in harsh environmental conditions.

Furthermore, the AI engine may simulate different scenarios to assess how the building may perform under various conditions, such as flooding, heavy snow, or high winds. These simulations help verify that the design is robust enough to handle the stresses imposed by these events. The AI engine may suggest design modifications, such as adjusting the slope of the roof slab 185C or reinforcing the pier structure 181, to enhance the building's resilience.

Referring now to FIG. 1I, it illustrates an exemplary scenario 190 may be considered by the AI engine for alignment analyses of a building construction, taking into account the surroundings of a proposed building 191, in accordance with the present invention. The scenario 190 depicted involves a coastal location where the building 191 is planned to be constructed adjacent to an existing building 192 and near a body of water, for example, the sea 194. The AI engine evaluates the suitability of the construction plan, considering both the immediate and broader environmental context to determine if the building 191 complies with relevant preferences.

The AI engine first considers the location where the building 191 is proposed to be built, focusing on its proximity to other existing structures, such as the building 192. The relationship between these buildings is useful, as it affects not only the structural integrity of the new construction but also factors like wind patterns, sunlight exposure, and building access. The AI engine may simulate the surrounding area to analyze how the construction of building 191 will interact with the existing environment. This may include assessing the potential impact on airflow around the buildings 191-192, which may influence ventilation and heating/cooling efficiency, as well as considering how the placement of building 191 may affect the structural stability and foundation preferences.

The AI engine may evaluate a minimum distance 193 between the proposed building 191 and the existing building 192. This distance may include providing adequate space for maintenance, preventing the spread of noise between the buildings 191-192, and maintaining privacy for the occupants. The AI engine may analyze local building deployment objectives to determine a preferred setback or separation distance based on the height and use of the buildings 191-192. For example, if building 192 is a residential structure, and building 191 is intended for commercial use, the AI engine may suggest a larger distance to mitigate noise and traffic concerns. Additionally, the AI engine may simulate different scenarios where the buildings are closer or farther apart, assessing the potential risks and benefits of each configuration before recommending the optimal placement.

The AI engine may also analyze the presence of a boundary wall 196, which is designed to provide a defense against floodwaters or waves 195 from the nearby sea 194. Coastal areas are often subject to environmental challenges such as rising sea levels, storm surges, and high waves, all of which can pose significant risks to buildings located close to the shoreline. The AI engine assesses whether the boundary wall 196 is sufficient to protect the new construction from these threats. This may include evaluating the height 196A of the wall, its structural integrity, and its ability to withstand the forces generated by waves and flooding. If the wall 196 is deemed inadequate, the AI engine may recommend reinforcing it or increasing its height to provide better protection.

In the absence of an existing boundary wall, the AI engine may recommend constructing one with a specific minimum height based on an analysis of the local wave conditions and historical data on flooding. The AI engine may access a database of environmental information, including tide patterns, storm frequency, and wave heights, to determine the most effective design for the wall. For example, in an area where the waves 195 frequently reach heights of 10 feet during storms, the AI engine may suggest a boundary wall that is at least 12 feet high to provide a safety margin. The AI engine may also consider the material composition of the wall, recommending durable, water-resistant materials such as reinforced concrete or engineered flood barriers that can withstand the corrosive effects of seawater and the impact of debris carried by waves.

Moreover, the AI engine may examine the potential for soil erosion around the construction site, particularly given its proximity to the sea 194. Coastal erosion can undermine the foundations of buildings, leading to structural instability over time. The AI engine may simulate different erosion scenarios based on the site's topography, soil composition, and historical erosion rates, providing recommendations on foundation design and additional protective measures, such as retaining walls or vegetation barriers, to mitigate these risks.

The AI engine may also assess the impact of the new building 191 on the local ecosystem, particularly if the construction is near a sensitive coastal habitat. This may involve evaluating the potential disruption to local wildlife, changes in drainage patterns, or the introduction of pollutants during the construction process. If the analysis reveals significant environmental concerns, the AI engine may suggest modifications to the design or construction practices to minimize ecological impact, such as using eco-friendly materials, implementing water management systems, or adjusting the building's footprint to avoid useful habitats.

Additionally, the AI engine may consider the potential impact of wind on the new construction. Coastal areas are often subject to strong winds, which can affect the structural design of buildings. The AI engine may analyze wind load data, considering factors such as the height and orientation of the building 191, the presence of windbreaks, and the aerodynamics of the surrounding buildings. Based on this analysis, the AI engine may recommend design adjustments, such as reinforcing the building's structure, optimizing window placement, or incorporating wind-resistant features like aerodynamic roof shapes or facade elements that reduce wind pressure on the building.

In some embodiments, the AI engine may also take into account the visual and aesthetic aspects of the new construction in relation to the surrounding buildings. Coastal areas often have specific architectural styles or preferences aimed at preserving the visual harmony of the landscape. The AI engine may analyze the design of building 192 and other nearby structures to determine if the building 191 aligns with these aesthetic considerations, recommending adjustments to the building's facade, color scheme, or landscaping to create a cohesive look.

Furthermore, the AI engine may assess the potential impact of the new construction on property values in the area. By simulating different design scenarios, the AI engine may provide insights into how the new building may affect the desirability of the surrounding properties, either positively or negatively. For example, if the building 191 obstructs views of the sea 194 for neighboring properties, the AI engine may suggest altering the building's height or orientation to mitigate this effect.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references. For example, in a hospital design, the AI engine may identify sinks 205 and toilets 206 to determine if they are correctly placed according to hygiene and accessibility codes.

Identification and characterization of various features 201-209 and/or text may be included in the input two-dimensional references. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; the complexity of features (e.g. a number of angles or curves included in a perimeter of an area; a type of hardware that may be used to construct a portion of a building, a quantity of a type of hardware that may be used to construct a portion of the building; or other variable value. For example, in the construction of an office building, the AI engine may quantify the number of doorways 204 and assess whether the hardware used meets equipment operation preferences. Additionally, the AI may calculate the total square footage of interior walls 202 to estimate material costs and labor for drywall installation.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). For example, during a load-bearing analysis, the AI engine may temporarily disregard windows 203 to focus on the structural integrity of exterior walls 201. Other features may be removed, such as the text 208, the plumbing features and other internal appliances and furniture which may be shown on drawings used as input to the processing. In a scenario where a clear floor plan layout is preferred for entrance/egress analysis, the AI engine may remove non-essential elements like kitchen counters 209 to create a simplified version of the floor plan. Again, such feature recognition may be useful to accomplish other goals, but for a goal of boundary 211 definition that delineates a floorplan 210 as illustrated in FIG. 2B a pictorial representation may be purposefully devoid of such features, as illustrated.

In addition to identification of the features themselves, an AI engine may determine a numerical or other digital data value of an amount of clearance between the features; and determine if the clearance between the features meets clearance preferences 131-133. For example, in a wheelchair accessibility alignment check, the AI engine may calculate the distance between doorways 204 and kitchen counters 209 to determine if there is adequate space for manuevering a wheelchair, adhering to ADA guidelines.

Referring now to FIG. 2B, a boundary 211 is illustrated around a grouping of defined spaces 213-216. Spaces are areas within a boundary (which may include, but are not limited to rooms, hallways, stairwells etc.). For example, in a residential building, spaces 213-216 may represent bedrooms, living areas, and bathrooms, all defined by boundary 211.

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A. In a commercial kitchen design, the AI engine may identify specific areas where kitchen counters 209 and sinks 205 should be placed, providing they are correctly spaced for workflow efficiency.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. In a healthcare facility, the AI engine may use such polygons to define the boundaries of patient rooms, determining further if they meet the preferred dimensions for accessibility and equipment placement. Boundaries that include polygons are useful, for example, in creating a three-dimensional representation of a design plan According to the present invention, a boundary may be represented on a user interface as one or both of: one or more line segments, and one or more polygons. In addition, a feature may be represented as a single point, a polygon, an icon, or a set of polygons. For example, in a multi-story office building, windows 203 may be represented as icons, while walls 201 may be depicted as polygons to assist in structural analysis. In some embodiments, a point may be placed in a centroid position for the feature and the centroid points may be counted, summarized, subtracted, averaged, or otherwise included in mathematical processes.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. For example, in a public building, the AI engine may analyze boundary polygons to determine if stairwell widths comply with user preferences, while centroids may be used to calculate the spacing of amenities, such as water spigots, seating, and the like. Extrapolation of a two-dimensional reference into a three-dimensional representation may be supported with a boundary that includes polygons.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. For example, in a large commercial building, a scale may be set to inches: feet to accurately measure the dimensions of interior partitions and determine if they meet the preferences. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length. In an industrial setting, this method may be used to verify that equipment rooms are large enough to house necessary machinery while allowing adequate clearance for maintenance.

Referring now to FIG. 2C, a user interface 220 is illustrated with multiple regions 221-224. The multiple regions 221-224 may be presented via different hatch representations or other distinguishing patterns (in some embodiments regions may also be represented as various colors etc.). For example, in a school design, classrooms may be hatched in one pattern, while hallways and common areas are distinguished with another, allowing easy identification of space types during alignment analysis. During training of AI engines, and in some embodiments, when a submitted design drawing includes highly customized or unique features, a user may wish to adjust an automated identification of boundaries and automated filling of space within the boundaries.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine.

In some embodiments, the controller may generate a user interface 220 that includes indications of assigned vertices and boundaries, and one or more filled areas or regions with user changeable editing features to allow the user to modify the vertices and boundaries. For example, the user interface may enable a user to transition an element such as a vertex to a different location, change an arc of a curve, move a boundary, or change an aspect of polylines, polygons, arcs, circles, ellipses, splines, NURBS or predefined subsets of the interface. In a residential complex, the user may adjust the vertices of a boundary to increase the living space while reducing the corridor area, achieving alignment preferences. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification. For example, if a user frequently adjusts AI-generated boundaries in a particular type of project, such as hospital designs, these adjustments can be used to refine the AI's future predictions for similar projects.

Discrete regions may be regions associated with an estimation function. A region that is contained within a defined wall feature may be treated in different ways such as ignoring all area in a boundary, to counting all area in a boundary (even though regions do not include boundaries). In an office building, the AI engine may ignore small utility closets when calculating usable office space, focusing instead on larger, more significant regions. If the AI engine counts the area, it may also make an automated decision on how to allocate the region to an adjacent region or regions that the region defines.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. Regions with similar dominance ranks may share space, or regions with higher dominance ranks may be automatically assigned to a boundary. For example, in a hotel design, guest rooms may be prioritized over storage areas when assigning space within the floorplan model. In general, a dominance ranking schema will result in an area being allocated to the space with the higher dominance rank. In some embodiments, a dominance rank will allocate an area that may be used in determining an occupancy load. In a stadium design, areas with higher dominance, such as seating areas, may be useful for determining the overall occupancy load. Moreover, in those embodiments that analyze a dynamic file (such as, for example, a Revit® compatible file) a dominance rank may be included, or added to, one or more dynamic features and be modified as the dynamic feature is modified.

In some embodiments, an area 235A between interior boundaries 236-237 and an exterior boundary 235 may be fully assigned to an adjacent region 232-234. An area between interior boundaries 235A may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. In a corporate office design, the AI may allocate more space to conference rooms over break areas based on the company's stated priorities. Parameters may also be based upon items that are automatically counted using AI analysis of pixel patterns that identify a pattern as an item, such as, by way of a non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to prioritize a kitchen over a bathroom, or a larger space over a smaller space. In a high-end residential building, the AI may prioritize kitchen space over bathrooms based on the design intent of providing gourmet kitchens. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region. Two-dimensional. In various embodiments, different calculated features are included in a user interface floorplan model 231 such as features representing aspects of a wall, such as, for example, center lines, the extent of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on alignment with a local code.

Once boundaries have been defined a variety of calculations may be made by the system. A controller may be operative to perform method steps resulting in calculation of a variable representative of a floorplan area, which in some embodiments may be performed by integrating areas between different line features that define the regions.

Alternatively, or in addition to method steps operative to calculate a value for a variable representative of an area, a controller may be operative to generate a value for element lengths, which values may also be calculated. For example, if ceiling heights are measured, presented on drawings, or otherwise determined, then volume for the room and surface area calculations for the walls may be made. There may be numerous dimensional calculations that may be made based on the different types of model output and the user inputted calibration factors and other parameters entered by the user.

In some embodiments, a controller may be provided with two-dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects.

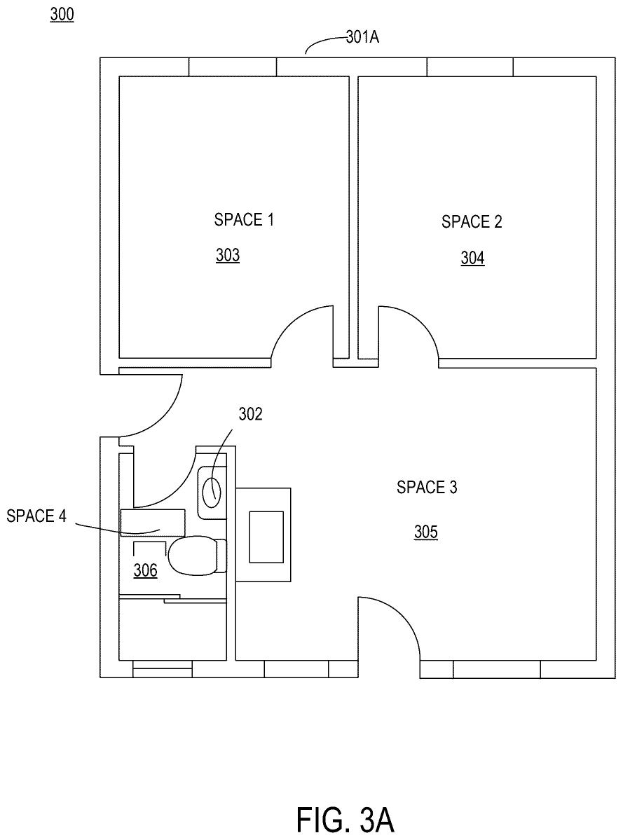

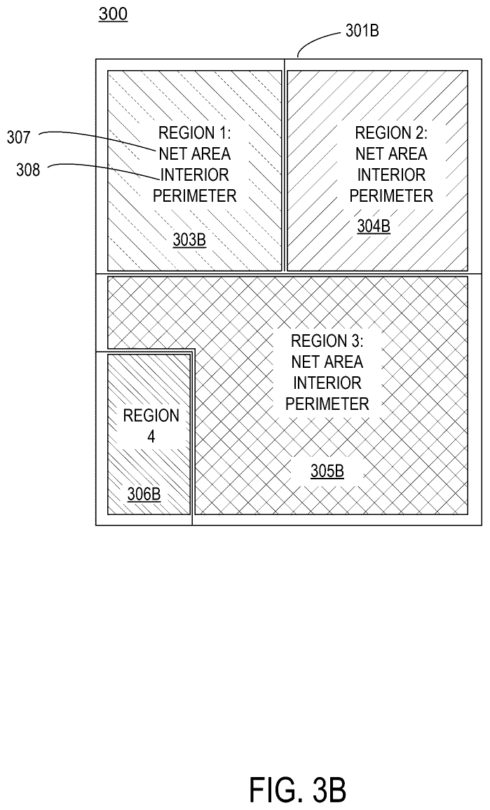

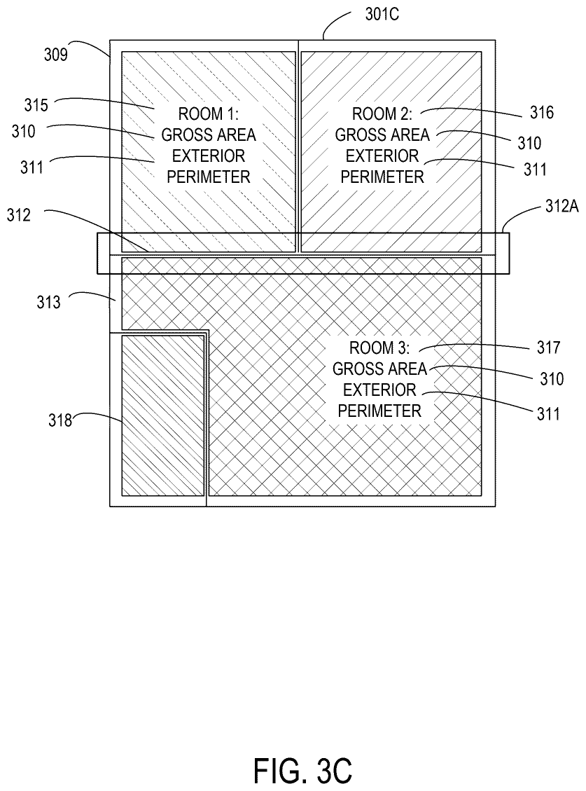

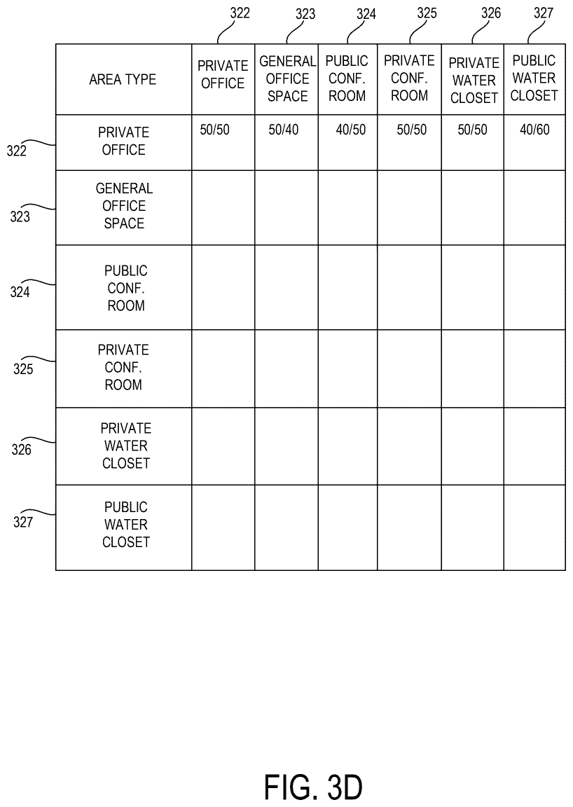

Referring now to FIGS. 3A-3C, a user interface 300 may generate multiple different user views, each view has different aspects related to the two-dimensional reference drawing inputted. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and be used to generate an estimate for completion of a project illustrated by, or otherwise represented by the two-dimensional reference. Referring now to FIG. 3B, in the user interface 300 a user may specify to a controller that one of multiple views available to presented via the interface. For example, a user may designate via an interactive portion of a screen displaying the user interface 300 that a region view 301B be presented. The region view 301B may identify one or more regions and/or spaces 303B-306B identified via processing by a controller, such as, for example, via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material.

Referring now to FIG. 3C, a gross area region view 301C and 309 is illustrated. As illustrated in FIG. 3B, a user interface may include interactive devices for the display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the present invention calculates an area bounded within a series of polygon elements (such as, for example, using mathematical principals or via pixel counting processes), and/or line segments.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B and subsequently have regions assigned as “Rooms” in FIG. 3C.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example, adjacent areas (e.g., area 315 and area 317 or area 317 and area 318), the hierarchical relationship may be used to generate a dominance ranking of one area of another area, or to ascertain factors useful in determining whether a building is in alignment with an applicable code. For example, a dominance ranking may allocate space used to calculate one or more of: an occupancy load; a width and/or area of a travel path; a width and/or area of a common path; a length of a dead end; egress capacity; and travel distance from a furthest point.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ratio, but a private office adjacent to a general office space may be allocated 60 percent of an area included in a border region, and so on.

Dominance associated with various areas may be systemic throughout a project, according to customer preference, indicated on a two-dimensional reference by two-dimensional reference basis or another defined basis.

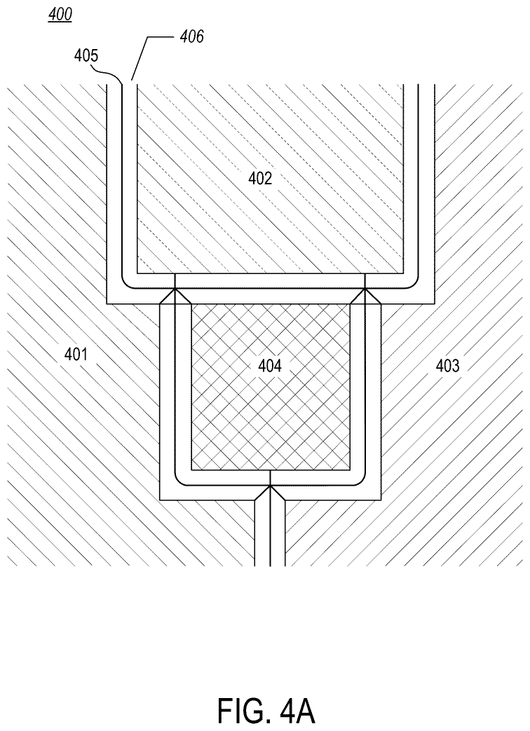

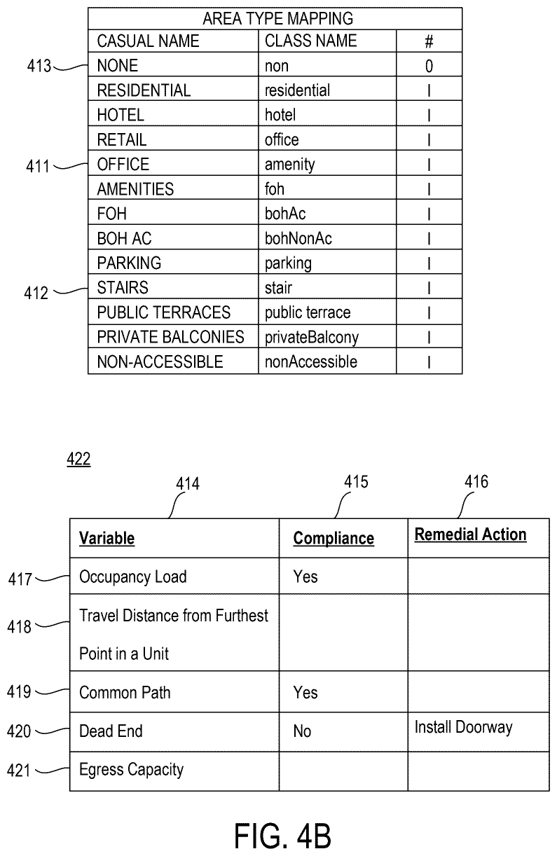

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary, and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicates classes of space types and their associated ranks. In some embodiments, a controller may be operative via execution of software to determine relative ranks associated with a region on one or either side of a boundary. For example, area 402 may represent office space and area 404 may represent a stairwell. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect alignment with conditions that must be met in order to be compliant with a code, such as, for example, alignment and remedial actions. For example, as illustrated, variables 417-421 may include occupancy load 417, travel distance from a furthest point 418, Common path 419, dead end 420, and egress capacity 421.

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes to automatic classification of regions from an input drawing.

An AI engine or other process executed by a controller may be refined, trained, or otherwise instructed to utilize a number of recognized characteristics to accomplish area classification. For example, an AI engine may base predictions for a type “/”category“ of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of the recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

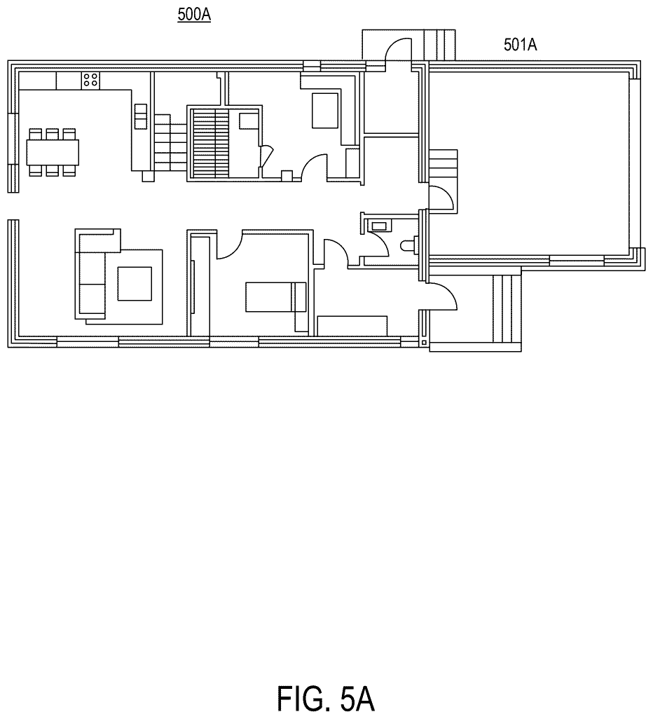

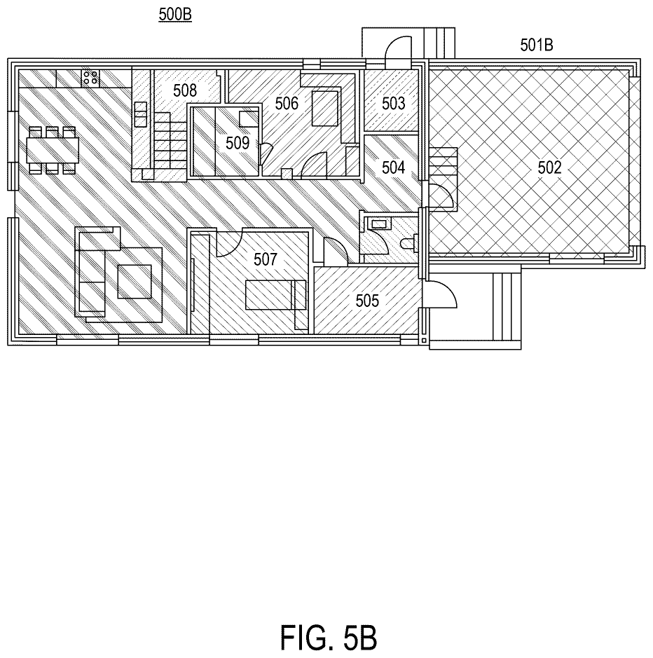

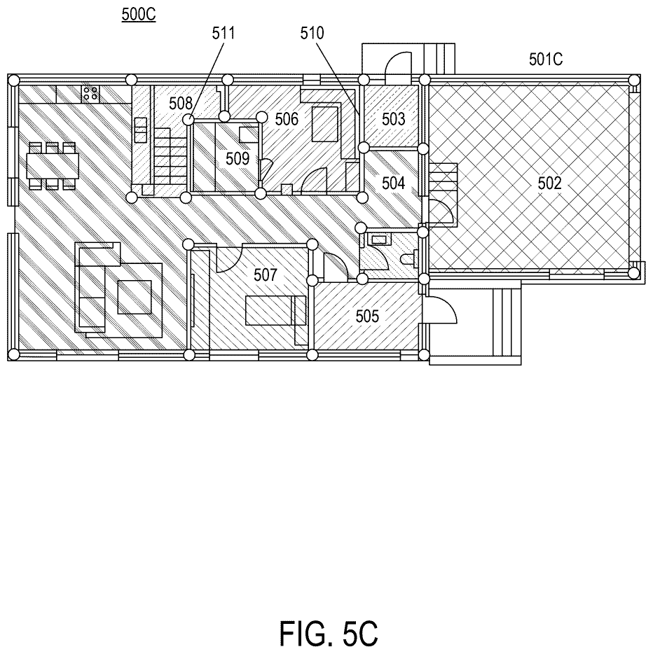

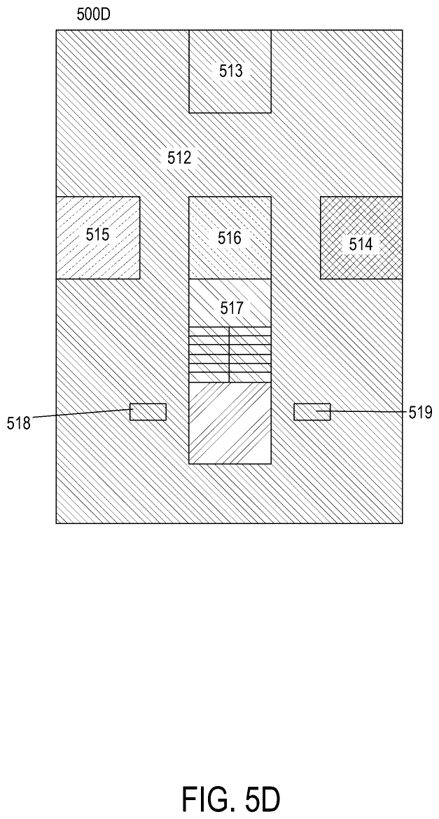

Referring now to FIGS. 5A-5D, a progressive series of outputs that may be included in various user interfaces are illustrated and provide examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of: regions; spaces; patterned portions; line segments; polygons; symbols; icons or other portions of the user interfaces may be assembled and presented in a user output and our user interface, or as input into another automated process.

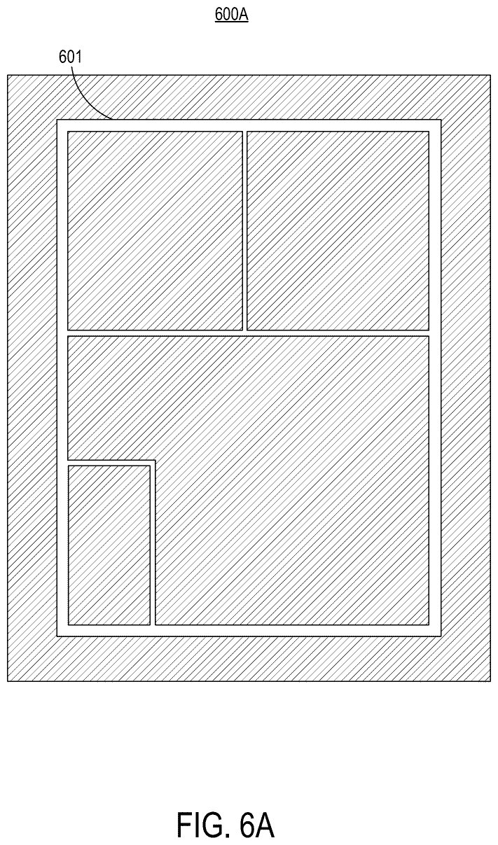

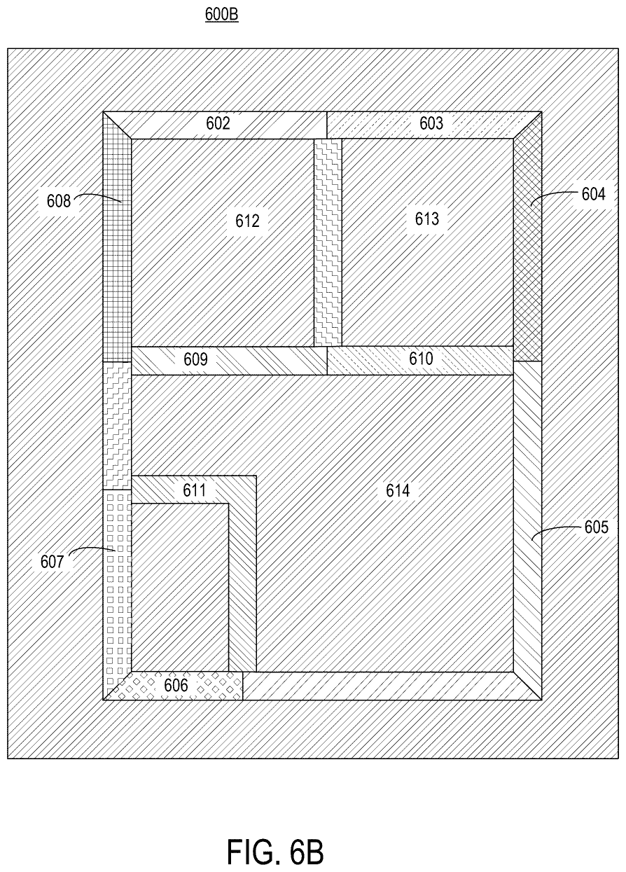

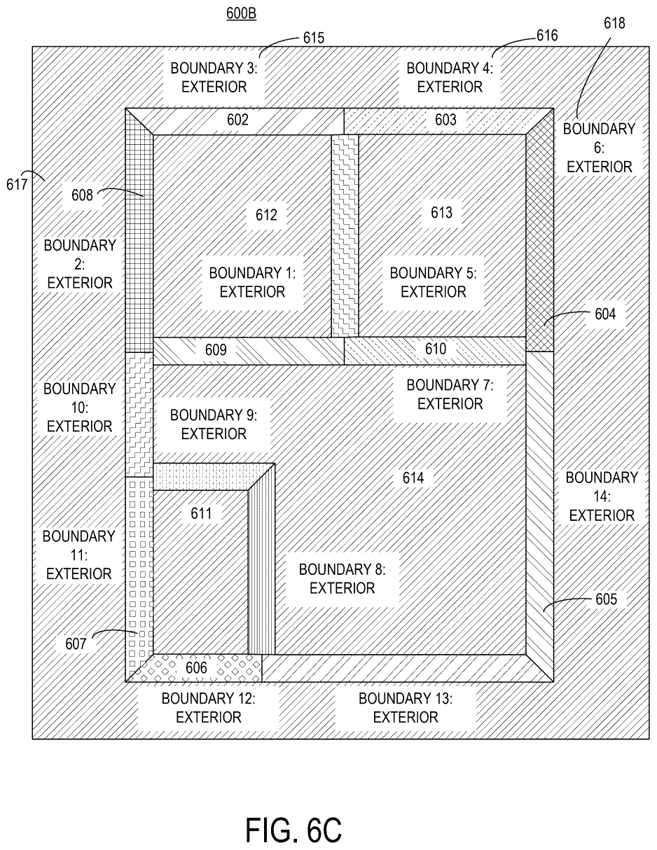

Referring now to FIGS. 6A-6C, in some embodiments, automated and/or user-initiated processes may include refinement of regions, spaces, or areas that may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

In some embodiments, functionality may be allocated to classified individual line segments 602-611, such as, by way of a non-limiting example, a process that generates an estimated materials list for a region or an area defined by a boundary, based on the regions or area's characteristics and its classification.

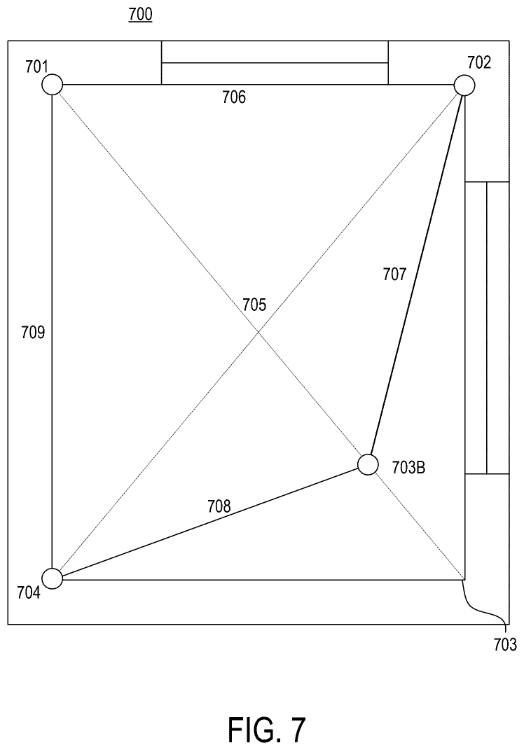

Referring now to FIG. 7, in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user-defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance.

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of a non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied by a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Also, a text input or other narrative may be recognized to provide a more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, in a user interface or other output display or on reports, different layers may be illustrated at different times along with an associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of codes, standards and the like and review the discovered design elements for alignment. In some embodiments, a list of variances or discovered potential issues may be presented to a user on a display or in a report form. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

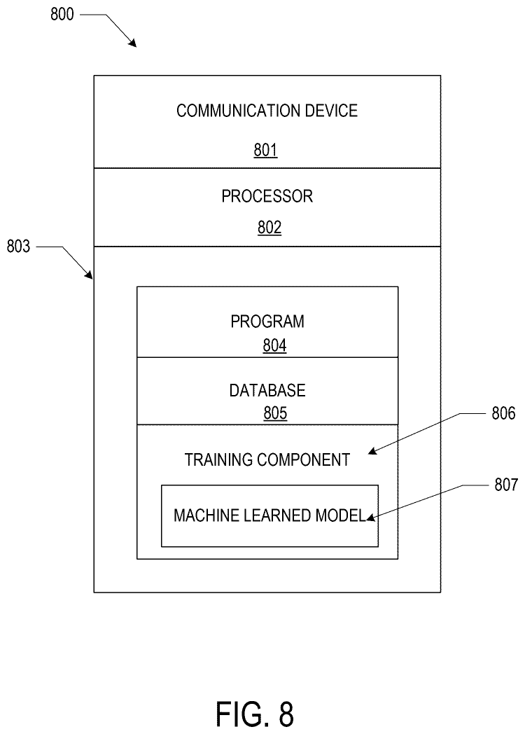

Referring now to FIG. 8, an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804, and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

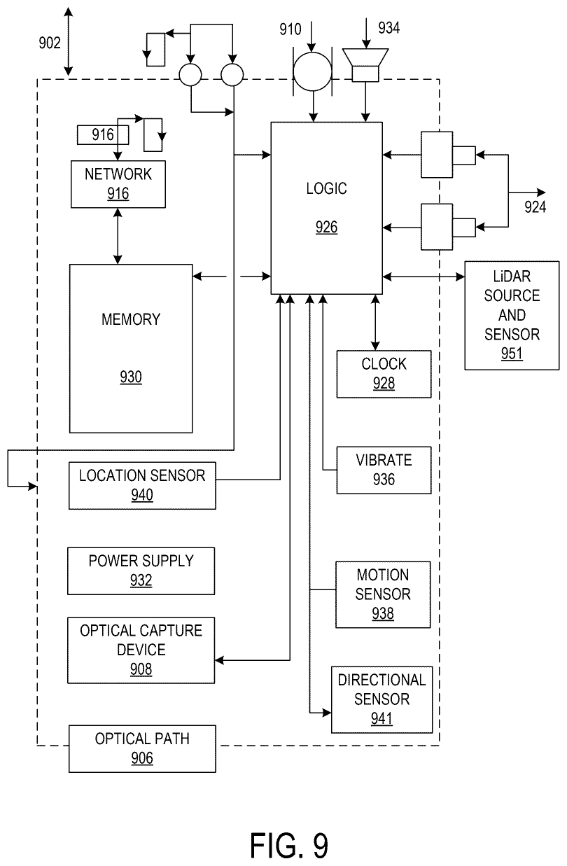

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments, other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as in the infrared. An associated sensor device, sensitive to the light of emission may be included in the system to record the time and strength of the returned signal that is reflected off of surfaces in the environment of the mobile device 902. In some embodiments, as have been described herein, a two-dimensional drawing or representation may be used as the input data source and vector representations in various forms may be utilized as a fundamental or alternative input data source. Moreover, in some embodiments, files which may be classified as BIM input files may be directly used as a source on which method steps may be performed. BIM and CAD file formats may include, by way of a non-limiting example, one or more of: BIM, RVT, NWD, DWG, IFC and COBie. Features in the BIM or CAD datafile may already have defined boundary aspects having innate definitions such as walls and ceilings and the like. An interactive user interface may be generated that receives input from a user indicating a user choice of types of innate boundary aspects a user provides instruction to the controller to perform subsequent processing on.

In some embodiments, a controller may receive user input enabling input data from either a design plan format or similar such formats, or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as fundamental elements, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

In some embodiments, the user may be given access to movement of boundary elements and vertices of boundary elements. In examples where lines or vectors are used to represent boundaries and surrounding area, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a features or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

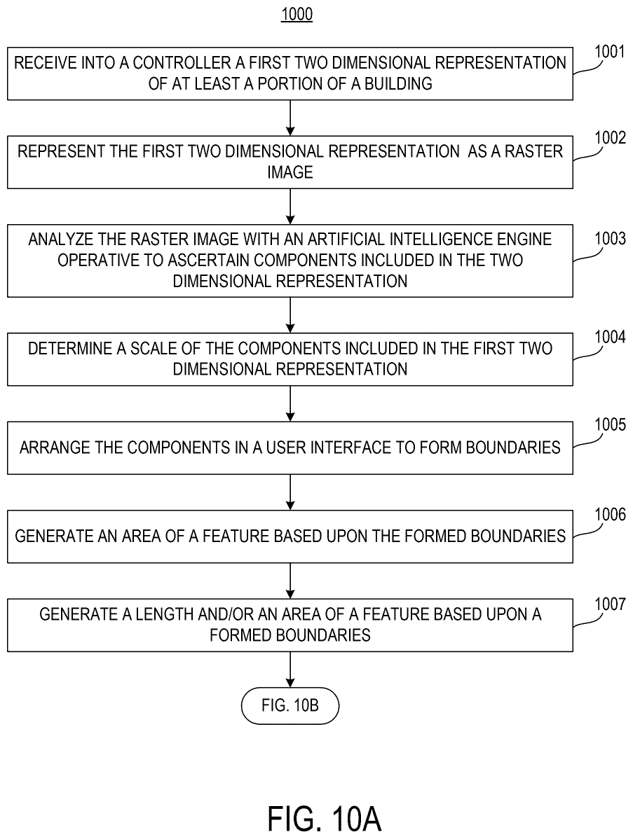

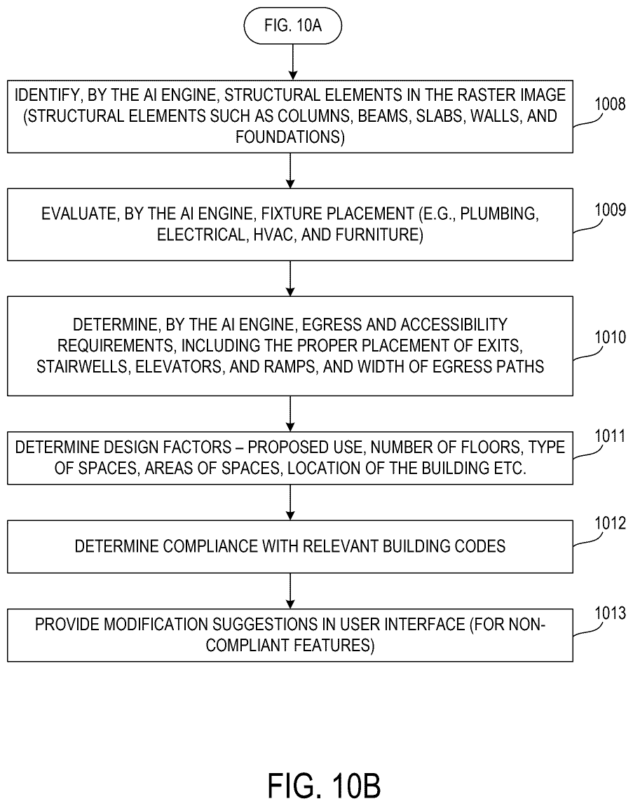

Referring now to FIGS. 10A-10B, method steps 1000 are illustrated for quantifying preferences for alignment of one or more relevant building deployment objectives applied to a building based upon artificial intelligence analysis of a design plan according to some embodiments of the present invention.

At step 1001, the process begins with receiving into a controller a first two-dimensional (2D) representation of at least a portion of a building. The 2D representation may be an architectural drawing, blueprint, or other digital design files like CAD models, PDFs, or scanned images. This step involves the initial input of the design plan into the system, which the controller, integrated with an artificial intelligence (AI) engine, uses for subsequent analyses. The 2D representation captures design elements such as the layout of rooms, structural components like walls and columns, and the placement of fixtures. For example, in a residential building, the 2D representation may depict the layout of bedrooms, bathrooms, kitchens, and living areas, possibly with respective dimensions and placements.

At step 1002, the controller converts the 2D representation into a raster image. This conversion process involves transforming the vector data, typically found in CAD or blueprint formats, into a pixel-based format. Raster images are composed of pixels, each with a specific color value, which collectively represent the entire 2D design. The AI engine may operate more efficiently with raster images, allowing for more straightforward image processing techniques such as edge detection, segmentation, and pattern recognition. For example, in analyzing a floor plan, converting it into a raster image allows the AI to recognize and differentiate between walls, doors, windows, and other structural elements based on pixel patterns.

At step 1003, the AI engine begins analyzing the raster image to ascertain various components included in the 2D representation. This analysis is focused on identifying structural elements such as walls, beams, columns, and floors, as well as fixtures like windows, doors, plumbing, and electrical outlets. The AI engine uses pattern recognition algorithms to detect and classify these components based on their pixel arrangements within the raster image. For example, a series of contiguous pixels forming a straight line with a specific width may be identified as a wall, while rectangular patterns with a distinct color may be recognized as windows or doors. The AI engine may also cross-reference these detected patterns with a database of standard building components to improve accuracy.

At step 1004, the AI engine determines a scale of the components included in the first 2D representation. Determining scale is useful for converting the pixel-based measurements back into real-world dimensions. This may involve identifying known reference points or features within the design that have a defined size, such as doorways, windows, or standardized room dimensions. For example, if a door is known to be 3 feet wide, the AI engine can use this information to establish a scale for the entire raster image. Once the scale is determined, all components identified in the previous step can be accurately measured.

At step 1005, the components identified and scaled by the AI engine are arranged in a user interface to form boundaries. These boundaries represent the edges of rooms, hallways, and other spaces within the building design. The user interface may display these boundaries as lines or shaded areas, highlighting the limits of each space. For example, the AI engine may define a boundary around a kitchen area, including all walls, counters, and openings like doors or windows. This arrangement of components into boundaries helps users visualize the spatial layout of the building, making it easier to assess whether the design plan meets certain criteria, such as minimum room sizes or preferred clearances. Additionally, this step facilitates the next stages of analysis where these boundaries will be used to calculate areas and lengths, which are useful for assessing alignment with building preferences.

At step 1006, the AI engine generates an area of a feature based upon the formed boundaries. This calculation involves determining the square footage or square meterage of various spaces within the building, such as rooms, hallways, or entire floors. The AI engine uses the boundaries established in the previous step to compute these areas accurately. For example, if the boundaries define a living room with dimensions of 20 feet by 15 feet, the AI engine can calculate the area as 300 square feet. This step is useful for several aspects of building alignment, such as determining if rooms meet minimum size preferences or that overall building footprints do not exceed zoning limits. The areas generated are also useful for planning utilities, HVAC systems, and furniture layouts.

At step 1007, the AI engine generates a length and/or an area of a feature based upon the formed boundaries. This step is an extension of the previous area calculation but includes the determination of linear measurements, such as the lengths of walls, the perimeter of rooms, or the height of ceilings. These measurements are vital for various aspects of building design and alignment. For example, knowing the length of a wall is necessary for determining the amount of material needed for construction or for determining if windows and doors are correctly spaced. Similarly, calculating the perimeter of a room is useful in planning baseboards, crown moldings, and other finishing details. The AI engine can also use these measurements to verify that the design complies with specific building deployment objectives that mandate minimum or maximum dimensions for various features.

At step 1008, the AI engine identifies structural elements within the raster image. This step may involve recognizing and categorizing key load-bearing components such as columns, beams, slabs, walls, and foundations. For example, the AI engine may identify a series of thick vertical lines as columns and horizontal lines connecting them as beams. These structural elements are useful for the integrity of the building and must be accurately identified to assess the design's alignment with structural codes. The AI engine also determines the relationship between these elements, such as how columns support beams or how walls are integrated into the overall structure. This information is used for determining if the building is designed to withstand expected loads, including both static loads like the weight of the building itself and dynamic loads such as those caused by wind or seismic activity.

At step 1009, the AI engine evaluates fixture placement within the building design. Fixtures may include plumbing, electrical, HVAC, and furniture elements that are provided for the building's functionality. The AI engine assesses whether these fixtures are placed according to best practices and preferences. For example, the AI engine may analyze the placement of plumbing fixtures like sinks, toilets, and showers to determine if they are correctly aligned with water supply and drainage systems. Similarly, the AI evaluates the positioning of electrical outlets and light switches, determining if they meet accessibility standards and are spaced appropriately for safe operation. The AI engine may also check the layout of HVAC components, such as the placement of vents and returns, to verify that they will provide adequate heating and cooling throughout the building. Additionally, the AI engine may analyze the arrangement of furniture to determine if there is sufficient space for movement and that the furniture does not obstruct any travel paths.

At step 1010, the AI engine determines egress and accessibility preferences for the building. This may involve assessing the placement of exits, stairwells, elevators, ramps, and the width of travel paths to determine if they meet regulatory standards. The AI engine checks that egress routes are clear, direct, and unobstructed, providing safe and efficient travel options in case of emergencies. For example, the AI engine may analyze a building's floor plan to verify that exits are distributed according to preferences, so that no occupant is too far from an exit. The AI engine also evaluates the width of corridors and doorways to confirm they are wide enough to accommodate the expected occupant load, including individuals with disabilities. Additionally, the AI engine assesses the placement of stairwells and ramps, determining if they are designed for safe and easy access, particularly for those with mobility challenges.

At step 1011, the AI engine determines design factors that affect the building's alignment with relevant codes. These factors may include the proposed use of the building, the number of floors, the type of spaces (e.g., residential, commercial, industrial), the areas of spaces, and the location of the building. For example, a building intended for residential use may have different preferences compared to a commercial building, particularly in areas of public access. The AI engine also considers the number of floors, as multi-story buildings must meet additional structural and preferences, such as the inclusion of elevators and stairwells. The AI engine evaluates the types of spaces within the building such as kitchens, bathrooms, offices, or retail spaces, to determine if they are designed according to specific codes and standards. The location of the building is another important factor, as it may be subject to local zoning laws, environmental preferences, and climatic considerations that affect its design and construction.

At step 1012, the AI engine determines alignment with relevant building deployment objectives. This step may involve cross-referencing the identified structural elements, fixture placements, travel paths, and design factors with the applicable building deployment objectives and standards. The AI engine uses a comprehensive database of building deployment objectives, which may include local, national, and international preferences, to evaluate whether the design meets all preferences. For example, the AI engine may check that the structural elements are designed to withstand specific loads, and that fixtures are placed according to preferences. The AI engine also considers any special preferences related to the building's location, such as seismic codes in earthquake-prone areas or wind load preferences in hurricane zones.

At step 1013, the AI engine provides modification suggestions in the user interface for any features that are not compliant with the relevant building deployment objectives. If the AI engine identifies elements of the design plan that do not meet preferences, it generates specific recommendations for changes. These suggestions may include altering the placement of fixtures, adjusting the dimensions of structural elements, or redesigning egress routes to improve safety and alignment. For example, if the AI engine detects that a corridor is too narrow to meet preferences, it may suggest widening the corridor or adding an additional exit. The modification suggestions are presented in the user interface, allowing the user to review and implement the changes directly within the design software. This step may facilitate an iterative design process, enabling architects and engineers to refine the building design until it meets preferences.

In some embodiments of the present invention, the AI engine is configured to calculate costs associated with the construction of the building, including material costs, construction costs, and labor costs for all the elements identified in the design plan, as well as for any modifications suggested by the AI engine. This capability provides a comprehensive financial overview of the project, enabling architects, engineers, builders, and stakeholders to make informed decisions regarding budgeting and resource allocation.

To calculate material costs, the AI engine first identifies the specific materials required for each element of the building as outlined in the design plan. These materials may include concrete, steel, wood, glass, insulation, roofing materials, and various finishes such as paint, flooring, and tiles. For example, if the design plan specifies reinforced concrete columns, the AI engine will calculate the amount of concrete and rebars required based on the dimensions and specifications of the columns. The AI engine cross-references this information with material cost data, which may be sourced from integrated third-party databases or suppliers. These databases contain up-to-date pricing information for a wide range of construction materials, allowing the AI engine to generate accurate cost estimates based on current market conditions.

In addition to material costs, the AI engine also calculates construction costs, which encompass the expenses associated with the physical assembly of the building's structural and functional elements. This includes costs related to the procurement of materials, equipment rental, site preparation, and the execution of various construction tasks such as excavation, foundation laying, framing, electrical and plumbing installation, and finishing work. The AI engine evaluates the complexity and scale of each construction task, taking into account factors such as the number of floors, the type of structural elements (e.g., beams, columns, slabs), and the installation of fixtures (e.g., plumbing, electrical, HVAC systems). The AI engine uses this information to estimate the time, effort, and resources required to complete each task, subsequently calculating the associated costs.

Labor costs are another useful component that the AI engine may calculate as part of the overall cost analysis. Labor costs include wages for skilled and unskilled workers, project management fees, and costs for specialized labor such as electricians, plumbers, and HVAC technicians. The AI engine may integrate with third-party databases or platforms that provide labor services, which offer detailed information on labor availability, hourly rates, and regional labor cost variations. For example, the AI engine may access a database that provides the average hourly wage for carpenters in a specific geographic area. Using this data, the AI engine calculates the total labor costs based on the estimated number of hours required to complete each construction task. The AI engine also accounts for labor productivity rates, which can vary depending on the complexity of the work, the skill level of the workers, and the working conditions on-site.

When the AI engine suggests modifications to the design plan, it also calculates the additional costs associated with implementing these changes. For example, if the AI engine recommends relocating a load-bearing wall to improve structural integrity or alignment with building deployment objectives, it will calculate the costs of the necessary materials (e.g., additional steel or concrete), the labor required to build the wall, and any additional construction tasks that may arise as a result of the modification (e.g., rerouting electrical wiring or plumbing). The AI engine updates the overall project cost estimate to reflect these additional expenses, providing a clear financial impact assessment for the suggested modifications.

To enhance accuracy, the AI engine continuously updates its cost calculations based on real-time data from suppliers and labor service providers. This integration with third-party databases provides that the cost estimates remain relevant and reflective of current market conditions. The AI engine may also allow for customization, enabling users to input specific material preferences or labor rates, which are then incorporated into the cost calculations. For example, if a user prefers a particular brand of high-end roofing material, the AI engine will adjust the material cost estimate accordingly.

Moreover, the AI engine can generate detailed cost reports that break down expenses by category (e.g., materials, labor, construction) and by building element (e.g., foundation, superstructure, finishes). These reports provide stakeholders with a transparent view of where the project budget is being allocated, highlighting areas where costs can be optimized or where additional investment may be required.

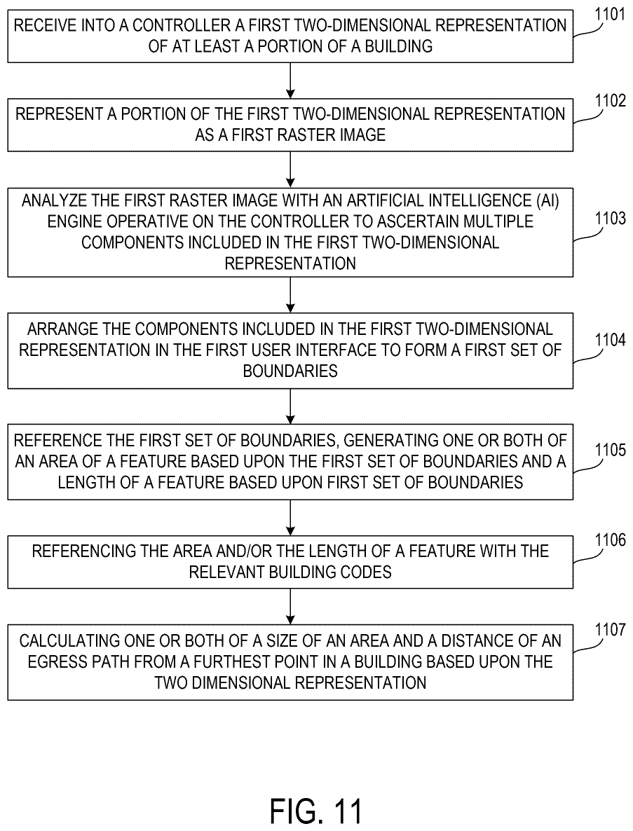

Referring now to FIG. 11, a system including one or more controllers can be configured to perform particular operations or actions by virtue of having executable software, firmware, hardware, or a combination of them that in operation cause the controllers to be operative to perform method steps. In some embodiments, the controller may perform method steps directed to quantifying requirements for construction of a building based upon artificial intelligence analysis of design plans.

At step 1101, the process begins by receiving into a controller a first two-dimensional representation of at least a portion of a building. The two-dimensional representation can be an architectural drawing, a blueprint, or a digital design file that outlines the layout and structure of the building. The two-dimensional representation serves as the initial input for the AI engine to begin its analysis. It may include detailed information such as room layouts, wall placements, column locations, and other structural elements, all of which are necessary for the AI engine to perform a comprehensive analysis. For example, in a commercial building project, the two-dimensional representation may show the arrangement of office spaces, conference rooms, utility areas, and corridors. The controller, equipped with the AI engine, uses the two-dimensional representation to begin processing the spatial and structural information contained within the design.

At step 1102, the controller converts a portion of the first two-dimensional representation into a first raster image. This conversion process transforms the vector-based or line drawing representation into a pixel-based image format. The raster image is composed of pixels, each representing a specific part of the design, such as the edges of walls, windows, doors, and other architectural features. This step is important because raster images are easier for the AI engine to process using image recognition techniques. For example, if the design plan includes a complex layout of walls and openings, the rasterization process simplifies these elements into a grid of pixels that the AI engine can analyze to identify patterns, edges, and boundaries.

At step 1103, the AI engine, operating on the controller, analyzes the first raster image to ascertain multiple components included in the first two-dimensional representation. The AI engine uses advanced image processing algorithms to detect and categorize different architectural and structural components present in the raster image. This may include identifying walls, columns, beams, slabs, windows, doors, and other elements useful to the building's design. For example, the AI engine may recognize a series of aligned pixels as a wall and further identify openings within this wall that represent doors or windows. This step allows the AI engine to decompose the building's design into its constituent components, enabling a deeper analysis of each element's role in the overall structure. The AI engine may also cross-reference these components with a database of standard building elements to enhance the accuracy of the identification process.

At step 1104, the components identified in the previous step are arranged within a user interface to form a first set of boundaries. These boundaries delineate the different spaces within the building, such as rooms, corridors, and other defined areas. The user interface provides a visual representation of these boundaries, allowing the user to interact with the design plan in a meaningful way. For example, the AI engine may define a boundary around a conference room by connecting the edges of the walls that enclose the space. These boundaries are used for further calculations, such as determining the area and perimeter of each space. The user interface may also allow users to adjust these boundaries, providing flexibility in the design process and enabling real-time feedback from the AI engine regarding the impact of any changes.

At step 1105, the AI engine references the first set of boundaries and generates one or both of an area of a feature based upon the boundaries and a length of a feature based upon the boundaries. This step involves calculating the area of enclosed spaces and the length of linear features such as walls or corridors. For example, the AI engine may calculate the area of a rectangular room by multiplying the length and width defined by the boundaries. Similarly, the AI engine may determine the length of a hallway by measuring the distance between two points along its boundary. These calculations are used for assessing whether the design meets specific requirements, such as minimum room sizes or maximum corridor lengths stipulated by building deployment objectives.

At step 1106, the AI engine references the area and/or the length of a feature with the relevant building deployment objectives. This step involves cross-referencing the calculated areas and lengths with relevant standards, guidelines, and building deployment objectives. The AI engine checks whether these dimensions comply with preferences, such as minimum room sizes, travel path lengths, or accessibility requirements. For example, if the AI engine calculates that a room is 100 square feet, it may cross-reference this size with local building deployment objectives to determine if it meets the minimum size requirement for that room type. Similarly, the AI engine may compare the length of a corridor with preferences to confirm it is within acceptable limits for safe travel.

The features analyzed by the AI engine may include various fixtures such as sinks, toilets, showers, electrical outlets, light switches, HVAC vents, and other installed components within the building. The AI engine determines the dimensions of these fixtures, including their height, width, depth, and placement relative to other elements in the design. After determining these dimensions, the AI engine cross-references them with relevant building deployment objectives to verify alignment with standards related to safety, accessibility, and functionality. For example, the AI engine may check whether the height of a sink is within the acceptable range for accessibility requirements or whether the spacing of electrical outlets adheres to local electrical codes.

At step 1107, the AI engine calculates one or both of a size of an area and a distance of an travel path from a furthest point in a building based upon the two-dimensional representation. This calculation may particularly be important for safety and accessibility analysis. The AI engine may determine the size of a specific area, such as a room or hallway, and calculate the distance from the furthest point within that area to the nearest exit or egress point. This analysis helps assess whether the building design meets preferred use requirements, such as, all occupants can conveniently access a destination within the building. For example, in a large office building, the AI engine may calculate the distance from the farthest desk in an open-plan office to the nearest stairwell.

The AI engine may also calculate the preferred occupancy load of a space, which refers to the number of people that a given area can accommodate for a proposed purpose. To determine the occupancy load, the AI engine first analyzes the dimensions of the space, such as its area and layout, and considers the type of activity or function the space is designed for, whether it's a conference room, office area, dining space, or an auditorium. The AI engine applies relevant building deployment objectives, which often specify occupancy load factors that indicate how much square footage is required per occupant for different types of spaces. Once the occupancy load is calculated, the AI engine uses this information to evaluate the alignment of various related aspects, such as the width of travel paths, the number of exits, and the capacity of stairwells or elevators, determining if these features are sufficient to handle the maximum number of occupants in accordance with preferences.

A scale of one or more components may be determined and a parameter of one or both of a polygon and a line segment may be modified based upon receipt of an instruction for a user; and a boundary may be set based upon reference to a boundary allocation hierarchy.

The steps may be performed multiple times and may include two or more two-dimensional references with results of the process be compared one against the other to ascertain when a change has been made to a two-dimensional reference that places a building in alignment with a selected code. In various embodiments, a change in subsequent two-dimensional references may be used to generate a change in one or more of a takeoff, labor costs, project management input or other aspects that may impact construction of a building and/or associated costs.

Implementations may include one or more of the following features. The method additionally determining a scale of the components included in the design plan and/or generating a user interface including user interactive areas to change at least one of: a size and shape of at least one of the dynamic components, the dynamic components may include, by way of a non-limiting example, one or more of: architectural features, polygons or arcuate shapes; regions, areas, spaces, travel paths, travel paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the interactive user interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via an interactive user interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in the construction of the building. In addition, a type of labor associated with at least one of the items to be included in the construction of the building may be designated based upon AI analysis of the first two-dimensional reference and the second two-dimensional reference, respectively.

Methods of practice may additionally include the steps of: determining whether a design plan received into the controller includes a vector image, and if one of the first and the second design plan received into the controller includes a vector image converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of a size and shape of at least one of the dynamic components. At least one of the dynamic components may include a polygon and the method further includes the steps of: receiving an instruction via the interactive user interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit, or other defined space. A change in area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of alignment with a set of conditions, such as a code relevant to a geopolitical locality and a building.

A dynamic component may include a line segment and/or vector, and the method may further include the steps of: receiving an instruction via the interactive user interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of: determining whether the design plans received into the controller includes a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

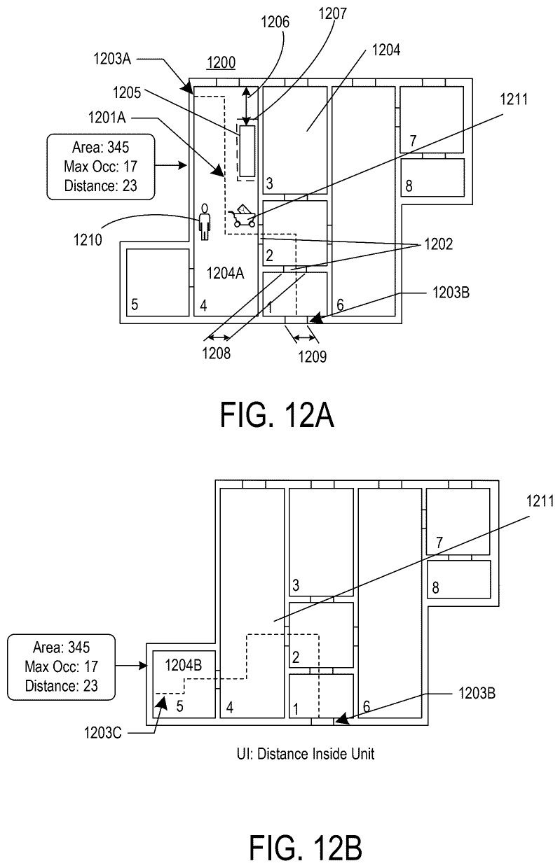

Referring now to FIG. 12A, this figure illustrates a diagram of travel paths analyzed by the AI engine for alignment analyses of design plans in some embodiments of the present invention. The diagram represents a design plan of a building 1200, which may be a residential apartment, an office suite, or another type of enclosed space within a larger building. The diagram focuses on a travel path 1201A, which is a preferred route that a specified traveler 1210 may use in the building 1200 for a proposed purpose. For example, two people walking abreast to a meeting room may preferably take a different path than a traveler 1210 with a cart or vehicle 1211 for maintaining the building. The AI engine is responsible for analyzing travel paths to determine if they meet the relevant building deployment objectives preferred use objectives.

A travel path 1201A may originates in a first area 1204A inside the building 1200. The first area 1204A may include an origination point 1203A to a destination point 1203B, such as, for example a point of entrance/egress. The first area 1204A may represent a living room, bedroom, or office space where an occupant may be located. The AI engine begins its analysis by identifying the origination point 1203A, which is then used for determining the overall length of the travel path 1201A. The distance from the origination point 1203A to the destination point 1203B is a key factor in determining if the building design is in accordance with a preferred deployment use.

The travel path 1201A proceeds from an origination point 1203A, guiding a traveler (e.g., a person or UGV or UAV) through the first unit 1204A toward the destination point 1203B. The travel path 1201A may entail passage through one or more two interior doorways 1202. The interior doorways 1202 may connect different rooms or areas within the building 1200 and will also be associated with a minimum clearance capability for the travel path 1201A.

The AI engine analyzes the doorways 1202 to determine clearance parameters 1208 associated with the doorway (or other path constriction) to determine whether the clearance parameters 1208 are of sufficient width and height to allow for easy passage by a traveler, such as a person, or apparatus. The analysis may include checking that the doorways meet minimum width requirements stipulated by preferred practices for a deployment use, so that they are wide enough to accommodate the expected type of apparatus, equipment shipment pallet or container, UAV, UGV, or number of occupants abreast.

A travel path 1201A may pass by an equipment item 1205 or other obstruction. The equipment item 1205 may have a clearance specification 1206 from a nearby architectural aspect, such as, for example, a wall, in order to be able to service the equipment 1205. The equipment item 1205 may also include a circumference 1207 specified for optimal and/or required clearance for proper operation and/or safety of use of the equipment 1205.

The travel path 1201A includes a includes destination point 1203B, which, in this case, may include a door that leads to an exterior of the building 1200. The AI engine examines the location and design of the destination point 1203B to confirm that it provides a direct and unobstructed route out of the building 1200 for a type of traveler specified by a user or the controller.

The destination may also include a clearance parameters 1209 that may be referenced to determine whether a desired travel path is suitable for a particular specified traveler 1210.

The user may make the specification via a user interactive interface. The analysis may involve checking the door's swing direction, determining if it opens outward as required by many building deployment objectives to facilitate a swift exit. Additionally, the AI engine may assess whether the destination point 1203B is clearly marked and whether there are any potential obstructions that may impede travel.

The area surrounding the travel path 1201A may also be analyzed by the AI engine for alignment with space and accessibility standards. For example, the AI engine may calculate the area of each room or unit through which the path passes, determining if there is adequate space for occupants to move quickly and without congestion. The dimensions of the rooms, along with the placement of furniture and fixtures, may be considered in this analysis to optimize the path's efficiency.

The AI engine also calculates the total distance of the travel path 1201A from the furthest point 1203A to the destination point 1203B. The distance is useful because building deployment objectives often specify maximum allowable travel distances to exits, particularly in larger units or those with complex layouts. By comparing the measured distance with these standards, the AI engine can determine whether the design is compliant or if adjustments are needed, such as adding additional exits or reconfiguring the layout to shorten the travel distance.

Furthermore, the AI engine may assess the occupancy load of the building 1200 and cross-reference this with the capacity of the travel path 1201A. For example, if the building 1200 is designed to accommodate a large number of people, the travel path 1201A must be capable of handling this load, both in terms of width and the number of exits. The AI engine may use the calculated occupancy load to verify that the travel path meets all preferences

Referring now to FIG. 12B, a travel path 1201B originating in a second area 1204B inside the building 1200 is illustrated from a second furthest point 1203C in the second area 1204B to a destination point 1203B. The diagram demonstrates how the AI engine can analyze multiple travel paths (1201A-1201B) within a single building 1200 to verify comprehensive safety and alignment with building deployment objectives.

Egress routes that occupants may use to destination point 1203B the building 1200 may be compared to the preferred deployment use of a building. In this scenario, a potential start point 1203C represents a potential location within the building 1200 from which an occupant may begin travel, and a preferred route may be determined, such as a route that passes aesthetically pleasing architectural aspects. The AI engine traces the travel path 1201B from this point, through various interior doorways and spaces, ultimately leading to the exit at 1203B.

The AI engine may be used to determine a second travel path 1201B (or other number of travel paths) and may compare travel paths, such as the one illustrated in FIG. 12A to provide multiple paths to accomplish a preferred use of the building space involved. By analyzing multiple paths of egress, the AI engine can identify a most preferred path according to a user defined criteria. For example, if the path 1201B from the second furthest point 1203C is more aesthetically pleasing than the path 1201A shown in FIG. 12A, the AI engine may select one path or another as preferred path, based upon defined criteria (defined criteria may be initiated by a user or a controller).

Furthermore, the AI engine can generate these paths dynamically, taking into account different potential starting points within the building 1200. This may particularly be useful in complex or large units where occupants may be distributed across various areas. The AI engine's ability to analyze and compare multiple travel paths helps in determining if the design accommodates safe travel from any point within the building 1200, providing a robust analysis of the building's overall safety.

In some embodiments, the AI engine may also assess other factors along each travel path, such as door widths, corridor clearances, and the presence of beneficial aspects, views, checkpoints, traffic, or obstacles that may hinder travel. These additional analyses help in identifying potential bottlenecks or hazards that need to be addressed in the design phase. By generating and evaluating multiple travel paths, the AI engine contributes to creating a safer and more compliant building design, where all possible travel routes are thoroughly examined and optimized.

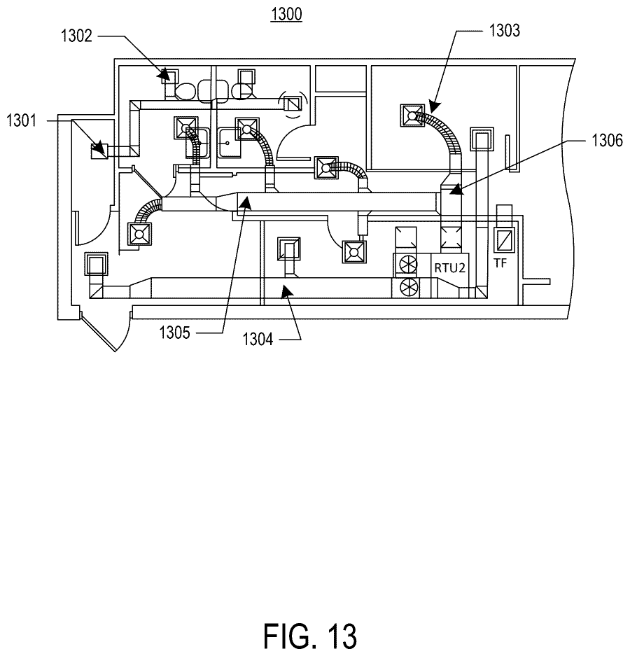

Referring now to FIG. 13, a design plan 1300 with airflow paths 1301-1306 is illustrated. The airflow paths 1301-1306, within a building's HVAC (Heating, Ventilation, and Air Conditioning) system, may by analyzed for volume, unimpeded pathways (including turns and straight runs). The AI engine, as part of its comprehensive analysis capabilities, evaluates these airflow paths to determine their efficiency, alignment with relevant codes, and overall functionality in maintaining the desired environmental conditions within the building. The airflow paths 1301-1306 are useful to the building's HVAC performance, as they dictate how air is distributed, filtered, and exhausted throughout the structure. Each of these paths may be represented by ducts of varying sizes and configurations, and they are strategically placed to facilitate optimal air circulation.

The AI engine begins its analysis by examining the volume of air that each airflow path 1301-1306 can carry. This involves calculating the cross-sectional area of the ducts, taking into account their dimensions, which are indicated by notations such as 8×8, 10×8, and 16×10 in the design plan. For example, the path 1301 may involve a series of ducts with varying sizes, where the AI engine determines the maximum airflow capacity by calculating the area of each duct segment and considering the air velocity. The AI engine may use these calculations to determine if the HVAC system is capable of delivering the required amount of conditioned air to each space within the building. This analysis is used for maintaining consistent temperature, humidity, and air quality levels, particularly in areas with high occupancy or specific environmental needs, such as data centers or laboratory spaces.

In addition to volume, the AI engine evaluates the airflow paths 1301-1306 for unimpeded pathways, which include both turns and straight runs. Unimpeded pathways are required for minimizing resistance and providing efficient air delivery. The AI engine analyzes the design to identify any sharp turns or bends in the ductwork, as these can significantly impact airflow by increasing resistance and reducing velocity. For example, the airflow path 1302 may include several 90-degree bends, which the AI engine will assess to determine if they are likely to cause a significant drop in air pressure or flow rate. The AI engine may suggest design modifications, such as using smoother curves or increasing duct size at turns, to mitigate these effects and maintain optimal airflow.

The straight runs within each airflow path are also analyzed for their effectiveness in transporting air without unnecessary loss of pressure or velocity. For example, in the airflow path 1303, the AI engine may examine a long straight duct that runs through several rooms. The length of the run, combined with the duct's material and diameter, will influence the air pressure at the end of the path. The AI engine calculates whether the pressure drop over the length of the run is within acceptable limits, so that the air delivered to the final destination is sufficient to meet the space's requirements. If the pressure drop is too significant, the AI engine may recommend installing booster fans or increasing the duct diameter to compensate.

The AI engine also considers the placement and configuration of HVAC components such as diffusers, return air grilles, and dampers along each airflow path. These components may be useful in controlling the distribution and direction of airflow. For example, in the airflow path 1304, the AI engine may evaluate the positioning of diffusers to determine if they are evenly distributing air across a large open office space. Similarly, the AI engine may analyze the return air grilles in the path 1305 to confirm that they are appropriately sized and placed to facilitate the efficient removal of air from the room, preventing the buildup of contaminants or excess humidity.

In some embodiments, the AI engine also assesses the integration of the airflow paths 1301-1306 with other building systems, such as HVAC control systems. For example, the airflow path 1306 may include dampers that are designed to open and/or close automatically to control the HVAC system. The AI engine evaluates these components to determine if they are correctly installed and that they comply with preferences. The AI engine may also simulate emergency scenarios to verify that the HVAC system can effectively transition to a smoke control mode, maintaining safe conditions for building occupants during a travel.

The AI engine's analysis extends to the overall balance of the HVAC system, where it assesses that the supply and return airflows are properly balanced. This involves comparing the total air volume supplied through airflow paths 1301-1306 with the air volume being returned or exhausted from the building. An imbalance between supply and return air can lead to pressurization issues, such as doors being difficult to open or drafts occurring in certain areas. The AI engine calculates the required adjustments, such as modifying damper settings or altering duct sizes, to achieve a balanced system that maintains a comfortable and stable indoor environment.

In addition to analyzing the airflow paths, the AI engine may assess the energy efficiency of the HVAC system. This may include evaluating the duct insulation, the efficiency of fans and blowers, and the potential for energy recovery. For example, the AI engine may identify areas where insulation can be improved to reduce thermal losses, or it may suggest the implementation of energy recovery ventilators (ERVs) to capture waste heat from exhaust air and use it to precondition incoming fresh air. These energy-saving measures may particularly be important in large buildings, where HVAC systems can account for a significant portion of the overall energy consumption.

Furthermore, the AI engine may analyze the design plan 1300 for alignment with environmental standards and certifications, such as LEED (Leadership in Energy and Environmental Design) or WELL Building Standard. This involves checking that the airflow paths 1301-1306 are designed to optimize indoor air quality by providing adequate ventilation rates, minimizing exposure to pollutants, and maintaining comfortable thermal conditions. The AI engine may also assess whether the HVAC system is capable of adapting to variable occupancy levels and environmental conditions, which is useful for maintaining a healthy and productive indoor environment.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to determine alignment suitability for a preferred use. In addition, in some embodiments, a process executed by an AI engine may ascertain building attributes and analyze the building attributes may be modified in order to bring the building into alignment. A user interface may present suggested modifications to a user. Some embodiments may also include designation and/or ranking of variables that may be modified in order to bring a building into alignment. By way of a non-limiting example, variables may relate to one or more of: magnitude of structural changes, cost to implement changes, time to implement changes, impact of a change(s) on a desired use of the building, and duration of a proposed change.

In another aspect, in some embodiments, suggested modifications may be ranked according to a priority ranking of features input via a user interface. For example, a user may input priority rankings that dictate that a number of a certain type of room or unit must be maintained above a threshold within the plan, such as, for example, the plan must include: ten residential units, each unit with three bedrooms and two bathrooms and kitchen a living room; or at least four units with three bedrooms each; a second priority may include room sizes of a minimum and/o maximum size; a third priority may include a washer and dryer area; a fourth priority may include a common area of a minimum size; and other prioritized attributes to be included in a building design. AI and/or user input may modify a design of the building to modify a building plan for suitability with a preferred alignment use, while also adhering to the priority ranking of features.

In an example, a user interface may be designed for an optimal user experience in evaluating an existence (or non-existence) of attributes necessary in order for a design plan alignment to be suitable for a preferred use. In some embodiments a design may be evaluated by any of the various processes as have been described herein. After a design plan is received into a controller, an interface may be presented to a user to allow for interactive assessment of attributes required for a preferred use.

In some embodiments, an AI system may receive an architectural file with intelligent features of various kinds which will be discussed in further detail following. The present system may operate in concert with a BIM or CAD design system, for example, as an add-in to these design systems and then the present system may have access to design elements, location data and the like directly. In other examples, the present system may access BIM or CAD design system data by loading data files from said systems. In still further examples, the present system may operate to capture data from display screens that are displaying designs from the said BIM or CAD design systems.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

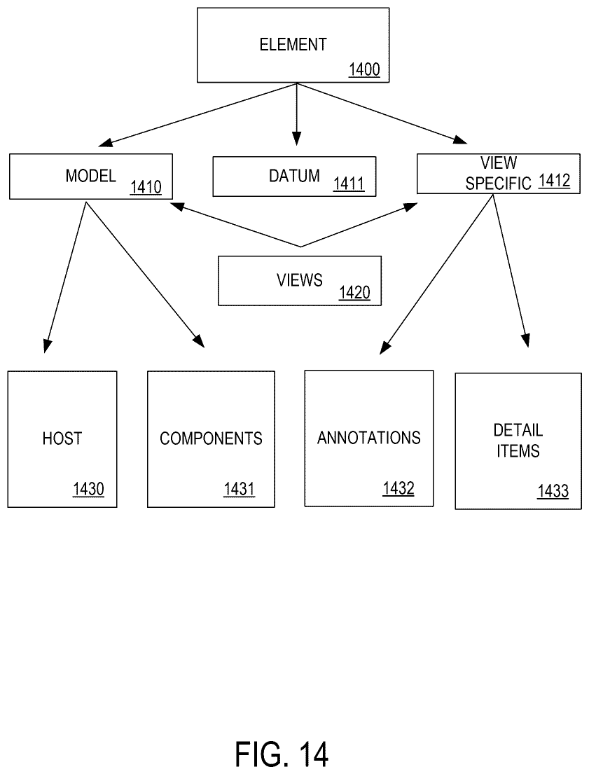

Referring now to FIG. 14, it illustrates a high-level overview of the types of elements 1400 that may be stored and analyzed within a Building Information Modeling (BIM) file, such as Revit files, in the context of the present invention. The elements 1400 within these files are categorized into three primary types: model elements 1410, datum elements 1411, and view-specific elements 1412. Each of these categories may serve a distinct purpose in the design and documentation of a building project, and the AI engine integrated into the controller of the present invention leverages this structured information to perform detailed alignment analyses and other evaluations of the building plans.

Model elements 1410 represent the physical components of the building that are intended to be constructed. These may include structural and architectural features such as floors, walls, ceilings, roofs, and other elements that define the building's physical form. For example, the AI engine may analyze walls within the model elements to determine whether they meet load-bearing requirements or comply with preferences. Within the model elements, a further classification is made into “Hosts” 1430, which include primary structural components such as the aforementioned walls, floors, and roofs. These hosts are useful for the integrity of the building, and the AI engine evaluates their design for a preferred user alignment, determining if they are capable of supporting the building's intended deployment purpose.

In addition to hosts, the model elements 1410 also include components 1431, which are secondary elements that may depend on the hosts. Components 1431 may include doors, windows, cabinets, and other fixtures that are attached to or interact with the primary structural elements. The AI engine assesses these components for proper placement, dimensions, and alignment with accessibility standards, energy efficiency requirements, and other relevant regulations. For example, the AI engine may check that windows are placed at appropriate heights for natural lighting and ventilation or that doors comply with accessibility standards such as those set forth by the Americans with Disabilities Act (ADA).

Datum elements 1411 are another category of elements within the BIM file. These elements may provide the contextual framework within which the model elements are placed. Datum elements include grids, levels, and reference planes that help organize the design and verify that all components are correctly aligned and positioned. Grids may be used to snap walls and columns into place, while levels organize the building into floors or sections, so that all components are at the correct height relative to one another. The AI engine uses datum elements 1411 to verify the spatial relationships between components, so that the design is consistent and that all elements are properly coordinated within the overall structure. For example, the AI engine may analyze the levels to determine if ceiling heights are uniform throughout a building or if floors are properly aligned with external elements such as entryways or outdoor terraces.

View-specific elements 1412, the third category, are those that are only visible or relevant in particular views of the building model. These elements are used for detailed documentation and presentation of the design. View-specific elements include annotations 1432 and detail items 1433. Annotations 1432 may include dimensions, notes, tags, and keynotes that provide additional information or clarification about the model elements in a specific view. These annotations help in communicating design intent, identifying potential issues, or providing instructions for construction.

Detail items 1433, on the other hand, may include additional lines, hatching, or other graphical elements that enhance the clarity or specificity of a design view. For example, detail lines may be used to indicate the slope of a roof or the layering of materials in a wall section. The AI engine may analyze these detail items to determine if they are consistent with the overall design and if they correctly represent the intended construction techniques. In some embodiments, the AI engine may even suggest improvements to detail items, such as more efficient construction methods or alternative materials that offer better performance or cost-effectiveness.

The AI engine integrated with the controller is capable of extracting and analyzing these various elements from BIM files, using them to perform a wide range of assessments. For example, the AI engine may extract model elements 1410 and assess their alignment with local building deployment objectives, determining if walls, floors, and roofs meet structural and safety requirements. Simultaneously, the AI engine may evaluate datum elements 1411 to verify that all components are properly aligned and that the overall design is coherent and logically organized.

Additionally, the AI engine's ability to interpret view-specific elements 1412 allows it to enhance the documentation process. By analyzing annotations and detail items, the AI engine can provide the building design to be thoroughly documented, with all necessary information clearly communicated to contractors, engineers, and other stakeholders involved in the construction process.

Furthermore, the AI engine can learn from the data it processes, applying machine learning techniques to improve its ability to recognize patterns, optimize designs, and suggest modifications. For example, if the AI engine frequently encounters certain types of errors or inefficiencies in the model elements or annotations, it can learn to identify these issues more quickly and offer solutions based on best practices or previous successful projects.

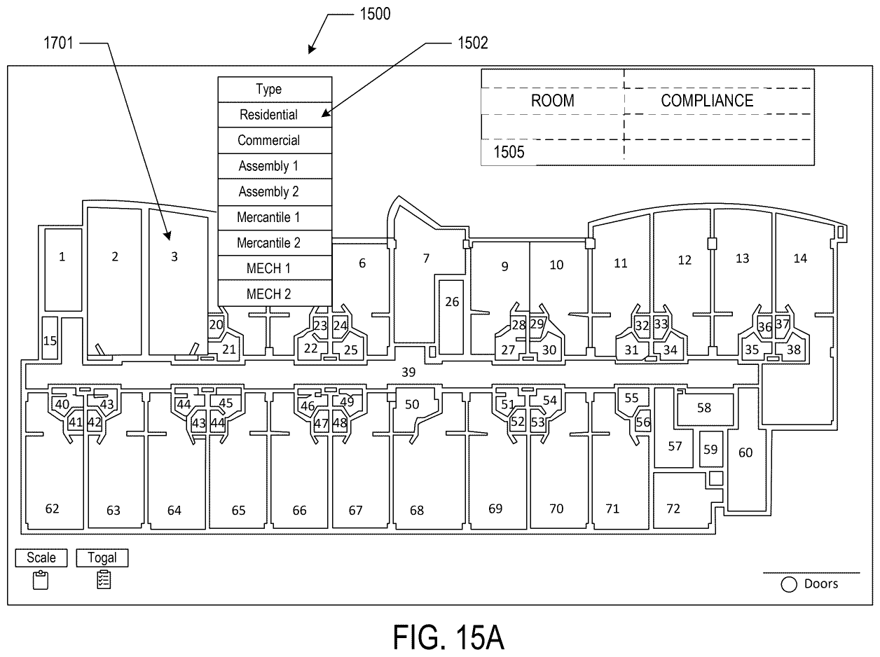

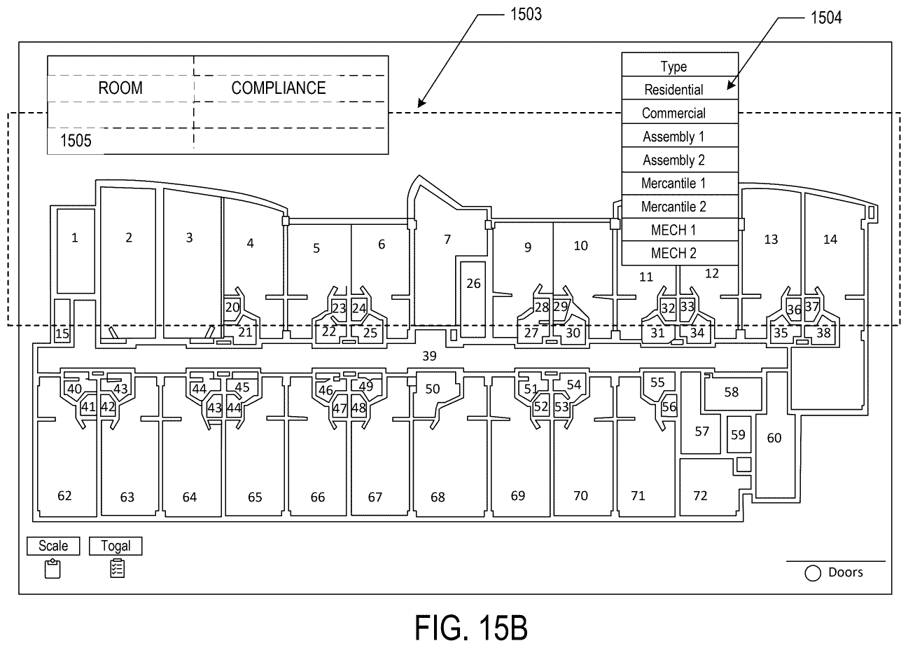

Referring now to FIG. 15A, it illustrates an exemplary interactive user interface 1500 that provides visual indicators for compliant and non-compliant spaces within a design plan undergoing alignment analysis by the AI engine. The interface 1500 is designed to offer a clear, color-coded representation of the alignment status of various areas within the building design, allowing users to quickly identify which parts of the design plan meet the relevant regulatory standards and which do not.

In FIG. 15A, the spaces within the design plan are color-coded, with red areas 1501 indicating non-compliant spaces and green areas representing compliant spaces. The AI engine is responsible for analyzing each space within the design plan against a comprehensive set of building deployment objectives and regulations. When a space is highlighted in red, it signifies that the area has failed to meet one or more of these alignment criteria. The AI engine may analyze the specific parameters of the non-compliant space, such as dimensions, occupancy load, structural integrity, or accessibility features, and identify the aspects that are not in accordance with the required standards. For example, a red-colored area may represent a hallway that is too narrow to meet egress requirements or a room that does not provide sufficient natural light according to local building deployment objectives.

Once the AI engine identifies a space, it can take several actions. First, it may provide a detailed explanation of why the space is suitable and/or not suitable for a preferred use, specifying reasons for suitability and/or non-suitability. This information may be used by architects, engineers, or project managers to understand what needs to be promoted and/or corrected. The AI engine may also suggest possible modifications to modify a space alignment for suitability for a preferred use. For example, if a room is too small to meet the minimum area requirement for its intended use, the AI engine may recommend enlarging the space or repurposing it for a different function. These suggestions help streamline the design revision process, making it easier for users to address issues and improve the overall plan. The AI engine may also provide modifications that eliminate non-optimal use of space, such as hallways, dead ends, etc.

The green areas within the design plan represent spaces that have been analyzed by the AI engine and found to be aligned with building deployment objectives and preferred use. These aligned spaces have met preferred use requirements. The AI engine's analysis of these spaces confirms that they are suitable for construction as designed, without the need for further modifications. This visual confirmation provides users with confidence that these parts of the design are ready to move forward in the construction process.

The interactive user interface 1500 also includes a pop-up window 1502, which may display detailed information about the analyzed areas. The pop-up window 1502 may provide users with in-depth data about each space within the design plan. The pop-up window 1502 may include information such as the type of area being analyzed (e.g., residential, commercial, assembly, or storage), the specific user preferences that were applied during an analysis, and any other relevant details that influenced the alignment with preference determination. For example, the pop-up 1502 may show that a particular room was analyzed for suitability of use in a preferred deployment.

Moreover, the pop-up 1502 may include a breakdown of different types of areas within the design, allowing users to filter the view based on specific criteria. For example, users may choose to view only commercial areas or focus on spaces that are intended for assembly purposes. This feature enables a more targeted analysis, allowing users to concentrate on specific parts of the building design that are most relevant to their current tasks.

The interface 1500 may also include additional interactive elements that allow users to modify the design plan directly from within the user interface. For example, if a space is marked as non-compliant, users may be able to click on that area to access tools for adjusting its dimensions, changing its intended use, or modifying its structural elements. Once the changes are made, the AI engine can re-analyze the space in real-time, updating the color-coding and alignment status accordingly. This iterative process supports a dynamic and efficient workflow, where design revisions can be made and evaluated on the fly.

In some embodiments, the user interface 1500 may also allow users to compare different versions of the design plan, showing how alignment has improved over time or how different design choices impact the overall alignment status. This comparative analysis can be valuable for making informed decisions about which design options to pursue.

Referring now to FIG. 15B, it illustrates an exemplary interactive user interface within which a user can select a portion of the design plan for detailed alignment analysis by the AI engine. The user interface is designed to allow users to focus on specific areas within the overall design plan, facilitating targeted alignment checks that align with the user's immediate objectives. The selected portion 1503, as shown in the interface, can include one or more areas of the design plan, enabling the AI engine to perform its analysis on these specific sections rather than the entire design at once.

In some embodiments, the user may select the portion 1503 of the design plan by clicking on the desired areas directly within the user interface. The user interface may support various selection methods, including click-and-drag functionality for rectangular selections, shift-clicking to select multiple non-contiguous areas, or using lasso tools to encompass irregular shapes. This flexibility in selection methods allows users to precisely define the scope of the analysis, so that the AI engine's resources are focused on the most relevant parts of the design.

Once a portion 1503 of the design plan is selected, the AI engine initiates the alignment analysis for the chosen areas. The analysis may include evaluating the selected spaces against multiple alignment factors, such as building deployment objectives, preferences, and functional requirements. The AI engine may assess whether the selected areas meet required dimensions, are appropriately spaced for their intended use, or are compliant with occupancy limits and egress requirements. For example, if the selected portion 1503 includes a series of offices and meeting rooms, the AI engine may check that all spaces meet minimum area requirements and that travel paths are adequately sized and accessible.

As the AI engine performs its analysis, a pop-up window 1504 may appear within the user interface, providing detailed information about the selected areas. The pop-up 1504 may include a breakdown of the types of spaces being analyzed, such as commercial, assembly, or mechanical areas, as well as specific attributes relevant to each type. For example, in an assembly area, the pop-up 1504 may highlight factors such as seating capacity, aisle width, and exit availability, whereas in a mechanical area, it may focus on equipment spacing and ventilation requirements. The pop-up 1504 serves as a real-time feedback tool, offering the user immediate insights into the alignment status of the selected areas without the need to navigate away from the main interface.

In addition to the pop-up 1504, the user interface also includes a detailed table 1505 that displays the results of the alignment analysis conducted by the AI engine. The table 1505 provides a comprehensive summary of the analyzed areas, listing out specific metrics such as the area of each space, the type of alignment check performed, and whether the space is compliant or non-compliant. The table 1505 may include columns for various parameters, such as area measurements, height requirements, occupancy limits, and egress distances, all of which are cross-referenced with the relevant building deployment objectives or standards.

For example, the table 1505 may show that a specific room in the selected portion 1503 has an area of 250 square feet, which is compliant with the minimum requirement of 200 square feet for its intended use as a small office. Conversely, it may indicate that another room fails to meet the necessary ceiling height for accessibility alignment, flagging it as non-compliant. This detailed breakdown allows users to quickly identify areas of concern and understand the specific reasons behind any alignment issues.

The user interface may also allow users to interact with the table 1505, providing options to sort, filter, or export the data for further review. For example, a user may choose to filter the table 1505 to display only non-compliant areas, enabling them to focus on resolving these issues before moving on to other tasks. Alternatively, the user may sort the table by room type or alignment criteria, allowing for a more organized review process.

Moreover, the user interface may include additional tools for modifying the design directly based on the AI engine's analysis. For example, if a space is found to be non-compliant due to insufficient area, the user may click on the corresponding table entry or pop-up and access tools for resizing the space or reconfiguring its layout. The AI engine may then re-analyze the modified design in real-time, updating the alignment status and providing immediate feedback on whether the changes have resolved the issue.

In some embodiments, the user interface may also allow for scenario-based analysis, where the AI engine runs multiple alignment checks under different assumptions or design variations. For example, the user may create several versions of a floor plan, each with slightly different room configurations, and use the interface to compare the alignment results for each version. This capability supports a more iterative and exploratory design process, helping users to optimize their plans for both alignment and functionality.

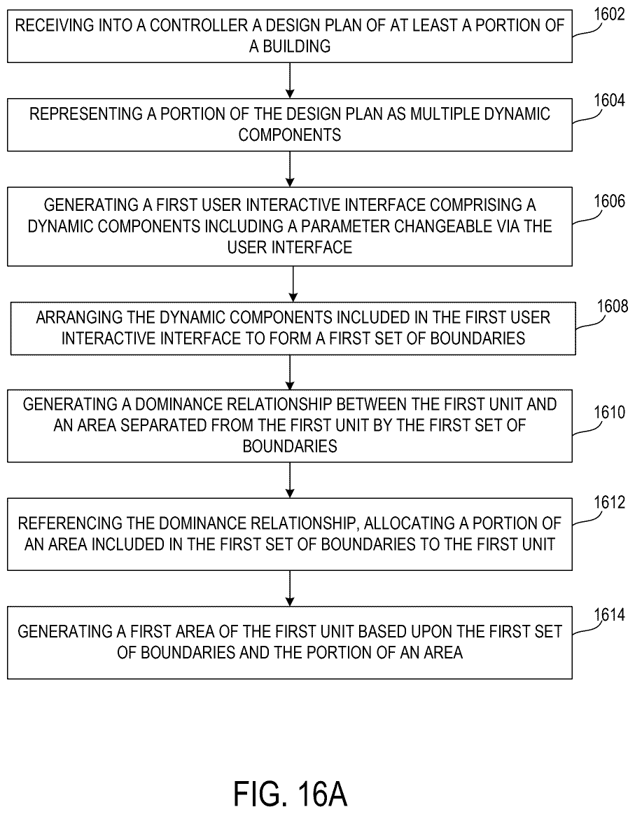

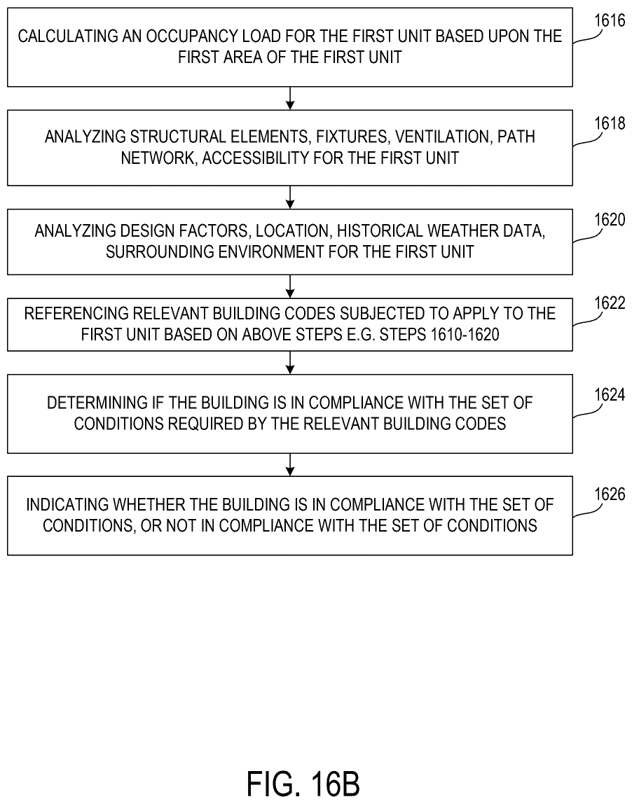

Referring now to FIGS. 16A-16B, the flowcharts describe a method, according to some embodiments of the present disclosure. The method involves a series of operations performed by the controller, which is configured with an AI engine, to analyze and optimize a design plan of at least a portion of a building. The sequence of steps is intended to facilitate the generation of a user interface that allows for dynamic interaction with the design components, leading to an enhanced and precise analysis of the building plan.

At step 1602, the process begins with the controller receiving a design plan of at least a portion of a building. The design plan may be a digital representation, such as a BIM (Building Information Modeling) file, CAD (Computer-Aided Design) drawing, or another form of architectural plan. The design plan includes detailed information about the layout, structural elements, fixtures, and other components of the building. For example, the design plan may represent an entire floor of a commercial building, including offices, conference rooms, and common areas, or it may focus on a specific section, such as a mechanical room or lobby. The controller, equipped with AI capabilities, interprets the design plan, preparing it for further analysis and manipulation in subsequent steps.

At step 1604, the controller represents a portion of the design plan as multiple dynamic components. These dynamic components correspond to the various elements within the design, such as walls, doors, windows, HVAC systems, electrical fixtures, and more. Each dynamic component is a digital entity that can be manipulated, resized, repositioned, or otherwise modified within the user interface. For example, a dynamic component representing a wall may include attributes such as height, length, thickness, material type, and load-bearing capacity. The AI engine may break down the design plan into these components to allow for detailed, granular control over each aspect of the building's layout and structure.

At step 1606, the controller generates a first user interactive interface comprising the dynamic components, each including a parameter changeable via the user interface. The user interface serves as the primary platform through which users can interact with the design plan. The dynamic components within this interface are not static; instead, they are designed to be adjustable based on user input or AI-driven suggestions. For example, a user may click on a dynamic component representing a door and adjust its width to comply with accessibility standards. The user interface may include tools for modifying parameters such as dimensions, materials, placement, and orientation of the components. The AI engine monitors these changes in real-time, offering recommendations or flagging potential alignment issues as the user makes adjustments.

At step 1608, the controller arranges the dynamic components included in the first user interactive interface to form a first set of boundaries. These boundaries define the spatial relationships between the various components within the design. For example, the boundaries may delineate the walls of a room, the space allocated for a corridor, or the extent of an open-plan office area. The arrangement of these boundaries is used for understanding how the different parts of the building interact with each other. The AI engine assists in this process by analyzing the spatial configuration to determine if it meets design objectives, such as efficient use of space, adherence to building deployment objectives, and optimization for occupant flow and safety. The boundaries may also be adjusted dynamically as the user modifies the components, so that the overall design remains coherent and functional.

At step 1610, the controller generates a dominance relationship between a first unit and an area separated from the first unit by the first set of boundaries. A dominance relationship refers to the hierarchical or functional relationship between different spaces within the design plan. For example, a conference room (the first unit) may dominate an adjacent hallway (the area separated by the boundary) in terms of access control, acoustic insulation, or spatial prominence. The AI engine analyzes these relationships to optimize the design for factors such as privacy, noise reduction, and traffic flow. For example, the AI engine may suggest reinforcing the wall between a noisy mechanical room and a quiet office space to prevent sound transmission. The dominance relationship also influences how spaces are used and perceived within the building, guiding the design towards configurations that enhance functionality and user experience.

At step 1612, the controller references the dominance relationship, allocating a portion of an area included in the first set of boundaries to the first unit. This step involves assigning specific portions of the building's layout to the dominant unit based on the established dominance relationship. For example, if a conference room is deemed to dominate a portion of a shared lobby area, the AI engine may allocate additional space to the conference room to accommodate larger groups or improve access. This allocation process is guided by the need to balance different functional requirements within the design, so that each space is appropriately sized and configured for its intended use. The AI engine may also consider factors such as occupancy load, safety requirements, and aesthetic preferences when making these allocations.

At step 1614, the controller generates a first area of the first unit based upon the first set of boundaries and the portion of an area allocated to the first unit. This step involves calculating and defining the precise area of the first unit after taking into account the boundaries and any additional space allocated to it. The AI engine verifies that the calculated area complies with relevant standards and regulations, such as minimum space requirements for specific room types or maximum occupancy limits. The resulting area definition is then integrated back into the overall design plan, completing the process. This finalized area can be used for further analysis, such as determining alignment with building deployment objectives, optimizing for energy efficiency, or planning interior layouts.

At step 1616, the controller calculates an occupancy load for the first unit based upon the first area of the first unit. Occupancy load refers to the maximum number of people that can safely occupy a space at any given time, as determined by building deployment objectives and preferences. The AI engine calculates this load by considering the area of the first unit, which is determined in earlier steps, and applying the relevant occupancy standards. For example, in a commercial office space, the occupancy load may be calculated based on the standard that allows one person per 10 square feet. If the first unit is a conference room with an area of 500 square feet, the AI engine may determine that the occupancy load is 50 people. The calculation may also consider other factors, such as the presence of fixed seating, the arrangement of furniture, or the type of activity conducted within the space.

At step 1618, the AI engine moves on to analyzing structural elements, fixtures, ventilation, path network, and accessibility for the first unit. This step involves a comprehensive review of the physical components and systems within the first unit to determine if they meet the necessary standards for safety, functionality, and comfort. The AI engine examines the structural elements, such as walls, beams, and columns, to verify that they are capable of supporting the building's loads and resisting environmental forces like wind and earthquakes. Fixtures, such as plumbing, lighting, and HVAC components, are analyzed to determine if they are correctly installed, adequately spaced, and compatible with the first unit's intended use. The AI engine also evaluates the ventilation system to determine proper air circulation, which is required for maintaining indoor air quality and preventing the buildup of pollutants. The path network, including hallways, doors, and stairwells, is assessed for alignment with egress requirements, so that occupants can exit the unit quickly and safely in an emergency. Accessibility is another important factor, with the AI engine checking that the first unit is designed to accommodate individuals with disabilities, in accordance with regulations like the Americans with Disabilities Act (ADA).

At step 1620, the AI engine analyzes design factors, location, historical weather data, and the surrounding environment for the first unit. This step involves contextualizing the design within its broader environmental and geographical setting. The AI engine considers the design factors, such as the building's purpose, the materials used, and the architectural style, to determine if they align with the location and intended use. For example, a building designed for a coastal area may require corrosion-resistant materials due to the salty air, while a building in a high-wind area may need additional bracing and reinforcement. Historical weather data, including information about past storms, floods, and temperature extremes, is analyzed to determine if the building can withstand the local climate. The surrounding environment is also considered, with the AI engine evaluating factors like proximity to other buildings, natural landscapes, and potential hazards like flood zones or seismic faults. By taking these factors into account, the AI engine helps in determining if the building design is resilient, sustainable, and well-suited to its location.

At step 1622, the AI engine references relevant building deployment objectives that apply to the first unit, based on the information gathered in steps 1616-1620. Building deployment objectives are a set of regulations that govern the design, construction, and maintenance of buildings so that they are safe, accessible, and energy-efficient. Preferred uses and deployment purposes may vary depending on the building's location, use, and other factors, and they cover a wide range of topics, including structural integrity, amenities, accessibility, and environmental impact. The AI engine cross-references the data it has gathered with the applicable codes to determine which specific regulations the first unit must comply with. For example, if the first unit is a residential space located in an earthquake-prone area and a swimming pool, the AI engine may reference codes related to seismic design and construction. Similarly, if the first unit is a commercial space with a high occupancy load, the AI engine may reference preferred use objectives such as multiple loading docks, resident access points, and service or delivery points of access.

At step 1624, the AI engine determines if the building is in alignment with the set of conditions required by the relevant building deployment objectives. This step involves a detailed comparison between the building design and the standards set forth in the building deployment objectives. The AI engine checks each aspect of the design, from structural elements to occupancy load, against the relevant regulations to identify any areas of non-alignment. For example, if the building design includes a staircase that is too narrow to meet egress requirements, the AI engine may flag this as an alignment issue. Similarly, if the ventilation system does not provide sufficient airflow to meet indoor air quality standards, the AI engine may identify this as a problem.

At step 1626, the AI engine indicates whether the building is in alignment with the set of conditions or not in alignment with the set of conditions. This final step involves communicating the results of the alignment analysis to the user. The AI engine provides a clear, concise summary of whether the building design meets the relevant standards, along with detailed information about any areas of non-alignment. For example, the AI engine may generate a report that highlights the specific codes that are not being met, along with recommendations for bringing the design into alignment. The report may also include visual indicators, such as color-coded diagrams or charts, to help the user quickly identify problem areas. If the building is fully compliant, the AI engine may provide a certification or approval notice that the design is ready to proceed to the next stage of the construction process. If there are issues, the AI engine may suggest specific modifications, such as resizing rooms, adding exits, or upgrading materials, to bring the design into alignment.

In some embodiments, the method may additionally include determining a scale of the components included in the design plan and/or referencing the dynamic components and determining a width of one or more of: an airflow pathway.

In some embodiments, the method may also include training the AI engine via a human identifying portions of the design plan as a particular type of component and associating a pattern of pixels with the portions of the design plan.

Another aspect may include generating suggested modifications to a design plan in order to meet alignment with a set of conditions. Modifications may include, by way of a non-limiting example, including a doorway, changing a length of a wall, widening the path of egress, eliminating a dead end, such as, for example, via inclusion of an additional wall.

Vertical openings are generally any opening between two or more floors (stories) in a building. They have a variety of uses and functions including, but not limited to: movement of occupants between floors during normal use and emergency use; exit stairs; convenience stairs/opening (limited to two floors); elevator shafts; installation of building services and features that serve multiple floors; plumbing systems; electrical systems (including telecom, data); heating/air conditioning ducts; water protection equipment such as pumps; trash and linen chutes; expansion/seismic joint; aesthetic value; communicating space; and atriums.

Some vertical openings have the same fundamental requirements for construction. Other types of vertical opening have special rules that don't require enclosure but rather layer in added features. The present invention allows for AI and machine learning processes to determine an existence of vertical openings, and automated processes apply an appropriate set of rules to the determined vertical openings and associated clearance objectives.

### Glossary

“Artificial Intelligence” as used herein means machine-based decision making and machine learning including, but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Clearance Objective” as used herein refers to a distance maintained be two items included in a building design.

“Computer Aided Design,” sometimes referred to as “CAD,” as used herein shall mean the use of automation for the creation, modification, analysis, or optimization of a design plan or design plan file.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The methods and apparatus of the present invention are presented herein generally, by way of example, to actions, processes, and deliverables important to industries such as the construction industry, by generating improved determination of alignment with specified deployment objectives, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan or other two-dimensional artifact) so that it may be analyzed using artificial intelligence and used to generate a determination of alignment with specified conditions included in one or multiple building deployment objectives in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### CONCLUSION

A number of embodiments of the present disclosure have been described. While this specification contains many specific implementation details, there should not be construed as limitations on the scope of any disclosures or of what may be claimed, but rather as descriptions of features specific to particular embodiments of the present disclosure. While embodiments of the present disclosure are described herein by way of example using several illustrative drawings, those skilled in the art will recognize the present disclosure is not limited to the embodiments or drawings described. It should be understood the drawings and the detailed description thereto are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

1-39. (canceled)

40. An apparatus for performing clearance analysis of a design plan with a relevant building deployment objective, the apparatus comprising:
a display screen; and
a controller comprising a processor and a memory storing executable software, the memory storing executable software being executable upon command to cause the controller to:
a. receive a design plan of at least a portion of a building;
b. convert the design plan into multiple dynamic components;
c. generate, on the display screen, a first interactive user interface comprising at least some of the multiple dynamic components representing the portion of the building, each dynamic component including a parameter changeable via the first interactive user interface;
d. arrange the multiple dynamic components included in the first interactive user interface to form a first set of boundaries, the first set of boundaries comprising a respective first length and a first area, and said first set of boundaries defining at least a portion of a first unit;
e. receive, via the first interactive user interface, a plurality of user-defined clearance objectives, each associated with a respective priority, wherein a user is enabled to dynamically adjust the respective priority of each clearance objective in real time;
f. determine, for each user-defined clearance objective, a set of clearance conditions between two or more of the multiple dynamic components;
g. analyze, by an explainable artificial intelligence (AI) engine, the design plan for alignment with the plurality of user-defined clearance objectives, wherein the explainable AI engine generates, for each clearance condition, a corresponding human-readable explanation and a visual trace within the first interactive user interface indicating a rationale for the set of clearance conditions determination and specific design elements involved;
h. provide, in the first interactive user interface, a versioned history of all user and AI modifications to the design plan, including timestamps, user identifiers, and an ability to compare, revert, or branch to any previous design state; and
i. indicate, in the first interactive user interface, whether the design plan is in alignment with each of the plurality of user-defined clearance objectives, and, if not, provide suggested modifications and the corresponding human-readable explanations and visual traces.

41. The apparatus of claim 40, wherein the set of clearance conditions between two or more of the multiple dynamic components is provided by an authority having jurisdiction over a geopolitical area comprising a building site.

42. The apparatus of claim 41, wherein the explainable AI engine is further configured to receive real-time feedback from multiple users, each with a distinct role, and to update a clearance analysis and explanations based on aggregated feedback.

43. The apparatus of claim 42, wherein the versioned history includes a graphical timeline interface allowing the user to select, compare, and restore any prior version of the design plan, with all associated clearance analyses and explanations.

44. The apparatus of claim 42, wherein the visual traces comprise a graphical overlay on the design plan highlighting specific boundaries, components, or areas that contributed to a clearance determination.

45. The apparatus of claim 41, wherein the human-readable explanation includes a citation to a building code referenced by the authority having jurisdiction.

46. The apparatus of claim 41, wherein the human-readable explanation includes a citation to a user preference that forms a basis for the set of clearance conditions.

47. The apparatus of claim 40, wherein the explainable AI engine is further configured to learn from user overrides of clearance determinations and to update its future analyses accordingly.

48. The apparatus of claim 40, wherein the first interactive user interface allows for simultaneous collaboration between multiple users, each user's actions being tracked and versioned.

49. The apparatus of claim 40, wherein the design plan comprises a plurality of floors, and wherein the first unit is part of a ground level floor of the building.

50. The apparatus of claim 40, wherein the controller is further configured to determine a proposed use of the building, a type of the first unit, the first area of the first unit, a number of floors within the building, a floor type of the first unit, an intended occupancy for the first unit, and a location for the building; and to determine the set of clearance conditions based upon each of: the proposed use of the building, the type of the first unit, the first area of the first unit, the number of floors within the building, the floor type of the first unit, the intended occupancy for the first unit, and the location for the building.

51. The apparatus of claim 50, wherein the proposed use of the building comprises a residential unit.

52. The apparatus of claim 50, wherein the controller is further configured to predict the intended occupancy for the first unit based upon the type of the first unit.

53. The apparatus of claim 51, wherein the type of the first unit comprises one of: a kitchen area, a water closet area, and a bedroom.

54. The apparatus of claim 52, wherein a fixture comprises one or more of: plumbing installations, electrical fixtures, HVAC systems, and furniture.

55. The apparatus of claim 54, wherein the fixture comprises plumbing fixtures comprising one or more of: sinks, toilets, showers, and bathtubs.

56. The apparatus of claim 41, wherein the explainable AI engine is configured to automatically suggest modifications to the design plan to meet the determined set of clearance conditions, and to provide the human-readable explanation and visual trace for each suggested modification.

57. The apparatus of claim 40, wherein a set of preferences indicated by the user via a user interface comprises one or more of: equipment clearance, sustainability preferences, and green building certifications.

58. The apparatus of claim 40, wherein the first interactive user interface allows for collaboration between multiple users, and each user's actions are tracked, timestamped, and versioned.

59. The apparatus of claim 40, wherein the controller is further configured to generate a second interactive user interface for a different portion of the building, each interface maintaining its own versioned history and explainable AI analysis.

60. The apparatus of claim 40, wherein the explainable AI engine accesses a database of building deployment objectives that is periodically updated, and provides citations to a relevant version of each objective in its explanations.

61. The apparatus of claim 60, wherein the explainable AI engine simulates a structural behavior of the building under different load conditions based on the set of clearance conditions, and provides a visual and textual explanation of simulation results.

62. The apparatus of claim 60, wherein the explainable AI engine is further configured to generate a 3D visualization of the building in the first interactive user interface, with overlays indicating clearance compliance and explanations.

63. The apparatus of claim 40, wherein the explainable AI engine prioritizes alignment analysis of the design plan based on a dominance rank of the first unit, and provides an explanation of a ranking rationale.
